(19) United States
(12) Patent Application Publication
(10) Pub. No.: US 2026/0235795 A1
(43) Pub. Date: Aug. 13, 2026

(54) LIGHT ABSORPTION FILM, ANTIREFLECTION FILM, AND DISPLAY DEVICE

(71) Applicant: FUJIFILM Corporation, Tokyo (JP)

(72) Inventors: Kunihiro ATSUMI, Minamiashigara-shi (JP); Ryota USAMI, Minamiashigara-shi (JP); Nobutaka FUKAGAWA, Minamiashigara-shi (JP)

(73) Assignee: FUJIFILM Corporation, Tokyo (JP)

(21) Appl. No.: 19/640,477

(22) Filed: Apr. 7, 2026

Related U.S. Application Data
(63) Continuation of application No. PCT/JP2024/037608, filed on Oct. 22, 2024.

(30) Foreign Application Priority Data
Oct. 23, 2023 (JP) 2023-181860
Sep. 27, 2024 (JP) 2024-169649

(51) Int. Cl. G02B 5/00; G02B 1/11

(52) U.S. Cl. CPC G02B 5/003; G02B 1/11

(57) ABSTRACT

Provided are a light absorption film including a support made of a transparent film, a transparent layer I having gas barrier properties, the transparent layer I being disposed in contact with the support, and a light absorption layer containing a transparent resin and a dye, the light absorption layer being disposed in contact with the transparent layer I having gas barrier properties; an antireflection film; and a display device.

### CROSS-REFERENCE TO RELATED APPLICATIONS

This application is a Continuation of PCT International Application No. PCT/JP2024/037608 filed on Oct. 22, 2024, which claims priority under 35 U.S.C. § 119 (a) to Japanese Patent Application No. 2023-181860 filed in Japan on Oct. 23, 2023 and Japanese Patent Application No. 2024-169649 filed in Japan on Sep. 27, 2024. Each of the above applications is hereby expressly incorporated by reference, in its entirety, into the present application.

### BACKGROUND OF THE INVENTION

### 1. Field of the Invention

The present invention relates to a light absorption film, an antireflection film, and a display device.

### 2. Description of the Related Art

As display devices, an organic electroluminescent (OLED) display device, an inorganic electroluminescent display device (inorganic EL display device), a liquid crystal display device, and the like have been used in recent years.

In the development of an image display device, a technique of suppressing a decrease in brightness while suppressing external light reflection by providing a light absorption layer capable of absorbing external light has been studied.

For example, in a liquid crystal display device, in a case where a white light emitting diode (LED) is used as a light source for a backlight unit, an attempt has been made to provide a light absorption filter in order to block light having unnecessary wavelengths emitted from the white LED.

In addition, WO2021/162115A discloses, as a laminate to be incorporated into a display device, a laminate including a wavelength selective absorption layer (light absorption layer) containing a resin, a dye including at least one of four specific dyes, and an antifading agent for the dye, and a gas barrier layer.

### SUMMARY OF THE INVENTION

In Examples of WO2021/162115A, it is described that a wavelength selective absorption layer (light absorption layer) is produced by applying a wavelength selective absorption layer forming liquid onto a base material and drying the wavelength selective absorption layer forming liquid, a surface of the obtained wavelength selective absorption layer is subjected to a corona treatment, and a gas barrier layer is produced by applying a gas barrier layer forming liquid onto the wavelength selective absorption layer subjected to the corona treatment and drying the gas barrier layer forming liquid. However, in a stage of incorporating the laminate into the display device, in a case where the gas barrier layer is disposed to be positioned on a viewer side (external light side) with respect to the light absorption layer and the decrease in absorbance of the dye contained in the wavelength selective absorption layer can be suppressed, it is considered to be not preferable from an optical point of view in a case where the laminate is incorporated into the display device as it is without peeling off the base material used for producing the laminate, because one layer of the support is interposed between the wavelength selective absorption layer and the display device into which the laminate is incorporated. Therefore, as described in WO2021/162115A, a support such as a peeling film is usually used as the base material used for producing the wavelength selective absorption layer so that the base material can be at least peeled off in a stage of incorporating the base material into the display device. On the other hand, in a method of peeling off the support such as the peeling film and transferring the wavelength selective absorption layer to be incorporated into the display device, there is a problem in terms of manufacturing efficiency because a peeling step and a transfer step are required.

An object of the present invention is to provide a light absorption film that includes a light absorption layer and a gas barrier layer and contributes to improvement in manufacturing (assembly) efficiency of a display device, an antireflection film, and a display device including these films.

That is, the above-described object has been achieved by the following means.

<1>

A light absorption film comprising:
a support made of a transparent film;
a transparent layer I having gas barrier properties, the transparent layer I being disposed in contact with the support; and
a light absorption layer containing a transparent resin and a dye, the light absorption layer being disposed in contact with the transparent layer I having gas barrier properties.
   <2>

The light absorption film according to <1>, further comprising:
a transparent layer II having gas barrier properties, the transparent layer II being disposed in contact with the light absorption layer on a side opposite to a side of the transparent layer I having gas barrier properties.
   <3>

The light absorption film according to <1> or <2>,
in which the light absorption layer further contains a polymer having a boronic acid-containing group.
   <4>

The light absorption film according to <1> or <2>,
in which a polymer constituting the transparent resin in the light absorption layer has a polar group.
   <5>

The light absorption film according to any one of <1>, <2>, or <4>,
in which the transparent layer I having gas barrier properties contains an amine compound or a polymer having an amino group.
   <6>

The light absorption film according to any one of <1> to <5>, further comprising:
a hard coat layer on a side of the support opposite to a side on which the transparent layer I having gas barrier properties is laminated.
   <7>

An antireflection film comprising:
an antireflection layer on a side of the support in the light absorption film according to any one of <1> to <5> opposite to a side on which the transparent layer I having gas barrier properties is laminated.
   <8>

A display device comprising:
the light absorption film according to any one of <1> to <6>.
   <9>

A display device comprising:
the antireflection film according to <7>.

In the present invention, in a case where there are a plurality of substituents, linking groups, and the like (hereinafter, referred to as substituents and the like) represented by specific reference numerals or formulae, or in a case where a plurality of substituents and the like are defined at the same time, the respective substituents and the like may be the same as or different from each other unless otherwise specified. The same applies to the definition of the number of substituents or the like. In a case where a plurality of substituents or the like come close to each other (particularly in a case where a plurality of substituents or the like are adjacent to each other), the substituents or the like may be linked to each other to form a ring unless otherwise specified. In addition, unless otherwise specified, rings, for example, alicyclic rings, aromatic rings, and heterocyclic rings may be further fused to form a fused ring.

In the present invention, unless otherwise specified, each of the components (such as a dye, a resin, and other components) constituting each layer of the light absorption film may be contained in each layer of the light absorption film in an amount of one kind or two or more kinds.

In the present invention, a polymer may be any of a chain polymerization polymer or a condensation polymerization polymer, and may be any of a homopolymer or a copolymer. In addition, in the case of copolymer, any of a random polymer, a block polymer, or the like may be used.

In the present invention, in a case where an E type double bond and a Z type double bond are present in a molecule, the double bond may be any one thereof or may be a mixture thereof, unless otherwise specified.

In the present invention, the representation of a compound (including a complex) is used to mean not only the compound itself but also a salt thereof, and an ion thereof. In addition, it is meant to include those in which a part of the structure is changed, as long as the effect of the present invention is not impaired. Further, a compound for which substitution or non-substitution is not specified means that the compound may have a predetermined substituent within a range in which an effect of the present invention is not impaired. The same applies to the definition of a substituent or a linking group.

In addition, in the present invention, the numerical range represented by using “to” means a range including the numerical values before and after “to” as the lower limit value and the upper limit value, respectively.

In the present invention, “composition” includes a mixture in which a component concentration varies within a range in which a desired function is not impaired, in addition to a mixture in which the component concentration is constant (respective components are uniformly dispersed).

In the present invention, the maximal absorption wavelength at which the maximum absorbance of the dye in the light absorption layer is exhibited is measured in a state of the light absorption film. Specifically, in Examples described later, the maximal absorption wavelength is measured under the conditions described in the section of “Maximal absorption value of light absorption film”.

The light absorption film and the antireflection film according to the present invention are a light absorption film and an antireflection film, which include a light absorption layer and a gas barrier layer, and can contribute to improvement in the manufacturing (assembly) efficiency of a display device.

In addition, since the display device according to the present invention includes the light absorption film or the antireflection film according to the present invention, the display device can be manufactured (assembled) with high efficiency.

### BRIEF DESCRIPTION OF THE DRAWINGS

FIG. 1 is a view schematically showing a configuration of a light absorption film according to the present invention.

FIG. 2 is a view schematically showing a configuration of an antireflection film according to the present invention.

FIG. 3 is a view schematically showing another configuration of the light absorption film according to the present invention.

### DESCRIPTION OF THE PREFERRED EMBODIMENTS

### <<Light Absorption Film>>

The light absorption film according to the embodiment of the present invention includes a support made of a transparent film, a transparent layer I having gas barrier properties, which is disposed in contact with the support, and a light absorption layer which is disposed in contact with the transparent layer I having gas barrier properties and contains a transparent resin and a dye.

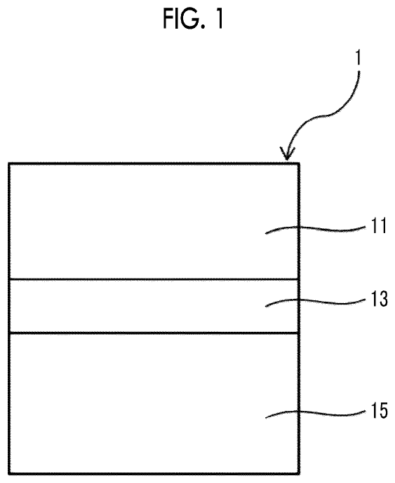

In the present invention, “disposed in contact with” means that the layers are in contact with each other without interposing a pressure-sensitive adhesive layer or the like. That is, as shown in FIG. 1, in a light absorption film 1 according to the embodiment of the present invention, a support 15 and a transparent layer I (hereinafter, also referred to as a “transparent gas barrier layer I”) 13 having gas barrier properties are laminated in a state of being in contact with each other without interposing a pressure-sensitive adhesive layer or the like, and the transparent gas barrier layer I (13) and a light absorption layer 11 are laminated in a state of being in contact with each other without interposing a pressure-sensitive adhesive layer or the like.

Examples of one aspect of the light absorption film according to the embodiment of the present invention include an aspect in which the dye is dispersed (preferably dissolved) in the resin. The dispersion may be any type of dispersion, such as a random type or a regular type.

The light absorption film according to the embodiment of the present invention has the above-described configuration, whereby the manufacturing efficiency of a display device can be improved. That is, in the light absorption film according to the embodiment of the present invention, the support, the transparent gas barrier layer I, and the light absorption layer are disposed in contact with each other in this order. Therefore, in a case where the light absorption film is incorporated into a display device such that the transparent gas barrier layer I is positioned on the viewer side (external light side) with respect to the light absorption layer and the decrease in the absorbance of the dye contained in the light absorption layer can be suppressed, the support is positioned on the viewer side (external light side) with respect to the transparent gas barrier layer I. Therefore, the light absorption film according to the embodiment of the present invention can be incorporated into the display device without peeling off the support and without transferring the light absorption layer. Therefore, the light absorption film according to the embodiment of the present invention can omit the peeling and transfer steps required for the light absorption layer and the gas barrier layer in the related art in a case of being incorporated into a display device, and can contribute to the manufacturing efficiency of the display device.

In the light absorption film according to the embodiment of the present invention, in order to suppress the decomposition of the dye and the broadening of the absorption waveform, it is preferable that the light absorption layer contains a hydrophobic polymer as a polymer constituting a transparent resin. In this case, since the transparent gas barrier layer I generally exhibits hydrophilicity, it is required to further improve the interlayer adhesion with the light absorption layer exhibiting hydrophobicity. In the light absorption film according to the embodiment of the present invention, it is considered that a chemical interaction occurs at the interface between the light absorption layer and the transparent gas barrier layer I by satisfying any one of the following regulations (I) to (III), and excellent interlayer adhesion can be realized. The detailed estimation mechanism of each regulation will be described later.
(I) The light absorption layer further contains a polymer having a boronic acid-containing group.
(II) The polymer constituting the transparent resin in the light absorption layer has a polar group.
(III) The transparent gas barrier layer I contains an amine compound or a polymer having an amino group.

### [Support]

The support in the light absorption film according to the embodiment of the present invention consists of a transparent film.

The light absorption film according to the embodiment of the present invention is disposed on a display device and used such that the support is on a viewer side and the light absorption layer is on a display device side. Therefore, the support in the light absorption film according to the embodiment of the present invention consists of a film having a light transmittance of 80% or more in a visible region at a wavelength of 400 to 800 nm.

In the present invention, the light transmittance in the visible region at a wavelength of 400 to 800 nm is an average transmittance calculated from the light transmittance at a wavelength of 400 to 800 nm measured by an ultraviolet-visible-near infrared spectrophotometer (for example, UV-3600i (product name, manufactured by Shimadzu Corporation)), and the details thereof are as described in Examples later. The same applies to the light transmittance of the transparent gas barrier layers I and II and the light absorption layer in the visible region at a wavelength of 400 to 800 nm.

Examples of the material constituting the transparent film include a polyester-based polymer (including a polyethylene terephthalate-based film), an olefin-based polymer, a cycloolefin-based polymer, a (meth)acrylic polymer, a cellulose-based polymer such as triacetyl cellulose, and a polyamide-based polymer.

The surface energy of the transparent film (support) is not particularly limited, but the adhesiveness between the transparent gas barrier layer I and the transparent film can be adjusted by adjusting the relationship between the surface energy of the material of the transparent gas barrier layer I and the coating solution and the surface energy of the surface of the transparent film on the side where the transparent gas barrier layer I is formed. In a case where the difference in surface energy is reduced, the adhesiveness tends to increase, and in a case where the difference in surface energy is increased, the adhesiveness tends to decrease, and the difference in surface energy can be appropriately set.

As the transparent film, a transparent film subjected to a surface treatment as appropriate can be used for the purpose of adjusting the surface properties (surface energy) of the transparent film. Examples of the surface treatment for reducing the surface energy include a corona treatment, a room temperature plasma treatment, and a saponification treatment, and examples of the surface treatment for increasing the surface energy include a silicone treatment, a fluorine treatment, and an olefin treatment.

It is preferable that the surface of the transparent film on the side where the transparent gas barrier layer I is formed is subjected to a surface treatment for reducing the surface energy, such as a corona treatment, a room temperature plasma treatment, or a saponification treatment.

In addition, the surface unevenness of the transparent film is not particularly limited and depending on the relationship between the surface energy, hardness, and surface unevenness of the surface of the light absorption layer and the surface energy and hardness of the surface of the transparent film opposite to the side on which the transparent gas barrier layer I is formed, for example, in order to prevent adhesion defect in a case where the light absorption film according to the embodiment of the present invention is stored in the form of a long roll, the surface unevenness of the transparent film can be adjusted. In a case where the surface unevenness is increased, adhesion defect tends to be suppressed, and in a case where the surface unevenness is reduced, the surface unevenness of the light absorption layer tends to be decreased and the haze of the light absorption layer tends to be small. Thus, the surface unevenness can be set appropriately.

The film thickness of the transparent film is preferably 5 to 100 μm, more preferably 10 to 75 μm, and still more preferably 20 to 65 km. In a case where the film thickness is equal to or larger than the above-described preferred lower limit value, sufficient mechanical strength can be easily secured, and failures such as curling, wrinkling, and buckling are less likely to occur. In addition, in a case where the film thickness is equal to or less than the above-described preferred upper limit value, in a case where the light absorption film in which at least three layers of the transparent film, the transparent gas barrier layer I, and the light absorption layer according to the embodiment of the present invention are formed into a multilayer film are stored in a long roll form, for example, the surface pressure applied to the multilayer film (light absorption film) is easily adjusted to an appropriate range, and adhesion failure is less likely to occur.

### [Transparent Gas Barrier Layer I]

The transparent gas barrier layer I in the light absorption film according to the embodiment of the present invention may be a layer having a light transmittance of 80% or more in a visible range at a wavelength of 400 to 800 nm and having gas barrier properties capable of suppressing a decrease in absorbance of the dye contained in the light absorption layer.

The material for forming the transparent gas barrier layer I is not particularly limited, and examples thereof include an organic material (preferably a crystalline resin) such as polyvinyl alcohol and polyvinylidene chloride, an organic-inorganic hybrid material such as a sol-gel material, and an inorganic material such as SiO₂, SiO, SiON, and Al₂O₃, which satisfy the above-described transmittance. The transparent gas barrier layer I may be a single layer or a multilayer, and in a case of being a multilayer, examples thereof include a configuration of an inorganic dielectric multilayer film and a multilayer film in which an organic material and an inorganic material are alternately laminated.

Examples of the transparent gas barrier layer I having hydrophilicity include a gas barrier layer formed of an organic material (preferably a crystalline resin) such as polyvinyl alcohol, polyvinylidene chloride, and an ethylene-vinyl alcohol copolymer resin as a forming material.

In the light absorption film according to the embodiment of the present invention, the transparent gas barrier layer I is disposed on a surface side (viewer side) which comes into contact with air in a case where the light absorption film according to the embodiment of the present invention is used, and the light absorption layer is disposed on an inner side of the transparent gas barrier layer I (display device side, which is a side opposite to the surface which comes into contact with air) to be used, whereby it is possible to suppress a decrease in absorption intensity of the dye in the light absorption layer in the light absorption film according to the embodiment of the present invention.

The light absorption film according to the embodiment of the present invention may have a configuration in which the transparent gas barrier layer is provided on both sides of the light absorption layer as long as the above-described disposition relationship between the transparent gas barrier layer I and the light absorption layer is satisfied.

That is, it is also preferable that the light absorption film according to the embodiment of the present invention includes a transparent layer II (hereinafter, also referred to as “transparent gas barrier layer II”) having gas barrier properties, which is disposed in contact with the light absorption layer on a side opposite to the side of the transparent gas barrier layer I.

The light absorption film according to the embodiment of the present invention, which has the transparent gas barrier layer II disposed in contact with the light absorption layer on the side opposite to the side of the transparent gas barrier layer I, can realize more excellent light resistance of the light absorption layer.

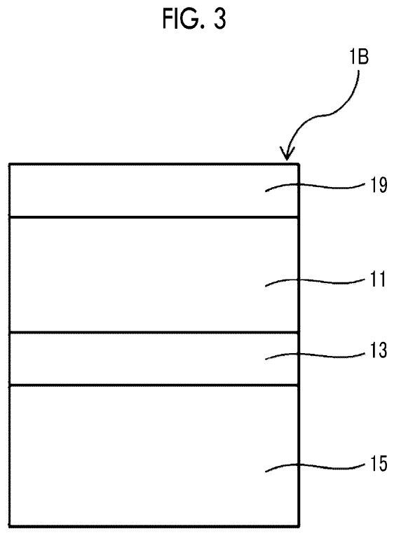

As described above, in the present invention, “disposed in contact with” means that the layers are in contact with each other without interposing a pressure-sensitive adhesive layer or the like. That is, as shown in FIG. 3, in the light absorption film 1B according to the embodiment of the present invention, the light absorption layer 11 and the transparent gas barrier layer II 19 are laminated in a state of being in contact with each other without interposing a pressure-sensitive adhesive layer or the like.

The light absorption layer 11, the transparent gas barrier layer I (13), and the support 15 in the light absorption film 1B of FIG. 3 can be used as the light absorption layer 11, the transparent gas barrier layer I (13), and the support 15 in the light absorption film 1 of FIG. 1, unless otherwise specified.

The description of the transparent gas barrier layer I can be applied as it is to the transparent gas barrier layer II, except for the disposition relationship with respect to the light absorption layer in a case where the light absorption film according to the embodiment of the present invention is incorporated into a display device. That is, for example, it is preferable that the transparent gas barrier layer II satisfies the above-described (III) in the same manner as the transparent gas barrier layer I, from the viewpoint of improving the adhesiveness to the light absorption layer.

The transparent gas barrier layer I and the transparent gas barrier layer II may be the same as or different from each other.

Among these, in a case where the transparent gas barrier layer I has a configuration containing a crystalline resin, it is preferable that the transparent gas barrier layer I contains a crystalline resin, the thickness of the layer is 0.1 μm to 10 μm, and the oxygen permeability of the layer is 60 cc/m²·day·atm or less.

In the above-described transparent gas barrier layer I, the “crystalline resin” is a resin having a melting point at which a phase transition from a crystal to a liquid occurs in a case where the temperature is raised, and can impart gas barrier properties against oxygen gas to the transparent gas barrier layer I.

Examples of the above-described crystalline resin include polyvinyl alcohol and an ethylene vinyl alcohol copolymer resin, and from the viewpoint that the crystalline portion can effectively suppress the permeation of gas, polyvinyl alcohol is preferable.

“The transparent gas barrier layer I containing a crystalline resin, where the thickness of the layer is 0.1 μm to 10 μm, and the oxygen permeability of the layer is 60 cc/m²·day·atm or less” described above is the same as the gas barrier layers described in [0180] to [0184] of WO2022/149510A, and these descriptions can be applied as they are.

In the light absorption film according to the embodiment of the present invention, it is preferable that the above-described (III) is satisfied, that is, the transparent gas barrier layer I contains an amine compound or a polymer having an amino group. The amine compound or the polymer having an amino group, which is contained in the transparent gas barrier layer I, is unevenly distributed in the vicinity of the interface between the transparent gas barrier layer I and the light absorption layer in the transparent gas barrier layer I, and in a case where the polymer constituting the transparent resin in the light absorption layer has an acidic group, the adhesiveness can be improved by forming a hydrogen bond, a chemical bond, or the like with the acidic group in the polymer.

In the present invention, the “transparent gas barrier layer I contains an amine compound or a polymer having an amino group” includes not only a form in which the transparent gas barrier layer I contains an amine compound or a polymer having an amino group, but also a form in which the amino group of the amine compound or the polymer having an amino group is used to form a chemical bond or the like with the acidic group in the light absorption layer.

### <Amine Compound or Polymer Having Amino Group>

The above-described amine compound may be any of primary to tertiary amine compounds, and may be a nitrogen-containing alicyclic heterocyclic compound (an alicyclic heterocyclic compound having at least a nitrogen atom as a heteroatom constituting an alicyclic ring) or a nitrogen-containing aromatic heterocyclic compound (an aromatic heterocyclic compound having at least a nitrogen atom as a heteroatom constituting an aromatic ring). In addition, the above-described amine compound may have a plurality of amino groups in the compound.

Examples of the amino group contained in the above-described amine compound and the polymer having an amino group include an unsubstituted amino group (—NH₂) and a primary or secondary amino group having a substituent (which means a monovalent group obtained by removing one hydrogen atom bonded to a nitrogen atom in a primary amine or a secondary amine). In addition, the substituents on the nitrogen atoms of the secondary amino group having a substituent may be bonded to each other to form a ring structure (nitrogen-containing alicyclic heterocyclic ring) other than the aromatic ring.

In addition, examples of the above-described amine compound and the polymer having an amino group also include a compound and a polymer having a nitrogen-containing alicyclic heterocyclic group (a monovalent group obtained by removing one hydrogen atom from an alicyclic heterocyclic compound having at least a nitrogen atom as a heteroatom constituting an alicyclic ring) and/or a nitrogen-containing aromatic heterocyclic group (a monovalent group obtained by removing one hydrogen atom from an aromatic heterocyclic ring having at least a nitrogen atom as a heteroatom constituting an aromatic ring).

Preferred specific examples of the above-described amino group, nitrogen-containing alicyclic heterocyclic group, or nitrogen-containing aromatic heterocyclic group (hereinafter, referred to as “amino group or the like”) include groups consisting of an aliphatic amine compound such as guanidine, aminopyridine, aminoalkylpyridine, aminopyrrolidine, indazole, imidazole, pyrazole, pyrazine, pyrimidine, purine, imidazoline, pyrazoline, piperazine, aminomorpholine, or aminoalkylmorpholine, a nitrogen-containing alicyclic compound, or a nitrogen-containing aromatic compound. Preferred examples of the substituent which may be contained in these amino groups or the like include an unsubstituted amino group, an alkylamino group, an aminoaryl group, an arylamino group, an alkyl group (particularly preferably an aminoalkyl group as a substituted alkyl group), an alkoxy group, an acyl group, an acyloxy group, an aryl group, an aryloxy group, a nitro group, a hydroxy group, and a cyano group.

Among these, examples of the particularly preferable compound include guanidine, 1,1-dimethylguanidine, 1,1,3,3-tetramethylguanidine, imidazole, 2-methylimidazole, 4-methylimidazole, N-methylimidazole, 2-phenylimidazole, 4,5-diphenylimidazole, 2,4,5-triphenylimidazole, 2-aminopyridine, 3-aminopyridine, 4-aminopyridine, 2-dimethylaminopyridine, 4-dimethylaminopyridine, 2-diethylaminopyridine, 2-(aminomethyl)pyridine, 2-amino-3-methylpyridine, 2-amino-4-methylpyridine, 2-amino-5-methylpyridine, 2-amino-6-methylpyridine, 3-aminoethylpyridine, 4-aminoethylpyridine, 3-aminopyrrolidine, piperazine, N-(2-aminoethyl)piperazine, N-(2-aminoethyl)piperidine, 4-amino-2,2,6,6-tetramethylpiperidine, 4-piperidinopiperidine, 2-iminopiperidine, 1-(2-aminoethyl)pyrrolidine, pyrazole, 3-amino-5-methylpyrazole, 5-amino-3-methyl-1-p-tolylpyrazole, pyrazine, 2-(aminomethyl)-5-methylpyrazine, pyrimidine, 2,4-diaminopyrimidine, 4,6-dihydroxypyrimidine, 2-pyrazoline, 3-pyrazoline, N-aminomorpholine, and N-(2-aminoethyl)morpholine. However, there is no limitation thereto.

Specific examples of the amine compound include the amine compounds described in the description of the specific examples of the amino group or the like.

Specific examples of the polymer having an amino group include polyethyleneimine, polyamine, and polyvinylpyridine, and among these, it is preferable to use at least one of polyethyleneimine or polyamine.

As the above-described polyethyleneimine, for example, Epomin SP-200, Epomin HM-2000, Epomin P-1000, and Epomin P-3000, all of which are trade names, manufactured by Nippon Shokubai Co., Ltd., and Polyethyleneimine 10000 and Polyethyleneimine 70000, all of which are trade names, manufactured by Junsei Chemical Co., Ltd., can be preferably used. In addition, polyethyleneimine manufactured by FUJIFILM Wako Pure Chemical Corporation can also be preferably used.

In addition, as the above-described polyamine, for example, PVAM-0570B, PVAM-0595B, and PVDL, all of which are trade names, manufactured by Mitsubishi Chemical Corporation, and PAA-1% C, PAA-25, PAA-50, PAA-100, PAA-1222, PAA-U5000, PAA-N5000, PAS-21, and PAA-D11, all of which are trade names, manufactured by Nittobo Medical Co., Ltd., can be preferably used.

The weight-average molecular weight (Mw) of the above-described polymer having an amino group is preferably 5,000 or more, more preferably 5,000 to 200,000, and still more preferably 5,000 to 150,000.

The content of the amine compound in the above-described transparent gas barrier layer I is, for example, preferably 0.1 to 30 parts by mass, more preferably 0.5 to 20 parts by mass, still more preferably 1 to 10 parts by mass, and particularly preferably 2 to 7 parts by mass, with respect to 100 parts by mass of the total of components other than the amine compound constituting the transparent gas barrier layer I. By adjusting the content of the amine compound in the above-described transparent gas barrier layer I, it is possible to ensure good adhesiveness with the light absorption layer while maintaining the transparency of the transparent gas barrier layer I.

In addition, the content of the polymer having an amino group in the above-described transparent gas barrier layer I is, for example, preferably 0.5 to 45 parts by mass, more preferably 0.75 to 30 parts by mass, still more preferably 1.0 to 20 parts by mass, and particularly preferably 1.5 to 15 parts by mass, with respect to 100 parts by mass of the total of components other than the polymer having an amino group constituting the transparent gas barrier layer I. By adjusting the content of the polymer having an amino group in the above-described transparent gas barrier layer I, it is possible to ensure good adhesiveness with the light absorption layer while maintaining the transparency of the transparent gas barrier layer I.

In addition, in a case where the light absorption film according to the embodiment of the present invention has the above-described transparent gas barrier layer II in addition to the above-described transparent gas barrier layer I, the content of the polymer having an amino group in each of the transparent gas barrier layer I and the transparent gas barrier layer II is, for example, preferably 0.1 to 45 parts by mass, more preferably 0.2 to 30 parts by mass, and still more preferably 0.5 to 20 parts by mass, with respect to 100 parts by mass of the total of components other than the polymer having an amino group constituting the transparent gas barrier layer. By adjusting the content of the polymer having an amino group in each of the above-described transparent gas barrier layer I and the above-described transparent gas barrier layer II, it is possible to ensure good adhesiveness with the light absorption layer while maintaining the transparency of the transparent gas barrier layer I and the transparent gas barrier layer II.

### [Light Absorption Layer]

The light absorption layer in the light absorption film according to the embodiment of the present invention is a layer containing a transparent resin and a dye.

### <Transparent Resin>

The transparent resin contained in the above-described light absorption layer (hereinafter, also referred to as a “matrix resin”) is not particularly limited as long as the above-described dye can be dispersed (preferably dissolved) and the light absorption layer adjusted for transmittance measurement can be a layer having a light transmittance of 80% or more in a visible region at a wavelength of 400 to 800 nm.

The “light absorption layer adjusted for transmittance measurement” means a layer having the same film thickness as the light absorption layer, which is produced using a forming liquid obtained by removing the dye from the light absorption layer forming liquid.

As the polymer constituting the above-described transparent resin, various polymers can be used.

Preferred examples thereof include a polymer having an aromatic ring or an alicyclic structure, and a (meth)acrylic polymer containing a constitutional unit having an aromatic ring or an alicyclic structure is more preferable.

Here, the (meth)acrylic polymer refers to a polymer containing at least one of a constitutional unit derived from (meth)acrylic acid or a constitutional unit derived from (meth)acrylic acid ester.

In the present disclosure, the “main chain” represents a relatively longest bonding chain in a molecule of a polymer compound, and the “side chain” represents an atomic group branched from the main chain.

### <<Constitutional Unit Having Aromatic Ring>>

It is also preferable that the polymer constituting the above-described transparent resin has a constitutional unit having an aromatic ring (preferably, an aromatic hydrocarbon ring).

Examples of the constitutional unit having an aromatic ring include a constitutional unit derived from a (meth)acrylate having an aromatic ring, and a constitutional unit derived from benzyl (meth)acrylate, naphthyl (meth)acrylate, phenethyl (meth)acrylate, phenoxyethyl (meth)acrylate, or naphthylmethyl (meth)acrylate is preferable.

In the polymer constituting the above-described transparent resin, a content of the constitutional unit having an aromatic ring is preferably 5 to 100 mol %, more preferably 10 to 100 mol %, and still more preferably 20 to 100 mol % in a case where the total of all constitutional units of the polymer is set to 100 mol %.

One kind of the constitutional unit having an aromatic ring may be used alone, or two or more kinds thereof may be used in combination.

### <<Constitutional Unit Having Alicyclic Structure>>

It is also preferable that the polymer constituting the above-described transparent resin has a constitutional unit having an alicyclic structure.

Examples of the alicyclic structure include a tricyclo[5.2.1.0^{2,6}]decane ring structure (also referred to as tetrahydrodicyclopentadiene; a monovalent group is dicyclopentanyl), a tricyclo[5.2.1.0^{2,6}]decane-3-ene ring structure (also referred to as 5,6-dihydrodicyclopentadiene; a monovalent group is dicyclopentenyl), an isobornane ring structure (a monovalent group is isobornyl), an adamantane ring structure (a monovalent group is adamantyl), a cyclopentane ring structure, and a cyclohexane ring structure (a monovalent group is cyclohexyl).

Examples of the constitutional unit having an alicyclic structure include a constitutional unit derived from a (meth)acrylate having an alicyclic structure, and a constitutional unit derived from dicyclopentanyl (meth)acrylate, dicyclopentenyl (meth)acrylate, isobornyl (meth)acrylate, adamantyl (meth)acrylate, or cyclohexyl (meth)acrylate is preferable.

In the polymer constituting the above-described transparent resin, a content of the constitutional unit having an alicyclic structure is preferably 1 to 90 mol %, more preferably 5 to 90 mol %, still more preferably 10 to 70 mol %, particularly preferably 20 to 55 mol %, and especially preferably 25 to 55 mol % in a case where the total of all constitutional units of the polymer is set to 100 mol %.

One kind of the constitutional unit having an alicyclic structure may be used alone, or two or more kinds thereof may be used in combination.

### <Constitutional Unit Having Alkyl Group Having 1 to 14 Carbon Atoms>>

From the viewpoint of adjusting the glass transition temperature, the polymer constituting the above-described transparent resin may include a constitutional unit having an alkyl group having 1 to 14 carbon atoms (excluding an alicyclic alkyl group). Examples of the constitutional unit having an alkyl group having 1 to 14 carbon atoms include a constitutional unit derived from an alkyl (meth)acrylate, such as methyl (meth)acrylate, ethyl (meth)acrylate, n-propyl (meth)acrylate, isopropyl (meth)acrylate, n-butyl (meth)acrylate, t-butyl (meth)acrylate, sec-butyl (meth)acrylate, pentyl (meth)acrylate, 2-ethylhexyl (meth)acrylate, 2-ethylbutyl (meth)acrylate, n-octyl (meth)acrylate, isooctyl (meth)acrylate, isononyl (meth)acrylate, lauryl (meth)acrylate, or tetradecyl (meth)acrylate. In the present invention, one kind of the constitutional unit having an alkyl group having 1 to 14 carbon atoms may be used alone, or two or more kinds thereof may be used in combination.

In the polymer constituting the above-described transparent resin, a content of the constitutional unit having an alkyl group having 1 to 14 carbon atoms is preferably 0 to 95 mol %, more preferably 0 to 70 mol %, still more preferably 0 to 50 mol %, and particularly preferably 0 to 20 mol % in a case where the total of all constitutional units of the polymer is set to 100 mol %.

In the light absorption film according to the embodiment of the present invention, it is preferable that the above-described requirement (II) is satisfied, that is, the polymer constituting the transparent resin in the light absorption layer has a polar group. The polar group of the polymer having a polar group present at the interface between the light absorption layer and the transparent gas barrier layer I can form a hydrogen bond, a chemical bond, or the like with a hydrophilic group such as an —OH group in the transparent gas barrier layer I, whereby the adhesiveness can be improved.

In the present invention, the “polymer constituting the transparent resin in the light absorption layer has a polar group” includes not only a form in which the polymer constituting the transparent resin in the light absorption layer has a polar group, but also a form in which the polar group of the polymer having a polar group is used to form a chemical bond with a hydrophilic group such as an —OH group in the transparent gas barrier layer I.

### <Constitutional Unit Having Polar Group>>

Examples of the polar group contained in the polymer constituting the transparent resin include a carboxy group, a carboxylic acid anhydride group, a hydroxy group (including a phenolic hydroxyl group), a nitrogen-containing aromatic ring group, and an amide group; and a carboxy group or a carboxylic acid anhydride group is preferable.

The polymer having a polar group, which constitutes the transparent resin, preferably contains a constitutional unit having a polar group, and examples thereof include a constitutional unit derived from a chain polymerization-based monomer having a polar group and a carbon-carbon double bond, and a constitutional unit derived from (meth)acrylic acid, 4-vinylpyridine, 4-vinylpyrrolidone, 4-vinylphenol, or the like is preferable.

In addition, as will be described later, a polar group may be introduced into the polymer structure later, and examples thereof include an acid-modified polymer.

In a case where the polymer constituting the transparent resin contains a constitutional unit having a polar group, the content of the constitutional unit having a polar group in the polymer constituting the transparent resin is preferably 1 to 95 mol %, more preferably 3 to 70 mol %, still more preferably 5 to 50 mol %, and particularly preferably 10 to 40 mol % in a case where the total of all constitutional units of the polymer is set to 100 mol %.

In a case where the transparent gas barrier layer I (further, the transparent gas barrier layer II which may be provided) contains an amine compound or a polymer having an amino group, it is preferable that the polymer constituting the transparent resin in the light absorption layer has an acid group, since the above-described provision (III) can be satisfied and the adhesiveness can be improved.

In the present invention, the “polymer constituting the transparent resin in the light absorption layer has an acid group” includes not only a form in which the polymer constituting the transparent resin in the light absorption layer has an acid group, but also a form in which the acid group of the polymer having an acid group is used to form a chemical bond with an amine compound or a polymer having an amino group in the transparent gas barrier layer I (further, the transparent gas barrier layer II which may be provided).

### <Polymer Having Acid Group>>

The acid group contained in the polymer constituting the transparent resin is preferably a proton dissociable group having a pKa of 12 or less. Specific examples of the acid group include a carboxy group, a sulfonamide group (—S(═O)₂NH₂), a phosphonate group (—P(═O)(OH)₂), a phosphate group (—OP(═O)(OH)₂), a sulfo group, a phenolic hydroxyl group, and a sulfonyl imide group, where a carboxy group is preferable. The pKa means a negative common logarithm (−log Ka) of an acid dissociation constant (Ka) in water at 25° C. The pKa can be calculated according to dropwise adding a 0.01 mol/L sodium hydroxide aqueous solution to an aqueous solution of a sample for measurement (a polymer having an acid group) and reading the amount of the sodium hydroxide aqueous solution added dropwise up to the half-equivalent point.

In addition, a part or all of the acid groups contained in the polymer constituting the transparent resin may or may not be anionized in the light absorption layer, and in the present invention, both the anionized acid group and the non-anionized acid group are referred to as an acid group. That is, the acid group contained in the polymer constituting the transparent resin may or may not be anionized in the light absorption layer.

From the viewpoint of excellent film-forming properties of the light absorption layer, the polymer having an acid group, which constitutes the transparent resin, is preferably a polymer having a carboxy group, that is, a carboxy group-containing polymer.

The carboxy group-containing polymer may further have, as an acid group, an acid group other than the carboxy group. Examples of the acid group other than the carboxy group include a phenolic hydroxyl group, a phosphate group, and a sulfonic acid group.

### <<Constitutional Unit Having Carboxy Group>>

The carboxy group-containing polymer preferably has a constitutional unit having a carboxy group.

Examples of the constitutional unit having a carboxy group include a constitutional unit derived from (meth)acrylic acid, crotonic acid, itaconic acid, maleic acid, or fumaric acid. Among the above, a constitutional unit derived from (meth)acrylic acid is preferable from the viewpoint of high decolorizing properties of the dye.

In the carboxy group-containing polymer, the content of the constitutional unit having a carboxy group can be applied with the description related to “content of constitutional unit having polar group in polymer constituting above-described transparent resin”.

One kind of the constitutional unit having a carboxy group may be used alone, or two or more kinds thereof may be used in combination.

In addition, as the polymer having an acid group, constituting the transparent resin, an acid-modified polymer such as a polymer having a carboxylic acid anhydride group as a group from which the above-described acid group can be derived in the light absorption layer is also preferable from the viewpoint of excellent film-forming properties of the light absorption layer.

Examples of the acid-modified polymer constituting the transparent resin include “TUFTEC M series” manufactured by Asahi Kasei Corporation, “ADMER series” and “UNISTAL series” manufactured by Mitsui Chemicals, Inc., “UMEX series” manufactured by Sanyo Chemical Industries, Ltd., and “HARDLEN series” manufactured by Toyobo Co., Ltd.

The weight-average molecular weight (Mw) of the polymer that constitutes the above-described transparent resin is preferably 10,000 or more, more preferably 10,000 to 200,000, and still more preferably 15,000 to 150,000.

In the present invention, the weight-average molecular weight of the polymer can be measured as a molecular weight in terms of polystyrene by gel permeation chromatography (GPC).

Specifically, a GPC device HLC-8220 (trade name, manufactured by Tosoh Corporation) is used, tetrahydrofuran is used as an eluent, G3000HXL+G2000HXL (both are trade names, manufactured by Tosoh Corporation) are used as columns, and detection can be performed by a differential refractive index (RI) at 23° C. and a flow rate of 1 mL/min.

In addition, as an example of another embodiment of the above-described transparent resin, the description of the matrix resin described in [0145] to [0175] of WO2021/132674A can be applied as it is.

Among these, as the above-described transparent resin, it is preferable to use the following polystyrene resin described in [0151] to [0156] of WO2021/132674A.

### (Polystyrene Resin)

The polystyrene contained in the polystyrene resin means a polymer containing a styrene component. The polystyrene preferably contains 50% by mass or more of the styrene component. The transparent resin contained in the above-described light absorption layer may contain one kind of polystyrene or two or more kinds of polystyrene. Here, the styrene component is a structural unit derived from a monomer having a styrene skeleton in the structure thereof.

The polystyrene more preferably contains 70% by mass or more of the styrene component, and still more preferably 85% by mass or more of the styrene component, in terms of controlling the photo-elastic coefficient and the hygroscopicity to values within a preferred range as the light absorption layer. In addition, it is preferable that the polystyrene is composed of only the styrene component.

Among polystyrenes, as the polystyrenes composed of only styrene components, a homopolymer of a styrene compound and a copolymer of two or more types of a styrene compound are exemplified. Here, the styrene compound is a compound having a styrene skeleton in the structure thereof, and is meant to include, in addition to styrene, a compound in which a substituent is introduced within a range where an ethylenically unsaturated bond of styrene can act as a reactive (polymerizable) group.

Specific examples of the styrene compound include the following styrenes: alkylstyrene such as α-methylstyrene, o-methylstyrene, m-methylstyrene, p-methylstyrene, 3,5-dimethylstyrene, 2,4-dimethylstyrene, o-ethylstyrene, p-ethylstyrene, and tert-butyl styrene; and substituted styrene having a hydroxyl group, an alkoxy group, a carboxy group, or a halogen atom introduced into the benzene nucleus of styrene, such as hydroxystyrene, tert-butoxy styrene, vinyl benzoic acid, o-chlorostyrene, and p-chlorostyrene. Among these, the polystyrene used in the present invention is preferably a homopolymer of styrene (that is, polystyrene) from the viewpoints of availability and cost of materials.

The constituent components other than the styrene component that can be contained in the polystyrene are not particularly limited. That is, the polystyrene may be a styrene-diene copolymer, a styrene-polymerizable unsaturated carboxylic acid ester copolymer, or the like. In addition, it is also possible to use a mixture of polystyrene and synthetic rubber (for example, polybutadiene and polyisoprene). In addition, high impact polystyrene (HIPS) obtained by graft-polymerizing styrene to synthetic rubber is also preferable. Further, a polystyrene obtained by dispersing a rubber-like elastic body in a continuous phase of a polymer including a styrene component (for example, a copolymer of a styrene component and a (meth)acrylate ester component), and subjecting the copolymer to graft polymerization with a rubber-like elastic body (referred to as graft type high impact polystyrene “graft HIPS”) is also preferable. Furthermore, a so-called styrene-based elastomer can also be suitably used.

In addition, the polystyrene may be hydrogenated (may be a hydrogenated polystyrene). The hydrogenated polystyrene is not particularly limited, and it is preferably a hydrogenated styrene-diene-based copolymer such as a hydrogenated styrene-butadiene-styrene block copolymer (SEBS) obtained by hydrogenating a styrene-butadiene-styrene block copolymer (SBS) or hydrogenated styrene-isoprene-styrene block copolymer (SEPS) obtained by hydrogenating a styrene-isoprene-styrene block copolymer (SIS). Only one of the hydrogenated polystyrenes may be used, or two or more thereof may be used.

In addition, the polystyrene may be modified polystyrene. The modified polystyrene is not particularly limited, and examples thereof include polystyrene having a reactive group such as a polar group introduced therein. Specific examples thereof preferably include acid-modified polystyrene such as maleic acid-modified and epoxy-modified polystyrene.

As the polystyrene, a plurality of kinds of polystyrenes having different compositions, molecular weights, and the like may be used in combination.

The polystyrene-based resin can be obtained using a conventional method such as anion, bulk, suspension, emulsification, or a solution polymerization method. In addition, in the polystyrene, at least a part of the unsaturated double bond of the benzene ring of the conjugated diene and the styrene monomer may be hydrogenated. The hydrogenation rate can be measured by a nuclear magnetic resonance apparatus (NMR).

As the polystyrene resin, a commercially available product may be used, and examples thereof include “CLEAREN 530L”, “CLEAREN 730L” manufactured by Denka Company Limited, “TUFPRENE 1265”, “ASAPRENE T411” manufactured by Asahi Kasei Corporation, “KRATON D1102A”, “KRATON D1116A” manufactured by Kraton Corporation, “STYROLUX S”, “STYROLUX T” manufactured by INEOS Styrolution Group GmbH, “ASAFLEX 840”, “ASAFLEX 860” manufactured by Asahi Kasei Corporation (all of which is SBS), “679”, “HF77”, “SGP-10” manufactured by PS Japan Corporation, “DICSTYRENE XC-515”, “DICSTYRENE XC-535” manufactured by DIC Corporation (all of which is GPPS), “475D”, “H0103”, “HT478” manufactured by PS Japan Corporation, and “DICSTYRENE GH-8300-5” manufactured by DIC Corporation (all of which is HIPS). Examples of the hydrogenated polystyrene-based resin include “TUFTEC H Series” manufactured by Asahi Kasei Corporation, “KRATON G Series” manufactured by Shell Japan Limited (all of which is SEBS), “DYNARON” manufactured by JSR Corporation (hydrogenated styrene-butadiene random copolymer), and “SEPTON” manufactured by Kuraray Co., Ltd. (SEPS). In addition, examples of a modified polystyrene-based resin include “TUFTEC M Series” manufactured by Asahi Kasei Corporation, “EPOFRIEND” manufactured by Daicel Corporation, “polar group-modified DYNARON” manufactured by JSR Corporation, and “RESEDA” manufactured by Toagosei Co., Ltd.

It is also preferable that the transparent resin contained in the light absorption layer contains a polyphenylene ether resin in addition to the polystyrene resin. By containing the polystyrene resin and the polyphenylene ether resin together, the toughness of the light absorption layer can be improved, and the occurrence of defects such as cracks can be suppressed even in a harsh environment such as high temperature and high humidity.

As the polyphenylene ether resin, ZYLON S201A, ZYLON S202A, and ZYLON S203A (all of which are product names) manufactured by Asahi Kasei Corporation can be preferably used. In addition, a resin in which the polystyrene resin and the polyphenylene ether resin are mixed in advance may also be used. As the mixed resin of the polystyrene resin and the polyphenylene ether resin, for example, XYRON 1002H, XYRON 1000H, XYRON 600H, XYRON 500H, XYRON 400H, XYRON 300H, XYRON 200H (all of which are product names), and the like manufactured by Asahi Kasei Corporation can be preferably used.

In a case where the transparent resin contained in the light absorption layer contains a polystyrene resin and a polyphenylene ether resin, a mass ratio of both resins is preferably 99/1 to 50/50, more preferably 98/2 to 60/40, and still more preferably 95/5 to 70/30, in terms of the polystyrene resin/polyphenylene ether resin. In a case where the formulation ratio of the polyphenylene ether resin is set in the above-described preferred range, the above-described light absorption layer can have sufficient toughness, and the solvent can be properly volatilized in a case where a film is formed with a solution.

### (Cyclic Polyolefin Resin)

As the transparent resin, a cyclic polyolefin resin described below can also be preferably used.

The cyclic olefin compound forming the cyclic polyolefin contained in the cyclic polyolefin resin is not particularly limited as long as the compound has a ring structure including a carbon-carbon double bond, and examples thereof include norbornene compounds and monocyclic olefin compounds, cyclic conjugated diene compounds, vinyl alicyclic hydrocarbon compounds, which are not norbornene compounds, and the like.

Examples of the cyclic polyolefin include (1) polymers including a structural unit derived from a norbornene compound; (2) polymers including a structural unit derived from a monocyclic olefin compound other than the norbornene compound; (3) polymers including a structural unit derived from a cyclic conjugated diene compound; (4) polymers including a structural unit derived from a vinyl alicyclic hydrocarbon compound; and hydrides of polymers including a structural unit derived from each of the compounds (1) to (4).

In the present invention, ring-opening polymers of the respective compounds are included in the polymers including a structural unit derived from a norbornene compound and the polymers including a structural unit derived from a monocyclic olefin compound.

The cyclic polyolefin is not particularly limited, but a polymer having a structural unit derived from a norbornene compound, which is represented by General Formula (A-II) or (A-III), is preferable. The polymer having the structural unit represented by General Formula (A-II) is an addition polymer of a norbornene compound, and the polymer having the structural unit represented by General Formula (A-III) is a ring-opening polymer of a norbornene compound.

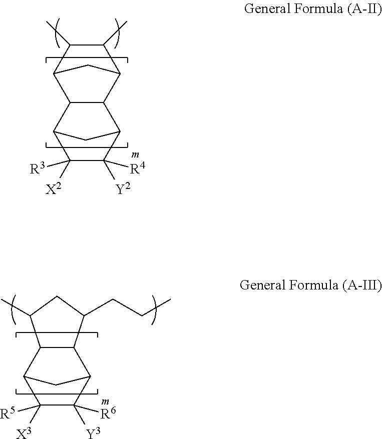

In the formula, m is an integer of 0 to 4, and is preferably 0 or 1.

R³ to R⁶ each independently represent a hydrogen atom or a hydrocarbon group having 1 to 10 carbon atoms.

The hydrocarbon group in General Formula (A-I) and General Formulae (A-II) and (A-III) is not particularly limited as long as it is a group consisting of a carbon atom and a hydrogen atom, and examples thereof include an alkyl group, an alkenyl group, an alkynyl group, and an aryl group (aromatic hydrocarbon group). Among these, an alkyl group or an aryl group is preferable.

X² and X³, and Y² and Y³ each independently represent a hydrogen atom, a hydrocarbon group having 1 to 10 carbon atoms, a halogen atom, a hydrocarbon group having 1 to 10 carbon atoms which is substituted by a halogen atom, —(CH₂)ₙCOOR^{D}, —(CH₂)ₙOCOR¹², —(CH₂)ₙNCO, —(CH₂)ₙNO₂, —(CH₂)ₙCN, —(CH₂)ₙCONR¹³R¹⁴, —(CH₂)ₙNR¹³R¹⁴, —(CH₂)ₙOZ or —(CH₂)ₙW, or (—CO)₂O or (—CO)₂NR¹⁵ which is formed by X² and Y² or X³ and Y³ bonded to each other.

Here, R¹¹ to R¹⁵ each independently represent a hydrogen atom or a hydrocarbon group having 1 to 20 carbon atoms, Z represents a hydrocarbon group or a hydrocarbon group substituted with halogen, W represents Si(R¹⁶)ₚD₍₃₋ₚ₎ (R¹⁶ represents a hydrocarbon group having 1 to 10 carbon atoms, D represents a halogen atom, —OCOR¹⁷, or —OR¹⁷ (R¹⁷ represents a hydrocarbon group having 1 to 10 carbon atoms), and p is an integer of 0 to 3). n is an integer of 0 to 10, and is preferably 0 to 8 and more preferably 0 to 6.

R³ to R⁶ are each preferably a hydrogen atom or —CH₃, and, in terms of moisture permeability, more preferably a hydrogen atom.

X² and X³ are each preferably a hydrogen atom, —CH₃, or —C₂H₅ and more preferably a hydrogen atom in terms of moisture permeability.

Y² and Y³ are each preferably a hydrogen atom, a halogen atom (particularly a chlorine atom), or —(CH₂)ₙCOOR¹¹ (particularly —COOCH₃) and more preferably a hydrogen atom in terms of moisture permeability.

Other groups are appropriately selected.

The polymer having the structural unit represented by General Formula (A-II) or (A-III) may further include at least one or more structural units represented by General Formula (A-I).

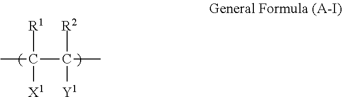

In General Formula (A-I), R¹ and R² each independently represent a hydrogen atom or a hydrocarbon group having 1 to 10 carbon atoms, and X¹ and Y¹ each independently represent a hydrogen atom, a hydrocarbon group having 1 to 10 carbon atoms, a halogen atom, a hydrocarbon group having 1 to 10 carbon atoms, which is substituted with a halogen atom, —(CH₂)ₙCOOR¹¹, —(CH₂)ₙOCOR¹², —(CH₂)ₙNCO, —(CH₂)ₙNO2, —(CH₂)ₙCN, —(CH₂)ₙCONR¹³R¹⁴, —(CH₂)ₙNR¹³R¹⁴, —(CH₂)ₙOZ, —(CH₂)ₙW, or (—CO)₂O or (—CO)₂NR¹⁵ which is formed by X¹ and Y¹ being bonded to each other.

Here, R¹¹ to R¹⁵ each independently represent a hydrogen atom or a hydrocarbon group having 1 to 20 carbon atoms, Z represents a hydrocarbon group or a hydrocarbon group substituted with a halogen, W represents Si(R¹⁶)ₚD₍₃₋ₚ₎ (R¹⁶ represents a hydrocarbon group having 1 to 10 carbon atoms, D represents a halogen atom, —OCOR¹⁷, or —OR¹⁷ (R¹⁷ represents a hydrocarbon group having 1 to 10 carbon atoms), and p is an integer of 0 to 3). n is an integer of 0 to 10.

From the viewpoint of adhesiveness, the content of the structural unit derived from the above-described norbornene compound in the cyclic polyolefin having the structural unit represented by General Formula (A-II) or (A-III) is preferably 100% by mass or less, more preferably 30% to 97% by mass, still more preferably 50% to 95% by mass, and most preferably 60% to 90% by mass with respect to the total mass of the cyclic polyolefin. Here, the proportion of the structural unit derived from a norbornene compound represents the average value in the cyclic polyolefin.

The addition (co)polymer of a norbornene compound is described in JP1998-7732A (JP-H10-7732A), JP2002-504184A, US2004/229157A1, and WO2004/070463A.

The polymer of a norbornene compound is obtained by the addition polymerization of norbornene compounds (for example, polycyclic unsaturated compounds of norbornene).

In addition, as the polymer of a norbornene compound, copolymers obtained by the addition copolymerization of, as necessary, a norbornene compound, olefin such as ethylene, propylene, and butene, conjugated diene such as butadiene and isoprene, unconjugated diene such as ethylidene norbornene, and an ethylenically unsaturated compound such as acrylonitrile, acrylic acid, methacrylic acid, maleic acid anhydride, acrylic acid ester, methacrylic acid ester, maleimide, vinyl acetate, and vinyl chloride are exemplified. Among these, a copolymer of a norbornene compound and ethylene is preferable.

Examples of the addition (co)polymers of a norbornene compound include APL8008T (Tg: 70° C.), APL6011T (Tg: 105° C.), APL6013T (Tg: 125° C.), and APL6015T (Tg: 145° C.), which are available from Mitsui Chemicals, Inc. under a product name of APEL and have glass transition temperatures (Tg) different from each other. In addition, pellets such as TOPAS8007, TOPAS6013, and TOPAS6015 are put on the market by Polyplastics Co., Ltd. Further, Appear 3000 is put on the market by Film Ferrania S. R. L.

As the polymer of a norbornene compound, commercially available products can be used. For example, polymers are put on the market by JSR Corporation under a product name of Arton G, Arton R, or Arton F, and polymers are put on the market by Zeon Corporation under a product name of Zeonor ZF14, ZF16, Zeonex 250, or Zeonex 280.

The hydride of the polymer of a norbornene compound can be synthesized by an addition polymerization or a ring-opening metathesis polymerization of a norbornene compound or the like and then an addition of hydrogen. The synthesis method is described in, for example, JP1989-240517A (JP-H1-240517A), JP1995-196736A (JP-H7-196736A), JP1985-26024A (JP-S60-26024A), JP1987-19801A (JP-S62-19801A), JP2003-159767A, JP2004-309979A, and the like.

### (Extensible Resin Component)

The transparent resin contained in the light absorption layer can appropriately select and contain a component exhibiting extensibility (also referred to as an extensible resin component) as a resin component. Specific examples thereof include an acrylonitrile-butadiene-styrene resin (an ABS resin), a styrene-butadiene resin (an SB resin), an isoprene resin, a butadiene resin, a polyether-urethane resin, and a silicone resin. Further, these resins may be further hydrogenated as appropriate.

As the extensible resin component, it is preferable to use an ABS resin or an SB resin, and it is more preferable to use an SB resin.

As the SB resin, for example, a commercially available one can be used. As such commercial products, TR2000, TR2003, and TR2250 (all, product name, manufactured by JSR Corporation), CLEAREN 210M, 220M, and 730V (all, product name, manufactured by Denka Corporation), Asaflex 800S, 805, 810, 825, 830, and 840 (all, product name, manufactured by Asahi Kasei Corporation), EPOREX SB2400, SB2610, and SB2710 (all, product name, Sumitomo Chemical Co., Ltd.), and the like can be exemplified.

The transparent resin contained in the light absorption layer preferably contains an extensible resin component in the matrix resin in an amount of 15% to 95% by mass, more preferably 20% to 50% by mass, and still more preferably 25% to 45% by mass.

As the extensible resin component, in a case where a sample having an aspect with a thickness of 30 m and a width of 10 mm is prepared by using the extensible resin component alone and the breaking elongation at 25° C. is measured in accordance with JIS 7127, a component having the breaking elongation of 10% or more is preferable, and a component having the breaking elongation of 20% or more is more preferable.

The content of the transparent resin in the light absorption layer is preferably 50% by mass or more and less than 100% by mass, more preferably 60% by mass or more and less than 100% by mass, and still more preferably 65% by mass or more and less than 100% by mass. The upper limit value thereof is also preferably 99% by mass or less, more preferably 97% by mass or less, still more preferably 95% by mass or less, and particularly preferably 90% by mass or less.

The transparent resin may be used alone or in combination of two or more kinds thereof.

In the light absorption film according to the embodiment of the present invention, it is preferable that the light absorption layer does not have a three-dimensional crosslinked structure. In a case where the light absorption layer is formed by radical polymerization of the monomer component, it is considered that the absorbance of the dye in the light absorption layer is affected. On the other hand, in the light absorption film according to the embodiment of the present invention, since the light absorption layer is produced using the light absorption layer forming liquid containing the transparent resin and the dye, the above-described influence on the dye can be suppressed.

It is preferable that the light absorption film according to the embodiment of the present invention satisfies the above-described (I), that is, the light absorption layer further contains a polymer having a boronic acid-containing group (hereinafter, also abbreviated as “boronic acid-containing polymer”). The boronic acid-containing polymer contained in the light absorption layer is unevenly distributed at the interface with the transparent gas barrier layer I in the light absorption layer, and —B—OH in the boronic acid-containing group forms a chemical bond such as a boronic acid ester with a hydrophilic group such as an —OH group in the transparent gas barrier layer I, whereby the adhesiveness can be improved.

The boronic acid-containing polymer is not included in the polymer constituting the transparent resin in the light absorption layer.

Here, the presence of the boronic acid-containing group at the interface between the light absorption layer and the transparent gas barrier layer I, or the formation of a chemical bond such as a boronic acid ester between the boronic acid-containing group and a hydrophilic group such as an —OH group in the gas barrier layer can be confirmed by, for example, time-of-flight secondary ion mass spectrometry (TOF-SIMS). Furthermore, for TOF-SIMS, the method described in “Surface Analysis Technology Library Secondary Ion Mass Spectrometry” edited by the Surface Science Society of Japan and published by Maruzen Co., Ltd. (published in 1999) can be adopted. Specifically, a fragment derived from a chemical bond such as a boronic acid ester formed between the boronic acid-containing group and a hydrophilic group such as an —OH group in the gas barrier layer is detected.

In the present invention, “the light absorption layer further contains a polymer having a boronic acid-containing group” includes not only a form in which the light absorption layer contains a polymer having a boronic acid-containing group, but also a form in which the boronic acid-containing group of the polymer having a boronic acid-containing group is used to form a chemical bond with a hydrophilic group such as an —OH group in the transparent gas barrier layer I.

In addition, in the present invention, the “boronic acid-containing group” is not limited to a group represented by —B(OH)₂, and means a group represented by —B(U^{b1}R^{b2})(U^{b2}R^{b3}) in General Formula (B).

### (Constitutional Unit Having Boronic Acid-Containing Group)

The boronic acid-containing polymer preferably includes a constitutional unit having a boronic acid-containing group, represented by General Formula (B).

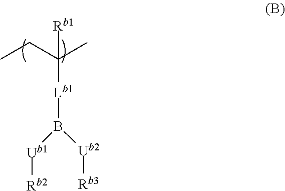

In Formula (B), R^{b1} represents a hydrogen atom, a fluorine atom, a chlorine atom, or an alkyl group having 1 to 20 carbon atoms.

In addition, L^{b1} represents a single bond or a divalent linking group.

Moreover, U^{b1} and U^{b2} each independently represent —O—, —S—, —COO—, —OCO—, —CONH—, —NHCOO—, or —NH—.

In addition, R^{b2} and R^{b3} each independently represent a hydrogen atom, a substituted or unsubstituted aliphatic hydrocarbon group, a substituted or unsubstituted aryl group, or a substituted or unsubstituted heteroaryl group. However, R^{b2} and R^{b3} may be bonded to each other through a linking group.

In Formula (B), as the alkyl group having 1 to 20 carbon atoms, represented by one aspect of R^{b1}, an alkyl group having 1 to 10 carbon atoms is preferable, an alkyl group having 1 to 8 carbon atoms (for example, a methyl group, an ethyl group, a propyl group, an isopropyl group, an n-butyl group, an isobutyl group, a sec-butyl group, a t-butyl group, and a cyclohexyl group) is more preferable, an alkyl group having 1 to 4 carbon atoms is still more preferable, and the methyl group or the ethyl group is particularly preferable.

R^{b1} preferably represents a hydrogen atom or a methyl group.

In Formula (B), examples of the divalent linking group represented by one aspect of L^{b1} include a divalent linking group selected from the group consisting of —O—, —S—, —COO—, —OCO—, —CONR^{b4}—, —NR^{b4}COO—, —CR^{b4}N—, a substituted or unsubstituted divalent aliphatic group, a substituted or unsubstituted divalent aromatic group, and a combination thereof, and R^{b4} represents a hydrogen atom or an alkyl group having 1 to 20 carbon atoms. In addition, specific examples of the substituent which may be contained in the divalent aliphatic group or the like include the same ones as the specific examples described in the substituent group Y which will be described later, and specific examples of R^{b4} include the same ones as the specific examples of R^{b1}.

Among these divalent linking groups, a divalent linking group selected from the group consisting of —O—, —COO—, —OCO—, —CONR⁹—, —NR⁹COO—, a substituted or unsubstituted divalent aliphatic group, a substituted or unsubstituted divalent aromatic group, and a combination thereof is preferable, and specific examples thereof include preferably a —COO-substituted or unsubstituted divalent aliphatic group-O-substituted or unsubstituted divalent aromatic group-COO-substituted or unsubstituted divalent aromatic group-.

In a case where L^{b1} includes a substituted or unsubstituted divalent aromatic group, the number of aromatic rings is preferably 1 to 3 and more preferably 1 or 2.

In Formula (B), U^{b1} and U^{b2} each independently represent —O—, —S—, —COO—, —OCO—, —CONH—, —NHCOO—, or —NH, as mentioned above, and is preferably —O— or —NH—, and more preferably —O—.

In Formula (B), examples of the substituted or unsubstituted aliphatic hydrocarbon group represented by one aspect of R^{b2} and R^{b3} include an alkyl group, an alkenyl group, or an alkynyl group, each of which may have a substituent.

Specific examples of the alkyl group include linear, branched, or cyclic alkyl groups such as a methyl group, an ethyl group, a propyl group, a butyl group, a pentyl group, a hexyl group, a heptyl group, an octyl group, a nonyl group, a decyl group, an undecyl group, a dodecyl group, a tridecyl group, a hexadecyl group, an octadecyl group, an eicosyl group, an isopropyl group, an isobutyl group, a sec-butyl group, a tert-butyl group, an isopentyl group, a neopentyl group, a 1-methylbutyl group, an isohexyl group, a 2-methylhexyl group, a cyclopentyl group, a cyclohexyl group, a 1-adamantyl group, and a 2-norbornyl group.

Specific examples of the alkenyl group include linear, branched, or cyclic alkenyl groups such as a vinyl group, a 1-propenyl group, a 1-butenyl group, a 1-methyl-1-propenyl group, a 1-cyclopentenyl group, and a 1-cyclohexenyl group.

Specific examples of the alkynyl group include an ethynyl group, a 1-propynyl group, a 1-butynyl group, and a 1-octynyl group.

In addition, examples of the substituted or unsubstituted aryl group represented by one aspect of R^{b2} and R^{b3} include those in which 1 to 4 benzene rings form a fused ring and those in which a benzene ring and an unsaturated five-membered ring form a fused ring, and specific examples thereof include a phenyl group, a naphthyl group, an anthryl group, a phenanthryl group, an indenyl group, an acenaphthenyl group, a fluorenyl group, and a pyrenyl group.

Moreover, examples of the substituted or unsubstituted heteroaryl group represented by one aspect of R^{b2} and R^{b3} include a heteroaryl group obtained by removing one hydrogen atom on an aromatic heterocyclic ring including one or more heteroatoms selected from the group consisting of a nitrogen atom, an oxygen atom, and a sulfur atom.

Specific examples of the aromatic heterocyclic ring including one or more heteroatoms selected from the group consisting of a nitrogen atom, an oxygen atom, and a sulfur atom include pyrrole, furan, thiophene, pyrazole, imidazole, triazole, oxazole, isoxazole, oxadiazole, thiazole, thiadiazole, indole, carbazole, benzofuran, dibenzofuran, thianaphthene, dibenzothiophene, indazole, benzimidazole, benzisoxazole, benzoxazole, benzothiazole, purine, pyridine, pyridazine, pyrimidine, pyrazine, triazine, quinoline, acridine, isoquinoline, phthalazine, quinazoline, quinoxaline, naphthyridine, phenanthroline, and pteridine.

Examples of the substituents which may be contained in R^{b2} and R^{b3} include monovalent non-metal atomic groups from which hydrogen is removed, and are selected from the following substituent group Y, for example.

### (Substituent Group Y)

A halogen atom (—F, —Br, —Cl, and —I), a hydroxy group, an alkoxy group, an aryloxy group, a mercapto group, an alkylthio group, an arylthio group, an alkyldithio group, an aryldithio group, an amino group, an N-alkylamino group, an N,N-dialkylamino group, an N-arylamino group, an N,N-diarylamino group, an N-alkyl-N-arylamino group, an acyloxy group, a carbamoyloxy group, an N-alkylcarbamoyloxy group, an N-arylcarbamoyloxy group, an N,N-dialkylcarbamoyloxy group, an N,N-diarylcarbamoyloxy group, an N-alkyl-N-arylcarbamoyloxy group, an alkylsulfoxy group, an arylsulfoxy group, an acylthio group, an acylamino group, an N-alkylacylamino group, an N-arylacylamino group, a ureide group, an N′-alkylureide group, an N′,N′-dialkylureide group, an N′-arylureide group, an N′,N′-diarylureide group, an N′-alkyl-N′-arylureide group, an N-alkylureide group, an N-arylureide group, an N′-alkyl-N-alkylureide group, an N′-alkyl-N-arylureide group, an N′,N′-dialkyl-N-alkylureide group, an N′,N′-dialkyl-N-arylureide group, an N′-aryl-N-alkylureide group, an N′-aryl-N-arylureide group, an N′,N′-diaryl-N-alkylureide group, an N′,N′-diaryl-N-arylureide group, an N′-alkyl-N′-aryl-N-alkylureide group, an N′-alkyl-N′-aryl-N-arylureide group, an alkoxycarbonylamino group, an aryloxycarbonylamino group, an N-alkyl-N-alkoxycarbonylamino group, an N-alkyl-N-aryloxycarbonylamino group, an N-aryl-N-alkoxycarbonylamino group, an N-aryl-N-aryloxycarbonylamino group, a formyl group, an acyl group, a carboxy group and a conjugate base group thereof, an alkoxycarbonyl group, an aryloxycarbonyl group, a carbamoyl group, an N-alkylcarbamoyl group, an N,N-dialkylcarbamoyl group, an N-arylcarbamoyl group, an N,N-diarylcarbamoyl group, an N-alkyl-N-arylcarbamoyl group, an alkylsulfinyl group, an arylsulfinyl group, an alkylsulfonyl group, an arylsulfonyl group, a sulfo group (—SO₃H) and a conjugate base group thereof, an alkoxysulfonyl group, an aryloxysulfonyl group, sulfinamoyl group, an N-alkylsulfinamoyl group, an N,N-dialkylsulfinamoyl group, an N-arylsulfinamoyl group, an N,N-diarylsulfinamoyl group, an N-alkyl-N-arylsulfinamoyl group, a sulfamoyl group, an N-alkylsulfamoyl group, an N,N-dialkylsulfamoyl group, an N-arylsulfamoyl group, an N,N-diarylsulfamoyl group, an N-alkyl-N-arylsulfamoyl group, an N-acylsulfamoyl group and a conjugate base group thereof, an N-alkylsulfonylsulfamoyl group (—SO₂NHSO₂(alkyl)) and a conjugate base group thereof, an N-arylsulfonylsulfamoyl group (—SO₂NHSO₂ (aryl)) and a conjugate base group thereof, an N-alkylsulfonylcarbamoyl group (—CONHSO₂ (alkyl)) and a conjugate base group thereof, an N-arylsulfonylcarbamoyl group (—CONHSO₂(aryl)) and a conjugate base group thereof, an alkoxysilyl group (—Si(O-alkyl)₃), an aryloxysilyl group (—Si(O-aryl)₃), a hydroxysilyl group (—Si(OH)₃) and a conjugate base group thereof, a phosphono group (—PO₃H₂) and a conjugate base group thereof, a dialkylphosphono group (—PO₃(alkyl)₂), a diarylphosphono group (—PO₃(aryl)₂), an alkylarylphosphono group (—PO₃(alkyl)(aryl)), a monoalkylphosphono group (—PO₃H(alkyl)) and a conjugate base group thereof, a monoarylphosphono group (—PO₃H(aryl)) and a conjugate base group thereof, a phosphonooxy group (—OPO₃H₂) and a conjugate base group thereof, a dialkylphosphonooxy group (—OPO₃(alkyl)₂), a diarylphosphonooxy group (—OPO₃(aryl)₂), an alkylarylphosphonooxy group (—OPO₃(alkyl)(aryl)), a monoalkylphosphonooxy group (—OPO₃H(alkyl)) and a conjugated base group thereof, a monoarylphosphonooxy group (—OPO₃H(aryl)) and a conjugated base group thereof, a cyano group, a nitro group, an aryl group, an alkenyl group and an alkynyl group. In addition, these substituents may be bonded to each other or bonded to a hydrocarbon group which is substituted to form a ring, as possible.

R^{b2} and R^{b3} in Formula (B) are each preferably the hydrogen atom, the substituted or unsubstituted alkyl group, or the substituted or unsubstituted aryl group, more preferably the hydrogen atom or the substituted or unsubstituted alkyl group, and still more preferably the hydrogen atom or both linked to each other through an alkylene linking group.

Specific examples of the monomer forming the repeating unit represented by Formula (B) include monomers represented by Formulae 3-1 to 3-26.

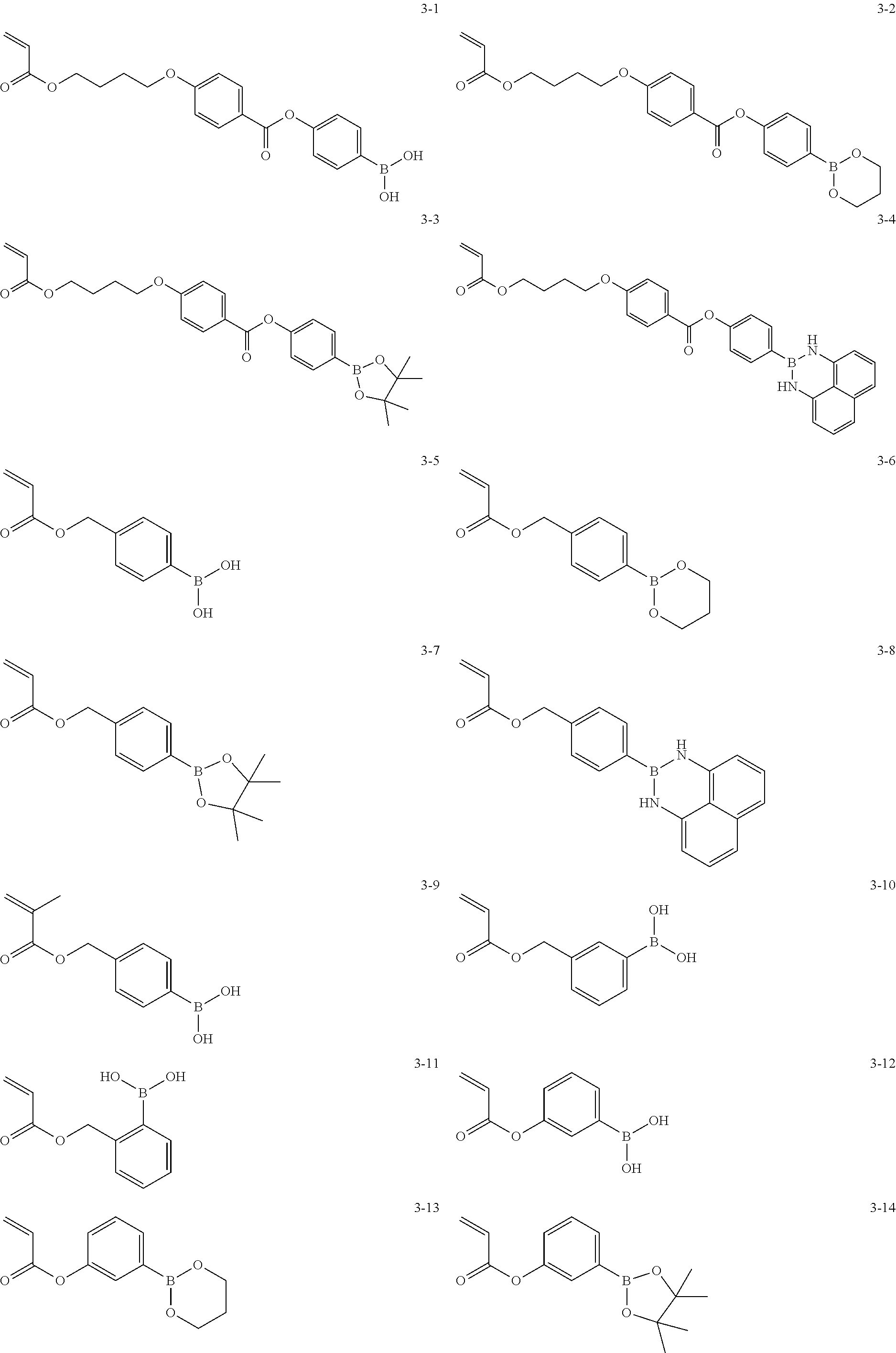

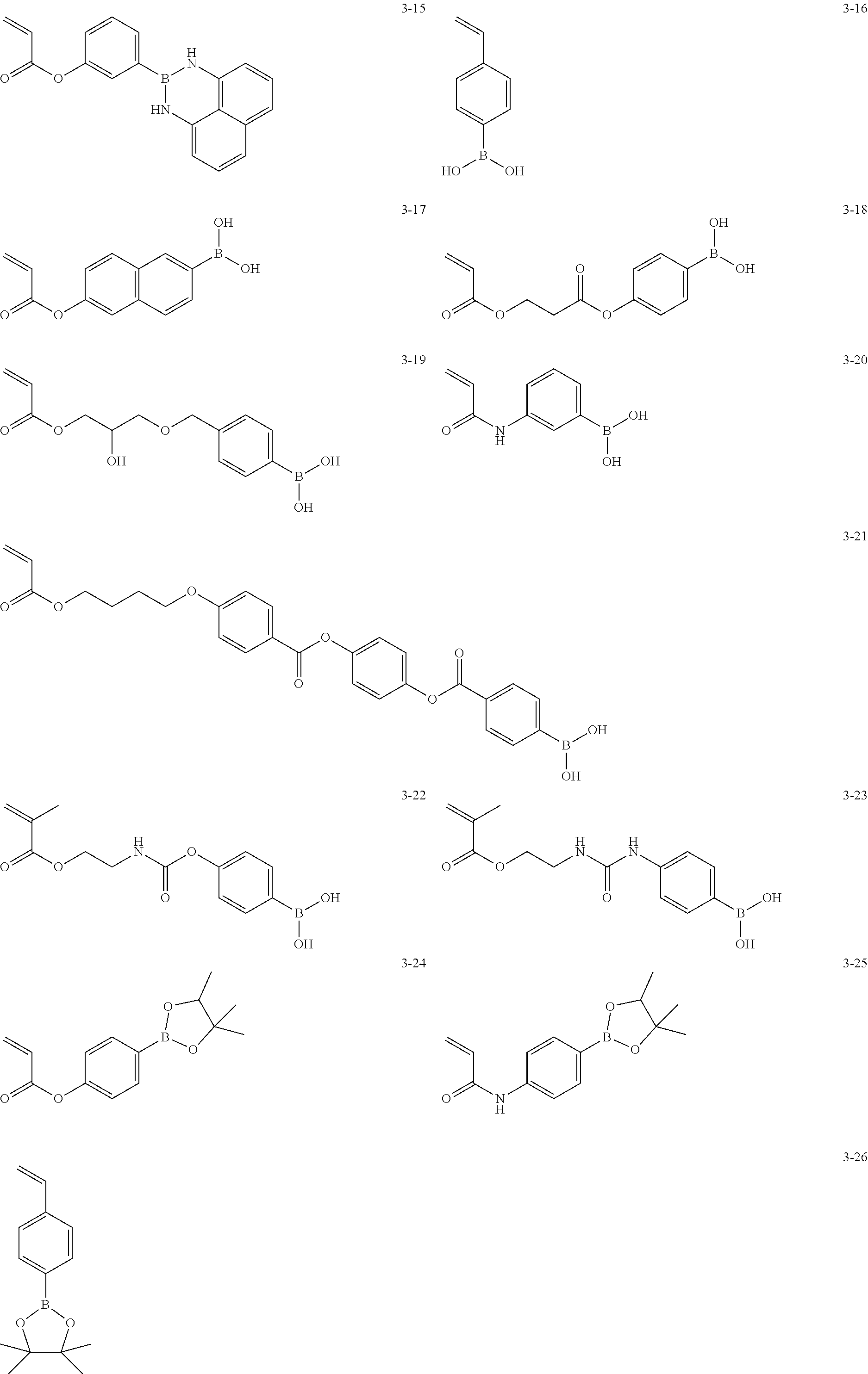

In a case where the total of all constitutional units of the boronic acid-containing polymer is set to 100% by mass, a content of the constitutional unit having a boronic acid-containing group represented by General Formula (B) in the boronic acid-containing polymer is preferably 10% to 80% by mass, more preferably 20% to 70% by mass, and still more preferably 25% to 60% by mass.

The constitutional unit having a boronic acid-containing group represented by General Formula (B) may be used alone or in combination of two or more kinds thereof.

The boronic acid-containing polymer preferably has a constitutional unit represented by General Formula (F) in addition to the constitutional unit having a boronic acid-containing group represented by General Formula (B).

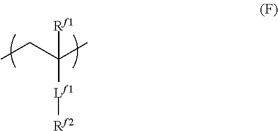

In Formula (F), R^{f1} represents a hydrogen atom, a chlorine atom, or an alkyl group having 1 to 20 carbon atoms.

In addition, L^{f1} represents a single bond or a divalent linking group.

Moreover, R² represents a group including at least one group of (a), (b), or (c) below.
(a) a group represented by any of Formulae (1) to (3) and (1H)
(b) a polyether group
(c) an alkyl group having 1 to 20 carbon atoms, which has a hydrogen bond between a proton-donating functional group and a proton-accepting functional group

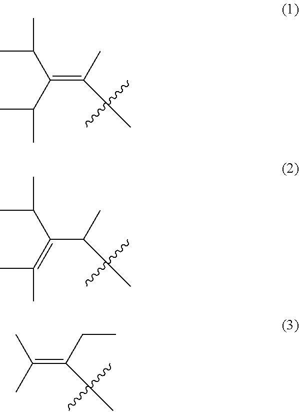

The wavy line in Formulae (1) to (3) indicates a bonding site. In addition, a group (referred to as “group represented by Formula (1H)”) in which both of two isopropyl groups in the group represented by Formula (1) are replaced with a hydrogen atom is also an exemplary example of the group (a).

In Formula (F), examples of the alkyl group having 1 to 20 carbon atoms, represented by one aspect of R^{f}, include the same ones as those of the alkyl group having 1 to 20 carbon atoms, represented by one aspect of R^{b1} in Formula (B). Among those, an alkyl group having 1 to 4 carbon atoms is preferable, and a methyl group or an ethyl group is particularly preferable.

R^{f1} preferably represents a hydrogen atom or a methyl group.

Examples of the divalent linking group represented by one aspect of L^{f1} in Formula (F) include the same ones as those of the divalent linking group represented by one aspect of L^{b1} in Formula (B). Among those, —O—, —CO—O—, —CO—NH—, and —O—CO— are preferable.

In Formula (F), R^{f2} represents a group including at least one group of (a), (b), or (c).

### (a) a Constitutional Unit Having a Group Represented by Formula (1), (1H), (2), or (3)

In a case where R^{f1} in Formula (F) includes the group represented by Formula (1), (1H), (2), or (3), it is also preferable that Formula (F) represents a constitutional unit represented by Formula (4).

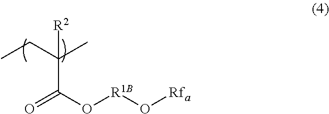

In Formula (4), Rfₐ is the group represented by Formula (1), (1H), (2), or (3).

In Formula (4), R^{1B} is a divalent group having 2 to 50 carbon atoms. The divalent group having 2 to 50 carbon atoms represented by R^{1B} may have a heteroatom and may be an aromatic group, a heteroaromatic group, a heterocyclic group, an aliphatic group, or an alicyclic group.

Specific examples of R^{1B} include the following groups. At least one hydrogen atom in CH₂ of the following groups may be replaced with a hydroxy group.

—(CH₂)ₙ₁— (n1=2 to 50)

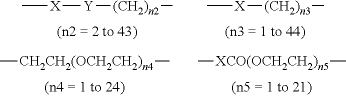

In the formulae, X represents phenylene, biphenylene, or naphthylene, which may have 1 to 3 substituents selected from an alkyl group having 1 to 3 carbon atoms (a methyl group, an ethyl group, or a propyl group) or an alkoxy group having 1 to 4 carbon atoms (a methoxy group, an ethoxy group, a propoxy group, a butoxy group, or the like). Y represents —O—CO—, —CO—O—, —CONH—, or —NHCO—.

X preferably represents 1,2-phenylene, 1,3-phenylene, or 1,4-phenylene, and more preferably represents 1,4-phenylene.

Specific examples of a particularly preferable divalent group having 2 to 50 carbon atoms represented by R^{1B} include divalent groups having the following structures. At least one hydrogen atom in CH₂ of the following groups may be replaced with a hydroxy group.

—(CH₂)ₙ₁— (n1=2 to 10)

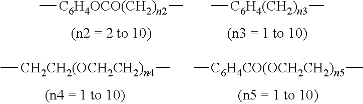

In Formula (4), R² is a hydrogen atom or a methyl group.

### (b) a Constitutional Unit Having a Polyether Group

In Formula (F), it is also preferable that R^{f1} has a polyether group.

The polyether group is a divalent group in which a plurality of hydrocarbon groups are bonded by an ether bond. The polyether group is preferably a divalent group in which a plurality of alkylene groups are bonded by an ether bond.

The polyether group may have a linear structure, a branched structure, or a cyclic structure, and preferably have a linear structure or a branched structure and more preferably have a linear structure.

In a case where Formula (F) includes a constitutional unit in which R^{f1} contains a polyether group, Formula (F) is preferably a constitutional unit represented by Formula (I-b).

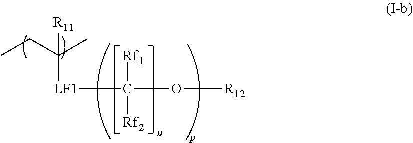

In Formula (I-b), LF1 has the same meaning as L^{f1} in Formula (F). R₁₁ represents a hydrogen atom, a chlorine atom, or an alkyl group having 1 to 20 carbon atoms. Rf₁ and Rf₂ each independently represent a hydrogen atom or an alkyl group. In a case where a plurality of Rf₁'s are present, the plurality of Rf₁'s may be the same as or different from each other. In a case where a plurality of Rf₂'s are present, Rf₂'s may be the same or different from each other. u represents an integer of 1 or more. p represents an integer of 1 or more.

R₁₂ represents a hydrogen atom or a substituent, and the substituent is not particularly limited, and examples thereof include an alkyl group (preferably having 1 to 10 carbon atoms) and a hydroxyalkyl group (preferably having 1 to 10 carbon atoms).

In Formula (I-b), u represents an integer of 1 or more, preferably represents an integer of 1 to 10, more preferably represents an integer of 1 to 6, and still more preferably represents an integer of 1 to 3.

In Formula (I-b), p represents an integer of 1 or more, preferably represents an integer of 1 to 100, more preferably represents an integer of 1 to 80, and still more preferably represents an integer of 1 to 60.

p pieces of [C(Rf₁)(Rf₂)]ᵤO's may be the same or different from each other.

(c) an Alkyl Group Having 1 to 20 Carbon Atoms, which has a Hydrogen Bond Between a Proton-Donating Functional Group and a Proton-Accepting Functional Group

In Formula (F), it is also preferable that R^{f1} has an alkyl group having 1 to 20 carbon atoms, which has a hydrogen bond between a proton-donating functional group and a proton-accepting functional group.

The compound having a proton-donor functional group and the compound having a proton-acceptor functional group is preferably a compound represented by any of Formulae (1-1) to (1-3).

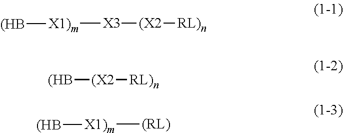

In Formulae (1-1) and (1-3), m represents an integer of 1 to 5. Further, in Formulae (1-1) and (1-2), n represents an integer of 1 to 5. However, the sum of m and n is an integer of 2 to 6.

Further, in Formulae (1-1) to (1-3), HB represents the above-described functional group capable of hydrogen bonding (that is, a proton-donating functional group and a proton-accepting functional group), and in a case where m represents an integer of 2 to 5, a plurality of HB's may be the same as or different from each other.

Examples of the proton-donating functional group include a carboxy group and a sulfonic acid group.

Examples of the proton-accepting functional group include a group having a nitrogen atom.

Moreover, in Formulae (1-1) to (1-3), X1 and X2 each independently represent a single bond or a divalent linking group; in a case where m is an integer of 2 to 5, the plurality of X1's may be the same as or different from each other; and in a case where n is an integer of 2 to 5, the plurality of X2's may be the same as or different from each other. In Formula (1-2), a part of HB and X2 may form a ring. Further, in Formula (1-3), a part of RL and X1 may form a ring.

Examples of the divalent linking group represented by one aspect of X1 and X2 in Formulae (1-1) to (1-3) include at least one or more groups selected from the group consisting of a linear, branched, or cyclic alkylene group having 1 to 10 carbon atoms which may have a substituent, an arylene group having 6 to 12 carbon atoms which may have a substituent, an ether group (—O—), a carbonyl group (—C(═O)—), and an imino group (—NH—) which may have a substituent.

Here, examples of the substituent that the alkylene group, the arylene group, and the imino group may have include an alkyl group, an alkoxy group, a halogen atom, and a hydroxyl group. As the alkyl group, for example, a linear, branched, or cyclic alkyl group having 1 to 18 carbon atoms is preferable, an alkyl group having 1 to 8 carbon atoms (such as a methyl group, an ethyl group, a propyl group, an isopropyl group, an n-butyl group, an isobutyl group, a sec-butyl group, a t-butyl group, or a cyclohexyl group) is more preferable, an alkyl group having 1 to 4 carbon atoms is still more preferable, and a methyl group or an ethyl group is particularly preferable. As the alkoxy group, for example, an alkoxy group having 1 to 18 carbon atoms is preferable, an alkoxy group having 1 to 8 carbon atoms (such as a methoxy group, an ethoxy group, an n-butoxy group, or a methoxyethoxy group) is more preferable, an alkoxy group having 1 to 4 carbon atoms is still more preferable, and a methoxy group or an ethoxy group is particularly preferable. Examples of the halogen atom include a fluorine atom, a chlorine atom, a bromine atom, and an iodine atom. Among these, a fluorine atom and a chlorine atom are preferable.

In regard to the linear, branched, or cyclic alkylene group having 1 to 10 carbon atoms, specific examples of the linear alkylene group include a methylene group, an ethylene group, a propylene group, a butylene group, a pentylene group, a hexylene group, and a decylene group. In addition, specific examples of the branched alkylene group include a dimethylmethylene group, a methylethylene group, a 2,2-dimethylpropylene group, and a 2-ethyl-2-methylpropylene group. Further, specific examples of the cyclic alkylene group include a cyclopropylene group, a cyclobutylene group, a cyclopentylene group, a cyclohexylene group, a cyclooctylene group, a cyclodecylene group, an adamantane-diyl group, a norbornane-diyl group, and an exo-tetrahydrodicyclopentadiene-diyl group.

Specific examples of the arylene group having 6 to 12 carbon atoms include a phenylene group, a xylylene group, a biphenylene group, a naphthylene group, and a 2,2′-methylenebisphenyl group. Among these, a phenylene group is preferable.

In addition, in Formula (1-1), X3 represents a single bond or a divalent to hexavalent linking group. Here, examples of the divalent linking group represented by one aspect of X3 include those described as the divalent linking group represented by one aspect of X1 and X2 in Formulae (1-1) to (1-3). In addition, examples of the trivalent to hexavalent linking group represented by one aspect of X3 include structures obtained by removing three to six hydrogen atoms bonded to carbon atoms forming a ring in ring structures, for example, a cycloalkylene ring such as a cyclohexane ring or a cyclohexene ring, an aromatic hydrocarbon ring such as a benzene ring, a naphthalene ring, an anthracene ring, or a phenanthroline ring, and an aromatic heterocyclic ring such as a furan ring, a pyrrole ring, a thiophene ring, a pyridine ring, a thiazole ring, or a benzothiazole ring. Among these ring structures, the benzene ring (for example, a benzen-1,2,4-yl group) is preferable.

In addition, in Formulae (1-1) to (1-3), RL represents an alkyl group having 1 to 20 carbon atoms, and in a case where n is an integer of 2 to 5, a plurality of RL's may be the same or different from each other.

Among the compounds represented by any of Formulae (1-1) to (1-3), as the compound having a proton-donating functional group, specifically, for example, the compound represented by Formulae.

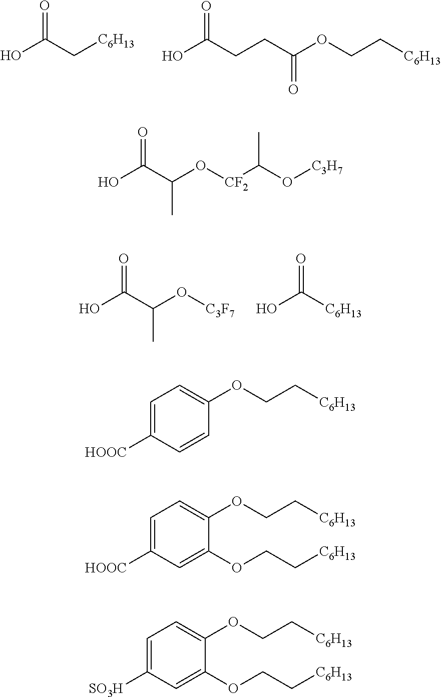

In addition, specific examples of the compound having a proton-acceptor functional group among the compounds represented by any of Formulae (1-1) to (1-3) include compounds represented by Formulae.

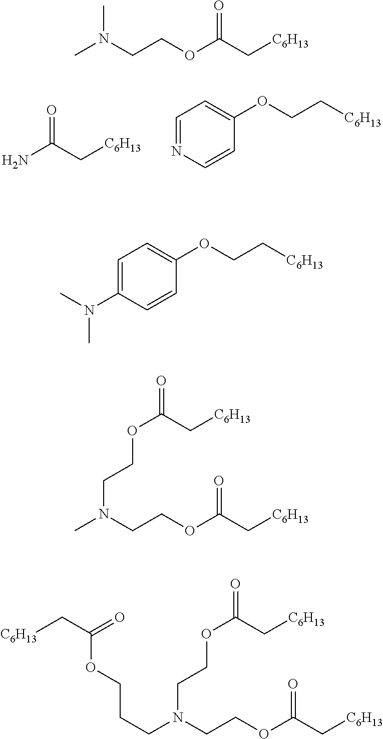

In a case where the total of all constitutional units of the boronic acid-containing polymer is set to 100% by mass, a content of the constitutional unit represented by General Formula (F) in the boronic acid-containing polymer is preferably 20% to 90% by mass, more preferably 30% to 80% by mass, and still more preferably 40% to 75% by mass.

The constitutional unit represented by General Formula (F) may be used alone or in combination of two or more kinds thereof.

The boronic acid-containing polymer may further have a constitutional unit (other constitutional units) other than the constitutional unit having a boronic acid-containing group, represented by General Formula (B), and the constitutional unit represented by General Formula (F). Examples of the other constitutional units include the above-described constitutional unit having an alkyl group having 1 to 14 carbon atoms.

In a case where the total of all constitutional units of the boronic acid-containing polymer is set to 100% by mass, a content of the other constitutional units in the boronic acid-containing polymer is preferably 0% to 40% by mass, more preferably 0% to 35% by mass, and still more preferably 0% to 30% by mass.

One kind of the other constitutional units may be used alone, or two or more kinds thereof may be used in combination.

A content of the boronic acid-containing polymer in the light absorption layer is preferably 0.5% to 40% by mass, more preferably 2% to 40% by mass, and still more preferably 3% to 30% by mass.

The boronic acid-containing polymer may be used alone or in combination of two or more kinds thereof.

### <Dye>

It is preferable that the light absorption layer contains a dye, and the dye is dispersed (preferably dissolved) in the resin.

The type, combination, content ratio, and the like of the dye can be appropriately adjusted according to a desired function such as suppression of external light reflection.

As the dye, a dye used in a display device can be used without particular limitation, and examples thereof include coloring agents (dyes) of pyrrole methine (PM), rhodamine (RH), boron dipyrromethene (BODIPY), squaraine (SQ), tetraazaporphyrin (TAP), cyanine (CY), indoaniline, anthraquinone, porphyrin, and pyrrolo-pyrrole.

Preferred examples of the pyrrole methine dye include a coloring agent (dye) represented by General Formula (A1) from the viewpoint that an absorption waveform at a maximal absorption wavelength at which a maximum absorbance is exhibited is sharp. As the coloring agent represented by General Formula (A1), the description of the coloring agents represented by General Formula (A1) or (A2) and specific examples described in paragraphs [0022] to [0066] of WO2022/138925A can be applied as they are.

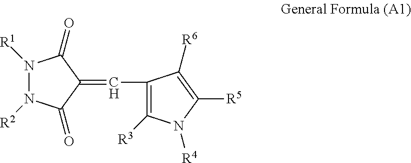

In Formula (A1), R¹ and R² each independently represent an alkyl group or an aryl group, R³ to R⁶ each independently represent a hydrogen atom or a substituent, and R⁵ and R⁶ may be bonded to each other to form a 6-membered ring.

With regard to definition and a preferred range of each substituent in General Formula (A1), each of descriptions related to each substituent of coloring agents represented by General Formula (A1) described in WO2022/138925A can be applied unless otherwise specified.

The squaraine dye is preferably used from the viewpoint that an absorption waveform at a maximal absorption wavelength at which a maximum absorbance is exhibited is sharp, and preferred examples thereof include a coloring agent (dye) represented by General Formula (1). As the coloring agent represented by General Formula (1), the description regarding the tautomer structure described in paragraphs [0020] to [0114] of WO2021/132674A, a squaraine-based coloring agent represented by any of General Formulae (1) to (9), a quencher-embedded coloring agent, and specific examples thereof, and the description of a squaraine-based coloring agent represented by General Formula (14) and specific examples described in paragraphs [0116] to [0126] of WO2022/138925A can be applied as they are. In addition, a dye C-121 used in Examples described later can also be preferably used.

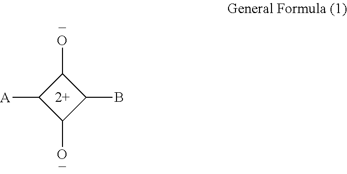

In Formula (1), A and B each independently represent an aryl group which may have a substituent, a heterocyclic group which may have a substituent, or —CH=G. G represents a heterocyclic group which may have a substituent.

With regard to definition and a preferred range of each substituent in General Formula (1), each of descriptions related to each substituent of coloring agents represented by General Formula (1) described in WO2021/132674A can be applied unless otherwise specified.

Preferred examples of the pyrrolopyrrole dye include a coloring agent (dye) represented by General Formula (D1) from the viewpoint that the absorption waveform at the maximal absorption wavelength at which the maximum absorbance is exhibited is sharp. As the coloring agent represented by General Formula (D1), the description of the coloring agents represented by any of General Formulae (D1) to (D3) and the specific examples described in paragraphs [0164] to [0197] of WO2021/14973A can be applied as they are.

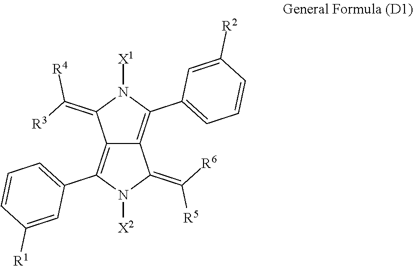

In Formula (D1), R¹ and R² each independently represent a substituent, R³ to R⁶ each independently represent a hydrogen atom or a substituent, R³ and R⁴, and R⁵ and R⁶ may be bonded to each other to form a ring, and X¹ and X² each independently represent a hydrogen atom or a substituent.

With regard to definition and a preferred range of each substituent in General Formula (D1), each of descriptions related to each substituent of coloring agents represented by General Formula (D1) described in WO2021/14973A can be applied unless otherwise specified.

In addition, as the above-described dye, an azo dye represented by any of General Formulae (i) to (iv) can also be used.

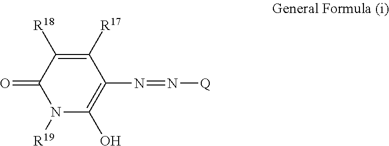

In the formula, R17 and R¹⁸ each independently represent a hydrogen atom or a monovalent substituent.

R¹⁹ represents a hydrogen atom, an aliphatic group, an aryl group, a heterocyclic group, a carbamoyl group, an alkoxycarbonyl group, an aryloxycarbonyl group, an acyl group, an alkylsulfonyl group, an arylsulfonyl group, or a sulfamoyl group.

Q represents a diazo component residue.

However, R17 to R19 and Q do not have a squaraine structure.

The above-described squaraine structure means a structure of a squaraine coloring agent. The squaraine coloring agent is a coloring agent having a structure that has a skeleton derived from squaric acid in a central part of a π-conjugated system. Examples thereof include the above-described squaraine coloring agent represented by General Formula (1).

Examples of the monovalent substituent that can be adopted as R¹⁷ and R¹⁸ include a halogen atom, an aliphatic group, an aryl group, a heterocyclic group, a cyano group, a carboxy group, a carbamoyl group, an aliphatic oxycarbonyl group, an aryloxycarbonyl group, an acyl group, a hydroxy group, an aliphatic oxy group, an aryloxy group, an acyloxy group, a carbamoyloxy group, a heterocyclic oxy group, an amino group (—NH₂), an aliphatic amino group, an arylamino group, a heterocyclic amino group, an acylamino group, a carbamoylamino group, a sulfamoylamino group, an aliphatic oxycarbonylamino group, an aryloxycarbonylamino group, an aliphatic sulfonylamino group, an arylsulfonylamino group, a nitro group, an aliphatic thio group, an arylthio group, an aliphatic sulfonyl group, an arylsulfonyl group, a sulfamoyl group, a sulfo group, an imide group, and a heterocyclic thio group. Among these, an aliphatic group, an aryl group, a heterocyclic group, a cyano group, a carbamoyl group, an aliphatic oxycarbonyl group, an aryloxycarbonyl group, an acyl group, an aliphatic oxy group, an aryloxy group, an aliphatic amino group, or an arylamino group is preferable mainly from the viewpoint of imparting solubility.

The substituents that can be adopted as R¹⁷ and R¹⁸ may be further substituted.

The aliphatic group that can be adopted as R¹⁷ to R¹⁹ may further have a monovalent substituent, may be saturated or unsaturated, and may be cyclic. Specific examples thereof include an alkyl group, a substituted alkyl group, an alkenyl group, a substituted alkenyl group, an alkynyl group, a substituted alkynyl group, an aralkyl group, and a substituted aralkyl group. The total number of carbon atoms in the aliphatic group is preferably 1 to 30 and more preferably 1 to 16. Specific examples of the aliphatic group include a methyl group, an ethyl group, a butyl group, an isopropyl group, a t-butyl group, a hydroxyethyl group, a methoxyethyl group, a cyanoethyl group, a trifluoromethyl group, a 3-sulfopropyl group, a 4-sulfobutyl group, a 2-(2-hydroxyethoxy)ethyl group, a 2-(2-(acetyloxy)ethoxy)ethyl group, a cyclohexyl group, a benzyl group, a 2-phenethyl group, a vinyl group, and an allyl group.

It is noted that Examples of the monovalent substituent which may be contained include the monovalent substituents that can be adopted as R¹⁷ and R¹⁸, and the same applies to the following description regarding the monovalent substituent which may be contained. The monovalent substituent which may be contained is, for example, preferably an alkoxy group, an acyloxy group, or a hydroxy group. In addition, this substituent may further have a substituent, and preferred examples thereof include an alkoxy group, an acyloxy group, and a hydroxy group.

The aryl group that can be adopted as R¹⁷ to R¹⁹ may further have a monovalent substituent, and the aryl group is preferably an aryl group having a total number of carbon atoms of 6 to 30, and more preferably an aryl group having a total number of carbon atoms of 6 to 16. Specific examples thereof include a phenyl group, a 4-tolyl group, a 4-methoxyphenyl group, a 2-chlorophenyl group, a 3-(3-sulfopropylamino)phenyl group, a 4-sulfamoylphenyl group, a 4-(ethoxyethylsulfamoyl)phenyl group, and a 3-(dimethylcarbamoyl)phenyl group.

The heterocyclic group that can be adopted as R¹⁷ to R¹⁹ may be a saturated or unsaturated aliphatic ring group or may be an aromatic ring group, and it is preferably an aromatic heterocyclic group. Examples of the ring-constituting atom constituting the heterocyclic group include those containing at least any one of a heteroatom such as a nitrogen atom, a sulfur atom, or an oxygen atom, where the heterocyclic group may further have a monovalent substituent. The heterocyclic group is preferably a heterocyclic group having a total number of carbon atoms of 1 to 30, and more preferably a heterocyclic group having a total number of carbon atoms of 1 to 15. Specific examples thereof include a 2-pyridyl group, a 2-thienyl group, a 2-thiazolyl group, a 2-benzothiazolyl group, a 2-benzoxazolyl group, and a 2-furyl group.

The carbamoyl group that can be adopted as R¹⁷ to R¹⁹ includes, in addition to an unsubstituted carbamoyl group (—CONH₂), a carbamoyl group substituted with an aliphatic group, an aryl group, or the like.

The carbamoyl group that can be adopted as R¹⁷ to R¹⁹ may further have a monovalent substituent, and the carbamoyl group is preferably a carbamoyl group having a total number of carbon atoms of 1 to 30, and more preferably a carbamoyl group having 1 to 16 carbon atoms. Specific examples thereof include a methylcarbamoyl group, a dimethylcarbamoyl group, a phenylcarbamoyl group, and an N-methyl-N-phenylcarbamoyl group.

To the aliphatic group in the aliphatic oxycarbonyl group that can be adopted as R¹⁷ and R¹⁸, the description of the aliphatic group that can be adopted as R¹⁷ to R¹⁹ can be applied.

The aliphatic oxycarbonyl group that can be adopted as R¹⁷ and R¹⁸ may further have a monovalent substituent, may be saturated or unsaturated, or may be cyclic, and the aliphatic oxycarbonyl group is preferably an aliphatic oxycarbonyl group having a total number of carbon atoms of 2 to 30, and more preferably an aliphatic oxycarbonyl group having a total number of carbon atoms of 2 to 16. Specific examples thereof include a methoxycarbonyl group, an ethoxycarbonyl group, and a 2-methoxyethoxycarbonyl group.

The alkoxycarbonyl group that can be adopted as R¹⁹ may further have a monovalent substituent, may be saturated or unsaturated, or may be cyclic, and the alkoxycarbonyl group is preferably an alkoxycarbonyl group having a total number of carbon atoms of 2 to 30 and more preferably an alkoxycarbonyl group having a total number of carbon atoms of 2 to 16. Specific examples thereof include a methoxycarbonyl group, an ethoxycarbonyl group, and a 2-methoxyethoxycarbonyl group.

The aryloxycarbonyl group that can be adopted as R¹⁷ to R¹⁹ may further have a monovalent substituent, and it is preferably an aryloxycarbonyl group having a total number of carbon atoms of 7 to 30 and more preferably an aryloxycarbonyl group having the number of carbon atoms of 7 to 16. Specific examples thereof include a phenoxycarbonyl group, a 4-methylphenoxycarbonyl group, and a 3-chlorophenoxycarbonyl group.

The acyl group that can be adopted as R¹⁷ to R¹⁹ includes an aliphatic carbonyl group, an arylcarbonyl group, and a heterocyclic carbonyl group, where an aspect in which the total number of carbon atoms is 1 to 30 is preferable, and an aspect in which the total number of carbon atoms is 1 to 16 is more preferable. Specific examples thereof include an acetyl group, a methoxyacetyl group, a thienoyl group, and a benzoyl group.

To the aliphatic group in the aliphatic sulfonyl group that can be adopted as R¹⁷ and R¹⁸, the description of the aliphatic group that can be adopted as R¹⁷ to R¹⁹ can be applied.

The aliphatic sulfonyl group that can be adopted as R¹⁷ and R¹⁸ may further have a monovalent substituent, may be saturated or unsaturated, or may be cyclic, where an aspect in which the total number of carbon atoms is 1 to 30 is preferable, and an aspect in which the total number of carbon atoms is 1 to 16 is more preferable. Specific examples thereof include a methanesulfonyl group, a methoxymethanesulfonyl group, and an ethoxyethanesulfonyl group.

The alkylsulfonyl group that can be adopted as R¹⁹ may further have a monovalent substituent, may be saturated or unsaturated, or may be cyclic, where an aspect in which the total number of carbon atoms is 1 to 30 is preferable, and an aspect in which the total number of carbon atoms is 1 to 16 is more preferable. Specific examples thereof include a methanesulfonyl group, a methoxymethanesulfonyl group, and an ethoxyethanesulfonyl group.

The arylsulfonyl group that can be adopted as R¹⁷ to R¹⁹ may further have a monovalent substituent, where an aspect in which the total number of carbon atoms is 6 to 30 is preferable, and an aspect in which the total number of carbon atoms is 6 to 18 is more preferable. Specific examples thereof include a benzenesulfonyl group and a toluenesulfonyl group.

The sulfamoyl group that can be adopted as R¹⁷ to R¹⁹ includes, in addition to an unsubstituted sulfamoyl group (—SO₂NH₂), a carbamoyl group substituted with an aliphatic group, an aryl group, or the like.

The sulfamoyl group that can be adopted as R¹⁷ to R¹⁹ may further have a monovalent substituent, where an aspect in which the total number of carbon atoms is 0 to 30 is preferable, and an aspect in which the total number of carbon atoms is 0 to 16 is more preferable. Specific examples thereof include an unsubstituted sulfamoyl group, a dimethylsulfamoyl group, and a di-(2-hydroxyethyl)sulfamoyl group.

The imide group that can be adopted as R¹⁷ and R¹⁸ may further have a monovalent substituent, and it is preferably an imide group of a 5- or 6-membered ring. In addition, an aspect in which the total number of carbon atoms in the imide group is 4 to 30 is preferable, and an aspect in which the total number of carbon atoms in the imide group is 4 to 20 is more preferable. Specific examples thereof include a succinimide group and a phthalimide group.

To the aliphatic group in the aliphatic oxy group, the aliphatic amino group, the aliphatic oxycarbonylamino group, the aliphatic sulfonylamino group, and the aliphatic thio group, which can be adopted as R¹⁷ and R¹⁸, the description of the aliphatic group that can be adopted as R¹⁷ to R¹⁹ can be applied.

To the aryl group in the aryloxy group, the arylamino group, the aryloxycarbonylamino group, the arylsulfonylamino group, and the arylthio group, which can be adopted as R¹⁷ and R¹⁸, the description of the aryl group that can be adopted as R¹⁷ to R¹⁹ can be applied.

To the acyl group in the acyloxy group and the acylamino group, which can be adopted as R¹⁷ and R¹⁸, the description of the acyl group, which can be adopted as R¹⁷ to R¹⁹, can be applied.

To the carbamoyl group in the carbamoyloxy group and the carbamoylamino group, which can be adopted as R¹⁷ and R¹⁸, the description of the carbamoyl group, which can be adopted as R¹⁷ to R¹⁹, can be applied.

To the heterocyclic group in the heterocyclic oxy group, the heterocyclic amino group, and the heterocyclic thio group, which can be adopted as R¹⁷ and R¹⁸, the description of the heterocyclic group, which can be adopted as R¹⁷ to R¹⁹, can be applied.

To the sulfamoyl group in the sulfamoylamino group that can be adopted as R¹⁷ and R¹⁸, the description of the sulfamoyl group, which can be adopted as R¹⁷ to R¹⁹, can be applied.

The diazo component residue represented by Q means a residue of a diazo component “Q-NH₂”. In particular, from the viewpoint of the color reproducibility to be targeted, Q is preferably an aryl group or an aromatic heterocyclic group.

The aromatic hydrocarbon ring constituting the aryl group that can be adopted as Q may be a monocyclic ring or a fused ring, and it is preferably a monocyclic ring. It is preferably an aryl group having a total number of carbon atoms of 6 to 30, and more preferably an aryl group having a total number of carbon atoms of 6 to 16. Specifically, a phenyl group is preferable. The aryl group that can be adopted as Q may have a substituent, and preferred examples of the substituent that may be contained include a sulfamoyl group (preferably an alkylsulfamoyl group or a dialkylsulfamoyl group), a sulfonyl group (preferably an alkylsulfonyl group), and a cyano group.

The aromatic heterocyclic group that can be adopted as Q is an aromatic ring group containing, as a ring-constituting atom constituting a heterocyclic group, at least any one among heteroatoms such as a nitrogen atom, a sulfur atom, and an oxygen atom, where the aromatic heterocyclic group is preferably composed of a 5- or 6-membered ring. The number of carbon atoms in the aromatic heterocyclic group is preferably 1 to 25 and more preferably 1 to 15. The aromatic heterocyclic ring constituting the aromatic heterocyclic group may be a monocyclic ring or a fused ring, and it is preferably a monocyclic ring.

Specific examples of the aromatic heterocyclic group include a pyrazole group, a 1,2,4-triazole group, an isothiazole group, a benzisothiazole group, a thiazole group, a benzothiazole group, an oxazole group, and a 1,2,4-thiadiazole group.

Examples of the above-described azo dye represented by General Formula (i) include the following exemplary compounds (B-12) to (B-16), (B-18), and (B-19). However, the present invention is not limited thereto.

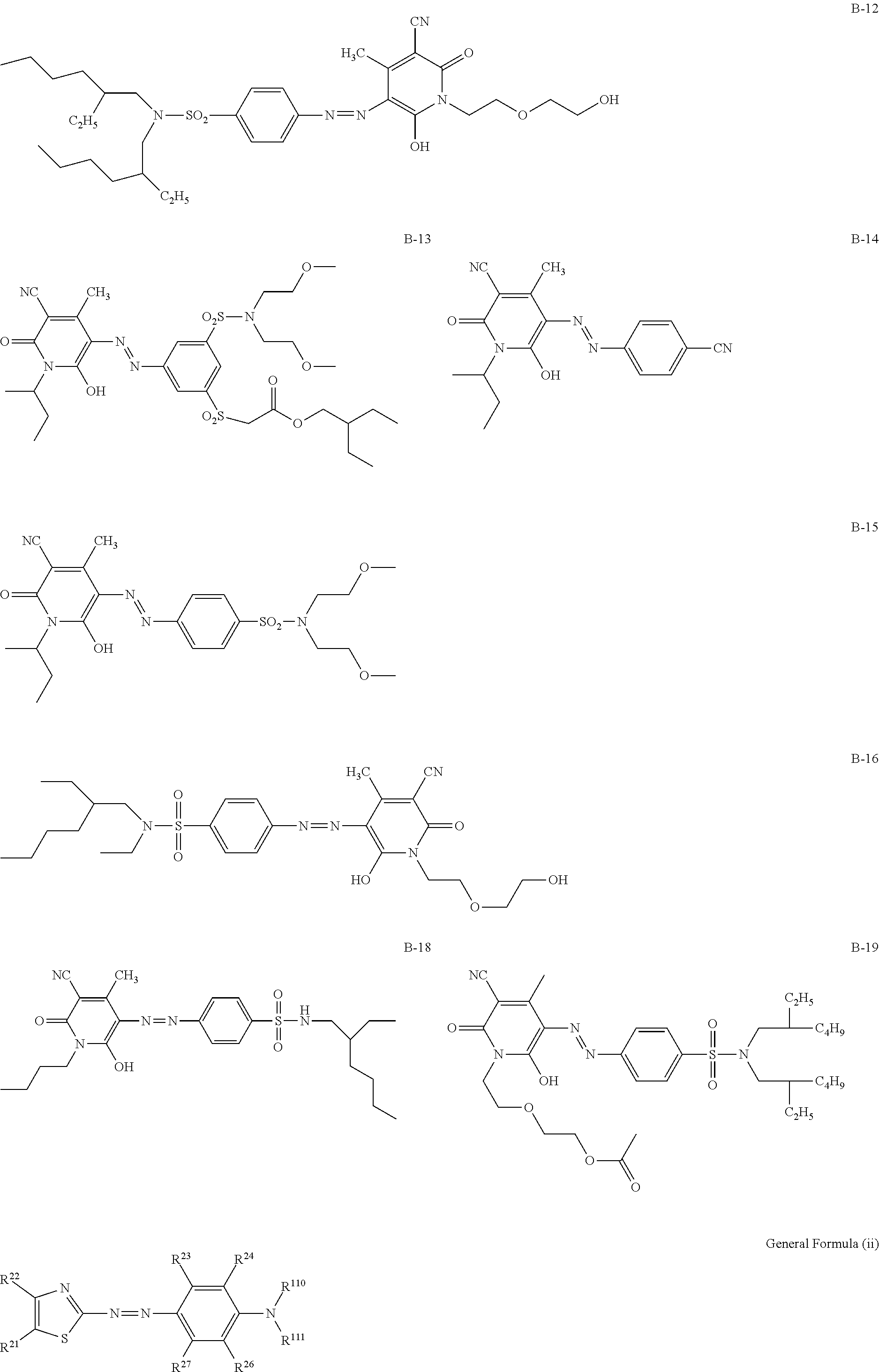

In the formula, R²¹ to R²⁴, R²⁶, and R²⁷ represent a hydrogen atom, a halogen atom, a cyano group, a nitro group, a carboxy group, a sulfo group, —OR¹⁰⁸, —SR¹⁰⁹, —NR¹¹⁰R¹¹¹, —S(═O)₂NR¹¹²R¹¹³, —C(═O)NR¹¹⁴R¹¹⁵, —NHC(═O)R¹¹⁶, —C(═O)OR¹¹⁷, —O(CH₂CH₂O)ₙR¹¹⁸, —O(CH₂CH₂S)ₙR¹¹⁹, —S(CH₂CH₂O)ₙR¹²⁰, —S(CH₂CH₂S)ₙR¹²¹, an acyclic hydrocarbon group, a monocyclic hydrocarbon group, a fused polycyclic hydrocarbon group, or a heterocyclic group.

R¹⁰⁸ to R¹²¹ represent a hydrogen atom, an acyclic hydrocarbon group, a monocyclic hydrocarbon group, a fused polycyclic hydrocarbon group, or a heterocyclic group, and n represents a positive integer.

It is noted that the acyclic hydrocarbon group, the monocyclic hydrocarbon group, the fused polycyclic hydrocarbon group, or the heterocyclic group may have, as a substituent, one or two or more of a halogen atom, a cyano group, a nitro group, a carboxy group, a sulfo group, —OR¹⁰⁸, —SR¹⁰⁹, —NR¹¹⁰OR¹¹¹, —S(═O)₂NR¹¹²R¹¹³, —C(═O)NR¹¹⁴R¹¹⁵, —NHC(═O)R¹¹⁶, —C(═O)OR¹¹⁷, —O(CH₂CH₂O)ₙR¹¹⁸, —O(CH₂CH₂S)ₙR¹¹⁹, —S(CH₂CH₂O)ₙR¹²⁰, —S(CH₂CH₂S)ₙR¹²¹, an acyclic hydrocarbon group, a monocyclic hydrocarbon group, a fused polycyclic hydrocarbon group, and a heterocyclic group.

The acyclic hydrocarbon group that can be adopted as R²¹ to R²⁴, R²⁶, R²⁷, and R¹⁰⁸ to R¹²¹ means an acyclic alkyl group in which one hydrogen atom is removed from an acyclic alkane. However, the acyclic alkyl group may have a ring structure as a substituent. The number of carbon atoms in the acyclic alkyl group is preferably 1 to 30, more preferably 1 to 20, still more preferably 1 to 12, particularly preferably 1 to 8, and among these, it is preferably 1 to 6.

The monocyclic hydrocarbon group that can be adopted as R²¹ to R²⁴, R²⁶, R²⁷, and R¹⁰⁸ to R¹²¹ means a monocyclic cycloalkyl group, a monocyclic cycloalkenyl group, a monocyclic cycloalkynyl group, or a monocyclic aryl group, which is a group in which one hydrogen atom is removed from a monocyclic aliphatic hydrocarbon ring (which may be any of a monocyclic cycloalkane, a monocyclic cycloalkene, or a monocyclic cycloalkyne) or a monocyclic aromatic hydrocarbon ring.

The number of carbon atoms in the monocyclic cycloalkyl group, the monocyclic cycloalkenyl group, and the monocyclic cycloalkynyl group is not particularly limited as long as it is allowed in terms of the structure; however, it is more preferably 3 to 30, more preferably 3 to 20, and still more preferably 3 to 16. The number of carbon atoms in the monocyclic aryl group is more preferably 6 to 30, still more preferably 6 to 20, and even still more preferably 6 to 16.

The fused polycyclic hydrocarbon group that can be adopted as R²¹ to R²⁴, R²⁶, R²⁷, and R¹⁰⁸ to R¹²¹ means a fused polycyclic cycloalkyl group, a fused polycyclic cycloalkenyl group, a fused polycyclic cycloalkynyl group, or a fused polycyclic aryl group, which is a group in which one hydrogen atom is removed from a fused polycyclic aliphatic hydrocarbon ring (which may be any of a fused polycyclic cycloalkane, a fused polycyclic cycloalkene, or a fused polycyclic cycloalkyne) or a fused polycyclic aromatic hydrocarbon ring.

The number of carbon atoms in the fused polycyclic cycloalkyl group, the fused polycyclic cycloalkenyl group, and the fused polycyclic cycloalkynyl group is not particularly limited as long as it is allowed in terms of the structure; however, it is more preferably 8 to 30 and more preferably 8 to 20. The number of carbon atoms in the fused polycyclic aryl group is more preferably 12 to 30 and still more preferably 12 to 20.

To the heterocyclic group that can be adopted as R²¹ to R²⁴, R²⁶, R²⁷, and R¹⁰⁸ to R¹²¹, the description of the heterocyclic group that can be adopted as R¹⁷ to R¹⁹ in General Formula (i) can be applied.

n is preferably an integer of 1 to 12, more preferably an integer of 1 to 6, and still more preferably an integer of 1 to 3.

Regarding the specific group of each of the substituents in General Formula (ii), unless otherwise specified, the descriptions regarding R¹ to R⁴, R⁶, R⁷, and R⁸ to R²¹ for the compound represented by General Formula [1] described in JP1993-257180A (JP-H5-257180A) can be applied as they are to R²¹ to R²⁴, R²⁶, R²⁷, and R¹⁰⁸ to R¹²¹, respectively.

R²¹ is preferably a cyano group, a nitro group, —OR¹⁰⁸, an acyclic hydrocarbon group (preferably an acyclic alkyl group or an acyclic alkenyl group), or a heterocyclic group, more preferably a cyano group or a nitro group, or an acyclic alkyl group (preferably an alkyl group substituted with a fluorine atom) substituted with a halogen atom, and still more preferably a cyano group.

R²² is preferably a hydrogen atom, a cyano group, an acyclic hydrocarbon group (preferably an acyclic alkyl group), or a monocyclic hydrocarbon group, more preferably a hydrogen atom, an alkyl group, or an aryl group, and still more preferably an alkyl group or an aryl group.

It is noted that at least one of R²¹ or R²² is preferably a cyano group or a nitro group, or an acyclic alkyl group substituted with a halogen atom, a cyano group, or a nitro group.

R²³ is preferably a hydrogen atom, —OR¹⁰⁸, —SR¹⁰⁹, —NR¹¹⁰R¹¹¹, —C(═O)NR¹¹⁴R¹¹⁵, —NHC(═O)R¹¹⁶, —O(CH₂CH₂O)ₙR¹¹⁸, —O(CH₂CH₂S)ₙR¹¹⁹, —S(CH₂CH₂O)ₙR¹²⁰, —S(CH₂CH₂S)ₙR¹²¹, or an acyclic hydrocarbon group (preferably an acyclic alkyl group), more preferably a hydrogen atom, —OR¹⁰⁸, —SR¹⁰⁹, —NR¹¹⁰R¹¹¹, —NHC(═O)R¹¹⁶, or an acyclic alkyl group, and still more preferably —NHC(═O)R¹¹⁶. Here, R¹⁰⁸ to R¹¹¹, R¹¹⁶, and R¹¹⁸ to R¹²¹ are preferably an acyclic alkyl group.

R²⁴ and R²⁷ are preferably a hydrogen atom.

R²⁶ is preferably a hydrogen atom, —OR¹⁰⁸, —SR¹⁰⁹, —NR¹¹⁰R¹¹¹, —NHC(═O)R¹¹⁶, —O(CH₂CH₂O)ₙR¹¹⁸, —O(CH₂CH₂S)ₙR¹¹⁹, —S(CH₂CH₂O)ₙR¹²⁰, —S(CH₂CH₂S)ₙR¹²¹, or an acyclic hydrocarbon group (preferably an acyclic alkyl group), more preferably a hydrogen atom, —OR¹⁰⁸, or —SR¹⁰⁹, and still more preferably a hydrogen atom. Here, R¹⁰⁸ to R¹¹¹, R¹¹⁶, and R¹¹⁸ to R¹²¹ are preferably an acyclic alkyl group.

In —NR¹¹⁰R¹¹¹ that is located at the ortho position with respect to R²⁴ and R²⁶, R¹¹⁰ is preferably an acyclic alkyl group, and R¹¹¹ is preferably an acyclic alkyl group, more preferably an unsubstituted acyclic alkyl group or an acyclic alkyl group having —OR¹⁰⁸, a monocyclic hydrocarbon group, or a fused polycyclic hydrocarbon group as a substituent. Here, R¹⁰⁸ is preferably a hydrogen atom or an acyclic alkyl group.

Specific examples of the dye represented by General Formula (ii) include, in addition to the compounds that are used in Examples described later, the compounds described in paragraphs [0023] to [0034] of JP1993-257180A (JP-H5-257180A), and the compounds described in paragraphs [0050] and [0052], the compound D-18 described in paragraph [0055], and the compound described in paragraph [0056] of JP2013-129712A. However, the present invention is not limited thereto.

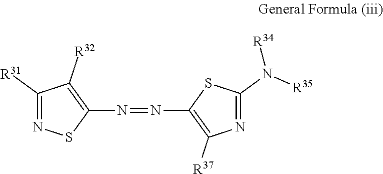

In the formula, R³¹ represents a hydrogen atom, an alkyl group, an alkoxy group, a cyano group, a carbonyl group (an alkyloxycarbonyl group or an aryloxycarbonyl group is preferable), an aromatic group, or a heterocyclic group.

R³² represents a hydrogen atom, an alkyl group, an alkoxy group, a cyano group, a nitro group, a carbonyl group (an alkyloxycarbonyl group or an aryloxycarbonyl group is preferable), an aromatic group, or a heterocyclic group.

R³⁴ and R³⁵ each independently represent a hydrogen atom, an alkyl group, or an aromatic group.

R³⁷ represents a hydrogen atom, an alkyl group, an alkoxy group, a cyano group, a carbonyl group (an alkyloxycarbonyl group or an aryloxycarbonyl group is preferable), an acylamino group, or an aromatic group.

R³⁴ and R³⁵ may be bonded to each other to form a ring.

Regarding the definition and the preferred range of each of the substituents in General Formula (iii), unless otherwise specified, the descriptions regarding R1 and R2 regarding General Formula (1) described in JP2013-129712A can be applied as they are to R31 and R32, respectively, and the description regarding R4, R5, and R7 regarding General Formula (3) described in JP2013-129712A can be applied as it is to R34, R35, and R³⁷, respectively.

It is noted that, in the present invention, R³⁷ can adopt the following acylamino group in addition to the hydrogen atom, the alkyl group, the alkoxy group, the cyano group, the carbonyl group, and the aromatic group, which can be adopted by R⁷ regarding General Formula (3) described in JP2013-129712A.

The number of carbon atoms in the acylamino group that can be adopted as R³⁷ is preferably 1 to 12 and more preferably 1 to 6.

In the present invention, the number of carbon atoms in the alkyl group that can be adopted as R³¹, R³², and R³⁷ is more preferably 1 to 20, still more preferably 1 to 12, and particularly preferably 1 to 6.

The number of carbon atoms in the alkoxy group that can be adopted as R³¹, R³², and R³⁷ is more preferably 1 to 20, still more preferably 1 to 12, and particularly preferably 1 to 6.

The number of carbon atoms in the alkyloxycarbonyl group that can be adopted as R³¹, R³², and R³⁷ is preferably 2 to 30, more preferably 2 to 20, still more preferably 2 to 12, and particularly preferably 2 to 7.

The number of carbon atoms in the alkyl group that can be adopted as R³⁴ and R³⁵ is preferably 1 to 30, more preferably 1 to 20, and still more preferably 1 to 12.

R³¹ is preferably an alkyl group or an aryl group, and more preferably an alkyl group.

R³² is preferably an alkyl group or a cyano group, and more preferably a cyano group.

R³⁴ and R³⁵ are preferably a hydrogen atom or an alkyl group, and more preferably an alkyl group.

R³⁷ is preferably a hydrogen atom, an alkyl group, an acylamino group, or an aromatic group, more preferably a hydrogen atom or an alkyl group, and still more preferably an alkyl group.

Specific examples of the dye represented by General Formula (iii) include compounds described below. However, the present invention is not limited thereto.

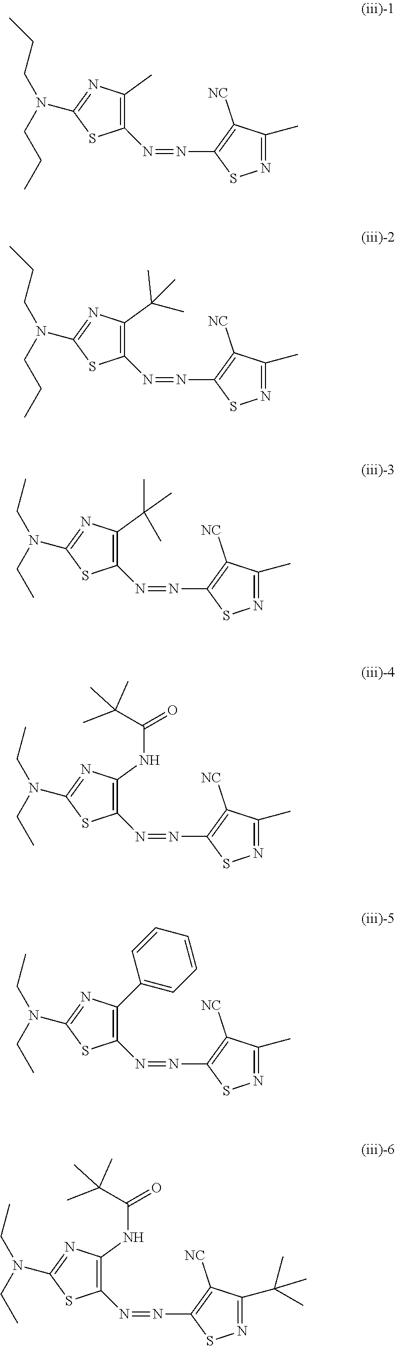

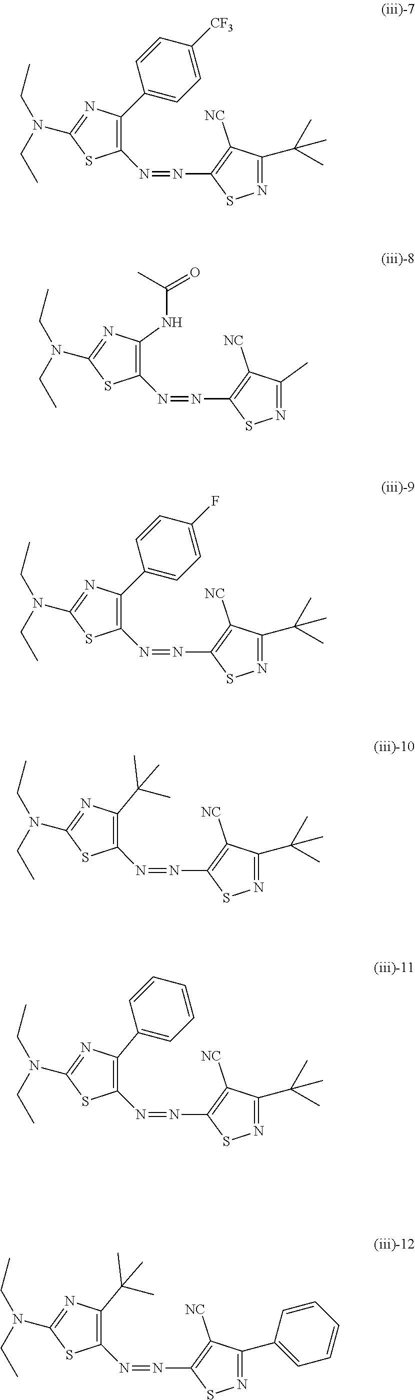

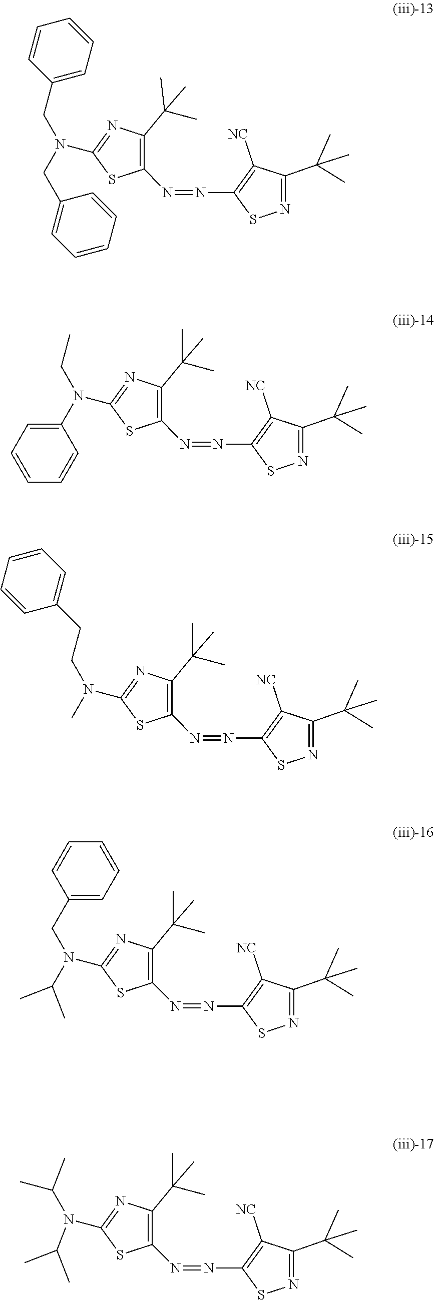

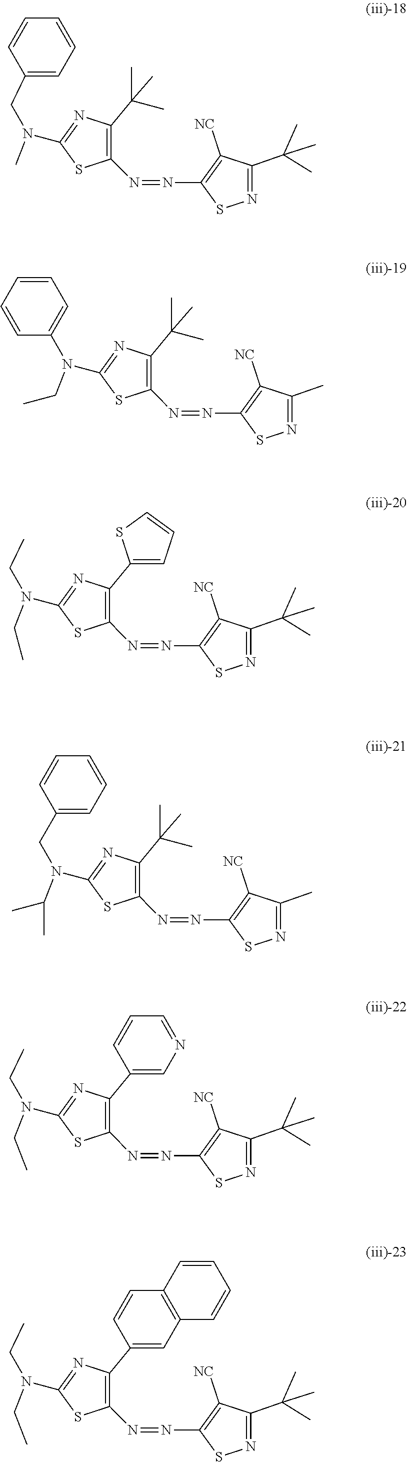

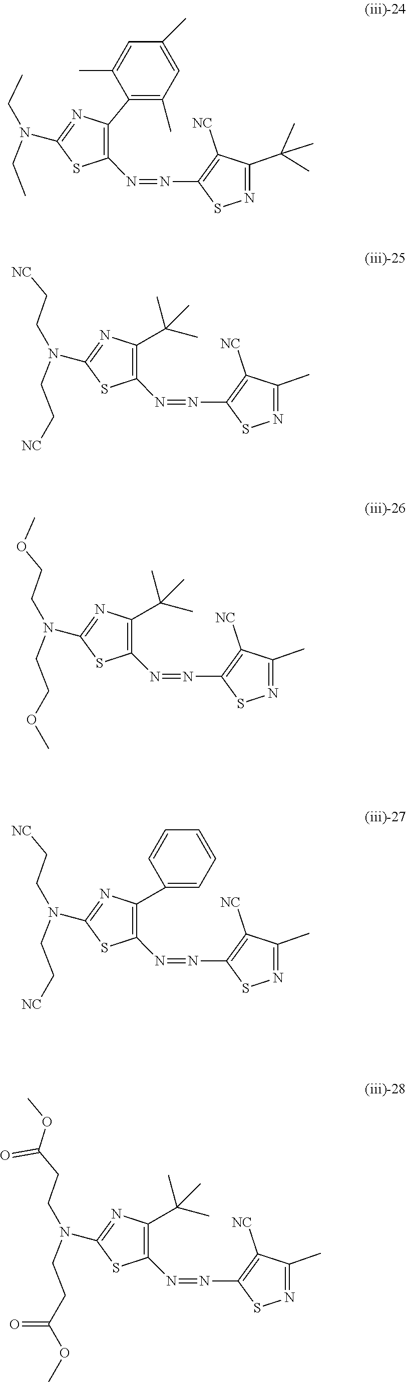

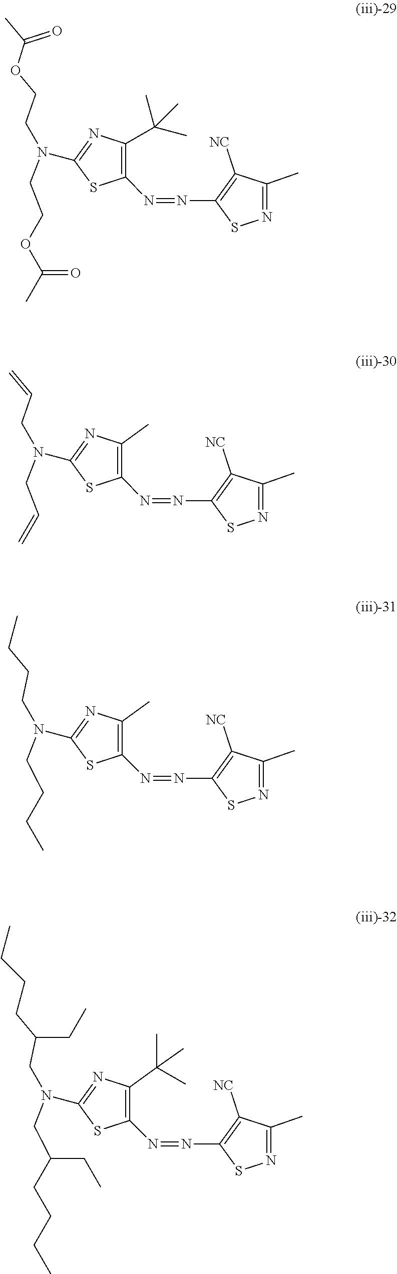

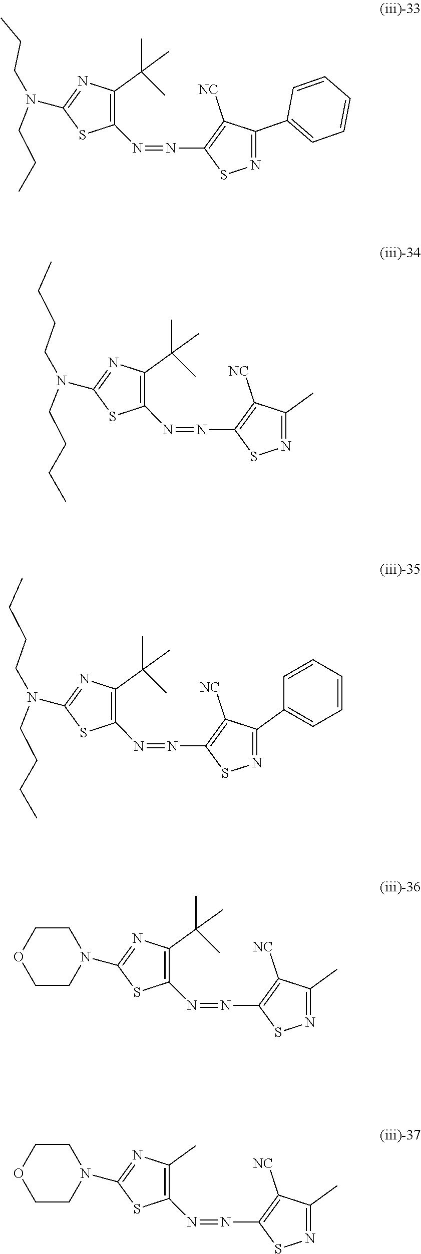

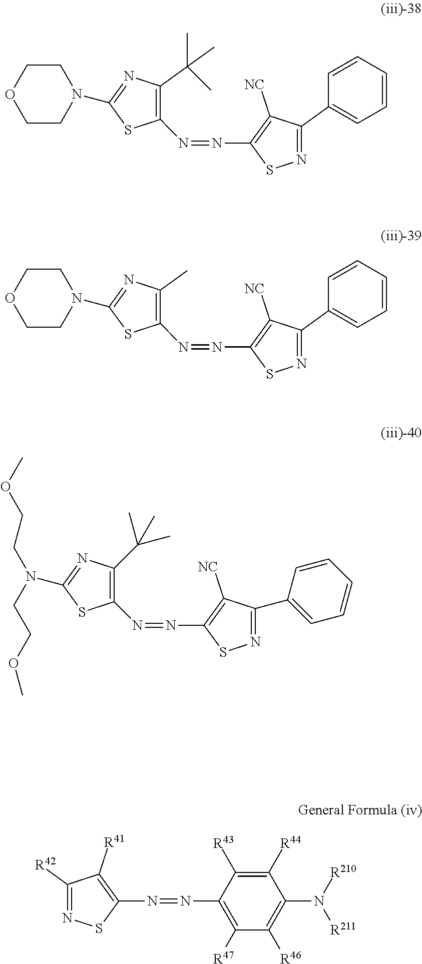

In the formula, R⁴¹ to R⁴⁴, R⁴⁶, and R⁴⁷ represent a hydrogen atom, a halogen atom, a cyano group, a nitro group, a carboxy group, a sulfo group, —OR²⁰⁸, —SR²⁰⁹, —NR²¹⁰R²¹¹, —S(═O)₂NR²¹²R²¹³, —C(═O)NR²¹⁴R²¹⁵, —NHC(═O)R²¹⁶, —C(═O)OR²¹⁷, —O(CH₂CH₂O)R²¹⁸, —O(CH₂CH₂S)ₙR²¹⁹, —S(CH₂CH₂O)ₙR²²⁰, —S(CH₂CH₂S)ₙR²²¹, an acyclic hydrocarbon group, a monocyclic hydrocarbon group, a fused polycyclic hydrocarbon group, or a heterocyclic group.

R²⁰⁸ to R²²¹ represent a hydrogen atom, an acyclic hydrocarbon group, a monocyclic hydrocarbon group, a fused polycyclic hydrocarbon group, or a heterocyclic group, and n is a positive integer.

The acyclic hydrocarbon group, the monocyclic hydrocarbon group, the fused polycyclic hydrocarbon group, and the heterocyclic group may have, as a substituent, one or two or more of a halogen atom, a cyano group, a nitro group, a carboxy group, a sulfo group, —OR²⁰⁸, —SR²⁰⁹, —NR²¹⁰R²¹¹, —S(═O)₂NR²¹²R²¹³, —C(═O)NR²¹⁴R²¹⁵, —NHC(═O)R²¹⁶, —C(═O)OR²¹⁷, —O(CH₂CH₂O)ₙR²¹⁸, —O(CH₂CH₂S)ₙR²¹⁹, —S(CH₂CH₂O)ₙR²²⁰, and —S(CH₂CH₂S)ₙR²²¹.

The descriptions of R²¹ to R²⁴, R²⁶, R²⁷, R¹⁰⁸ to R¹²¹, and n in General Formula (ii) can be applied as they are to R⁴¹ to R⁴⁴, R⁴⁶, R⁴⁷, R²⁰⁸ to R²²¹, and n in General Formula (iv) unless otherwise specified.

R⁴³ is preferably a hydrogen atom, —OR²⁰⁸, —SR²⁰⁹, —NR²¹⁰R²¹¹, —NHC(═O)R²¹⁶, —O(CH₂CH₂O)ₙR²¹⁸, —O(CH₂CH₂S)ₙR²¹⁹, —S(CH₂CH₂O)ₙR²²⁰, —S(CH₂CH₂S)ₙR²²¹, or an acyclic hydrocarbon group (preferably an acyclic alkyl group), more preferably a hydrogen atom, —OR²⁰⁸, —SR²⁰⁹, —NR²¹⁰R²¹¹, —NHC(═O)R²¹⁶, or an acyclic alkyl group, and still more preferably —NHC(═O)R²¹⁶ or an acyclic alkyl group. Here, R²⁰⁸ to R²¹¹, R²¹⁶, and R²¹⁸ to R²²¹ are preferably an acyclic alkyl group.

In —NR²¹⁰R²¹¹ that is located at the ortho position with respect to R⁴⁴ and R⁴⁶, R²¹⁰ is preferably an acyclic alkyl group, and R²¹¹ is preferably an acyclic alkyl group and more preferably an unsubstituted acyclic alkyl group (including an acyclic alkyl group substituted with an acyclic alkyl group) or an acyclic alkyl group having —OR²⁰⁸, a monocyclic hydrocarbon group, or a fused polycyclic hydrocarbon group as a substituent. Here, R²⁰⁸ is preferably a hydrogen atom or an acyclic alkyl group.

It is noted that R⁴⁴ and/or R⁴⁶ in General Formula (iv) may be bonded to R²¹⁰ and/or R²¹¹ in —NR²¹⁰R²¹¹ located at the ortho position with respect to R⁴⁴ and R⁴⁶ on the benzene ring, thereby forming a ring. The ring which may be formed is preferably a 5- or 6-membered ring and may be saturated or unsaturated, and it is preferably a saturated 6-membered ring. The ring which may be formed may further have a substituent, and for example, it preferably has an alkyl group.

Among these, regarding a form in which a ring is formed, it is preferable that R⁴⁶ and R²¹¹ in —NR²¹⁰R²¹¹ that is located at the ortho position with respect to R⁴⁴ and R⁴⁶ on the benzene ring are bonded to each other to form a saturated 6-membered ring.

Specific examples of the dye represented by General Formula (iv) include the compounds used in Examples described later and the compounds described in paragraph [0053] of JP2013-129712A. However, the present invention is not limited thereto.

In addition, as the above-described dye, an indoaniline dye represented by General Formula (v) can also be preferably used.

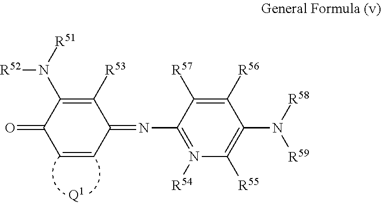

In the formula, Q¹ represents an atomic group that contains at least one nitrogen atom and is necessary for forming a 5- to 7-membered nitrogen-containing heterocyclic ring together with carbon atoms to be bonded.

R⁵¹ represents an acyl group, an alkoxycarbonyl group, an aryloxycarbonyl group, an aminocarbonyl group, or a sulfonyl group, R⁵² represents a hydrogen atom or an alkyl group, R⁵³ to R⁵⁷ represent a hydrogen atom, an alkyl group, an alkoxy group, an acylamino group, an alkylsulfonylamino group, or a halogen atom, and R⁵⁸ and R⁵⁹ represent a hydrogen atom, an alkyl group, or an aryl group.

R⁵¹ and R⁵³, R⁵⁴ and R⁵⁵, and/or R⁵⁵ and R⁵⁹, or R⁵⁸ and R⁵⁹ may be bonded to each other to form a ring. That is, it means that R⁵¹ and R⁵³ may be bonded to each other to form a ring, R⁵⁴ and R⁵⁵ and/or R⁵⁵ and R⁵⁹ may be bonded to each other to form a ring, or R⁵⁸ and R⁵⁹ may be bonded to each other to form a ring.

Regarding the definition and the preferred range of each of the substituents in General Formula (v), unless otherwise specified, the descriptions regarding R¹ to R⁶, R⁸, R⁹, and Q¹ in General Formula (I) described in JP1990-92686A (JP-H2-92686A) can be applied as they are to R⁵¹ to R⁵⁶, R⁵⁸, R⁵⁹, and Q¹, respectively.

It is noted that in the present invention, R⁵³ to R⁵⁶ can adopt the following acylamino group and alkylsulfonylamino group, in addition to the hydrogen atom, the alkyl group, the alkoxy group, and the halogen atom, which can be adopted by R³ to R⁶ regarding General Formula (I) described in JP1990-92686A (JP-H02-92686A).

The number of carbon atoms in the acylamino group that can be adopted as R⁵³ to R⁵⁷ is preferably 1 to 12 and more preferably 1 to 6.

The number of carbon atoms in the alkylsulfonylamino group that can be adopted as R⁵³ to R⁵⁷ is preferably 1 to 12 and more preferably 1 to 6.

To the alkyl group, the alkoxy group, and the halogen atom, which can be adopted as R⁵⁷, the descriptions of the alkyl group, the alkoxy group, and the halogen atom, which can be adopted as R⁵³ to R⁵⁶, can be applied as they are.

Q¹ is preferably represented by —NR¹⁶C(═O)-Q²-. Q² represents an atomic group required for forming a 5- to 7-membered nitrogen-containing heterocyclic ring together with a carbon atom to which —NR¹⁶C(═O)-Q²- is bonded and —NR¹⁶C(═O)—, and examples thereof include a divalent amino group, an ether bond, a thioether bond, an alkylene bond, an ethylene bond, an imino bond, a sulfonyl bond, a carbonyl bond, an arylene bond or a divalent heterocyclic group, and a group obtained by combining a plurality of these. R¹⁶ represents a hydrogen atom, an alkyl group, an aryl group, or a heterocyclic group, where a hydrogen atom is preferable. To each of the definition and the preferred range of each substituent of R¹⁶, the description regarding R¹⁶ regarding General Formula (I) described in JP1990-92686A (JP-H2-92686A) can be applied as it is.

R⁵¹ is preferably an acyl group having 2 to 7 carbon atoms or an alkoxycarbonyl group having 2 to 7 carbon atoms.

R⁵² is preferably a hydrogen atom, and R⁵³ to R⁵⁶ are preferably a hydrogen atom.

R⁵⁷ is preferably an alkoxy group, an acylamino group, or an alkylsulfonylamino group, and more preferably an alkoxy group or an acylamino group.

R⁵⁸ and R⁵⁹ are preferably an alkyl group having 1 to 6 carbon atoms.

Among these, the indoaniline dye represented by General Formula (v) is preferably represented by General Formula (v-a).

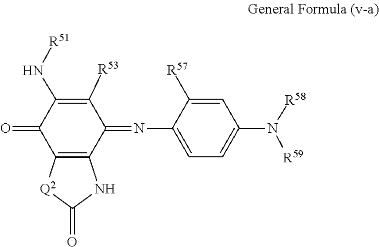

In the formula, R⁵¹, R⁵³, R⁵⁷ to R⁵⁹, and Q² have the same meanings as R⁵¹, R⁵³, R⁵⁷ to R⁵⁹, and Q² in General Formula (v).

Q² is preferably —CR¹¹R¹²CR¹³R¹⁴—, —CR¹¹R¹²—, or —NR¹¹—, and more preferably —CR¹¹R¹²CR¹³R¹⁴—.

R¹¹ to R¹⁴ represent a hydrogen atom or an alkyl group having 1 to 4 carbon atoms, and it is preferable that R¹¹ and R¹² are a hydrogen atom and R¹³ and R¹⁴ are an alkyl group having 1 to 4 carbon atoms.

It is noted that —CR¹¹R¹²CR¹³R¹⁴— is preferably bonded to >C═O on the side of the carbon atom to which R¹¹ and R¹² are bonded.

Specific examples of the coloring agent represented by General Formula (v) include, in addition to the compounds that are used in Examples described later, the compounds of Nos. 1 to 51 on pages 5 and 6 of JP1990-92686A (JP-H2-92686A). However, the present invention is not limited thereto.

As the above-described dye, an anthraquinone dye represented by General Formula (2) can also be preferably used.

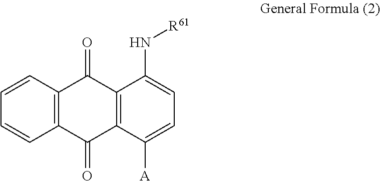

In the formula, A represents a hydroxy group or —NH—R⁶².

R⁶¹ and R⁶² represent a hydrogen atom, an aliphatic hydrocarbon group having 1 to 10 carbon atoms, an alicyclic hydrocarbon group having 3 to 10 carbon atoms, or a group represented by Formula (2b).

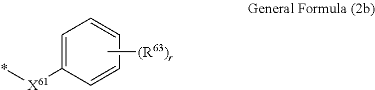

In the formula, R⁶³ represents an alkyl group having 1 to 6 carbon atoms, a halogen atom, —SO₃H, —CO₂H, —CO₂R⁶⁴, —NHCOR⁶⁴, —SO₃R⁶⁴, or —SO₂NR⁶⁴R⁶⁵.

R⁶⁴ represents a saturated hydrocarbon group having 1 to 10 carbon atoms.

R⁶⁵ represents a hydrogen atom or a saturated hydrocarbon group having 1 to 10 carbon atoms.

r is an integer of 0 to 5.

X⁶¹ represents a single bond or an alkanediyl group having 1 to 6 carbon atoms.

* represents a bonding site.

Examples of the aliphatic hydrocarbon group having 1 to 10 carbon atoms, which can be adopted as R⁶¹ and R⁶², include a methyl group, an ethyl group, a propyl group, a butyl group, a pentyl group, a hexyl group, a heptyl group, an octyl group, a nonyl group, a decyl group, an isopropyl group, an isobutyl group, a sec-butyl group, a tert-butyl group, an isopentyl group, a neopentyl group, and a 2-ethylhexyl group.

Examples of the alicyclic hydrocarbon group having 3 to 10 carbon atoms, which can be adopted as R⁶¹ and R⁶², include a cyclopropyl group, a cyclopentyl group, a cyclohexyl group, a cycloheptyl group, a cyclooctyl group, and a tricyclodecyl group.

The aliphatic hydrocarbon group having 1 to 10 carbon atoms and the alicyclic hydrocarbon group having 3 to 10 carbon atoms, which can be adopted as R⁶¹ and R⁶², may have a substituent, and examples of the substituent which may be contained include a hydroxy group and a halogen atom.

Examples of the alkyl group having 1 to 6 carbon atoms, which can be adopted as R63 include a methyl group, an ethyl group, a propyl group, a butyl group, a pentyl group, a hexyl group, an isopropyl group, an isobutyl group, a sec-butyl group, a tert-butyl group, an isopentyl group, and a neopentyl group.

The —SO₃H and —CO₂H, which can be adopted as R⁶³, may have an ionic structure in which a hydrogen ion is dissociated, or may have a salt structure. That is, “—CO₂H” is used to mean a group of a carboxylic acid ion or a salt thereof, and “—SO₃H” is used to mean a group of a sulfonic acid ion or a salt thereof. Examples of the salt include a salt with an alkali metal such as sodium and potassium; a salt with an alkaline earth metal such as calcium and magnesium; and an ammonium salt.

Examples of the saturated hydrocarbon group having 1 to 10 carbon atoms, which can be adopted as R⁶⁴ and R⁶⁵, include a linear alkyl group such as a methyl group, an ethyl group, a propyl group, a butyl group, a pentyl group, a hexyl group, a heptyl group, an octyl group, a nonyl group, and a decyl group; a branched alkyl group such as an isopropyl group, an isobutyl group, an isopentyl group, a neopentyl group, and a 2-ethylhexyl group; and a saturated alicyclic hydrocarbon group such as a cyclopropyl group, a cyclopentyl group, a cyclohexyl group, a cycloheptyl group, a cyclooctyl group, and a tricyclodecyl group.

At least one hydrogen atom contained in the saturated hydrocarbon group having 1 to 10 carbon atoms, which can be adopted as R⁶⁴ and R⁶⁵, may be substituted with a halogen atom, a hydroxy group, or an amino group.

Examples of —CO₂R⁶⁴ include a methoxycarbonyl group, an ethoxycarbonyl group, a propoxycarbonyl group, a tert-butoxycarbonyl group, a hexyloxycarbonyl group, and an icosyloxycarbonyl group.

Examples of —NHCOR⁶⁴ include an N-acetylamino group, an N-propanoylamino group, an N-butyrylamino group, an N-isobutyrylamino group, and an N-pivaloylamino group.

Examples of —SO₃R⁶⁴ include a methoxysulfonyl group, an ethoxysulfonyl group, a propoxysulfonyl group, a tert-butoxysulfonyl group, a hexyloxysulfonyl group, and an icosyloxysulfonyl group.

Examples of —SO₂NR⁶⁴R⁶⁵ include an N−1 substituted sulfamoyl group such as an N-methylsulfamoyl group, an N-ethylsulfamoyl group, an N-propylsulfamoyl group, an N-isopropylsulfamoyl group, an N-butylsulfamoyl group, an N-isobutylsulfamoyl group, an N-sec-butylsulfamoyl group, an N-tert-butylsulfamoyl group, an N-pentylsulfamoyl group, an N-(1-ethylpropyl)sulfamoyl group, an N-(1,1-dimethylpropyl)sulfamoyl group, an N-(1,2-dimethylpropyl)sulfamoyl group, an N-(2,2-dimethylpropyl)sulfamoyl group, an N-(1-methylbutyl)sulfamoyl group, an N-(2-methylbutyl)sulfamoyl group, an N-(3-methylbutyl)sulfamoyl group, an N-cyclopentylsulfamoyl group, an N-cyclohexylsulfamoyl group, an N-hexylsulfamoyl group, an N-(1,3-dimethylbutyl)sulfamoyl group, an N-(3,3-dimethylbutyl)sulfamoyl group, an N-heptylsulfamoyl group, an N-(1-methylhexyl)sulfamoyl group, an N-(1,4-dimethylpentyl)sulfamoyl group, an N-octylsulfamoyl group, an N-(2-ethylhexyl)sulfamoyl group, an N-(1,5-dimethyl)hexylsulfamoyl group, an N-(1,1,2,2-tetramethylbutyl)sulfamoyl group, and an N-(5-aminopentyl)sulfamoyl group;
an N,N-2 substituted sulfamoyl group such as an N,N-dimethylsulfamoyl group, an N-ethyl-N-methylsulfamoyl group, an N,N-diethylsulfamoyl group, an N-propyl-N-methylsulfamoyl group, an N-isopropyl-N-methylsulfamoyl group, an N-tert-butyl-N-methylsulfamoyl group, an N-butyl-N-ethylsulfamoyl group, an N,N-bis(1-methylpropyl)sulfamoyl group, and an N-heptyl-N-methylsulfamoyl group.

Examples of the alkanediyl group having 1 to 6 carbon atoms, which can be employed as X⁶¹, include a methylene group, an ethylene group, a propane-1,3-diyl group, a propane-1,2-diyl group, a butane-1,4-diyl group, a pentane-1,5-diyl group, a hexane-1,6-diyl group, an ethane-1,1-diyl group, a butane-1,3-diyl group, a 2-methylpropane-1,3-diyl group, a 2-methylpropane-1,2-diyl group, a pentane-1,4-diyl group, and a 2-methylbutane-1,4-diyl group.

Examples of the anthraquinone dye represented by General Formula (2) include the following exemplary compounds (2-1) to (2-14). However, the present invention is not limited thereto.

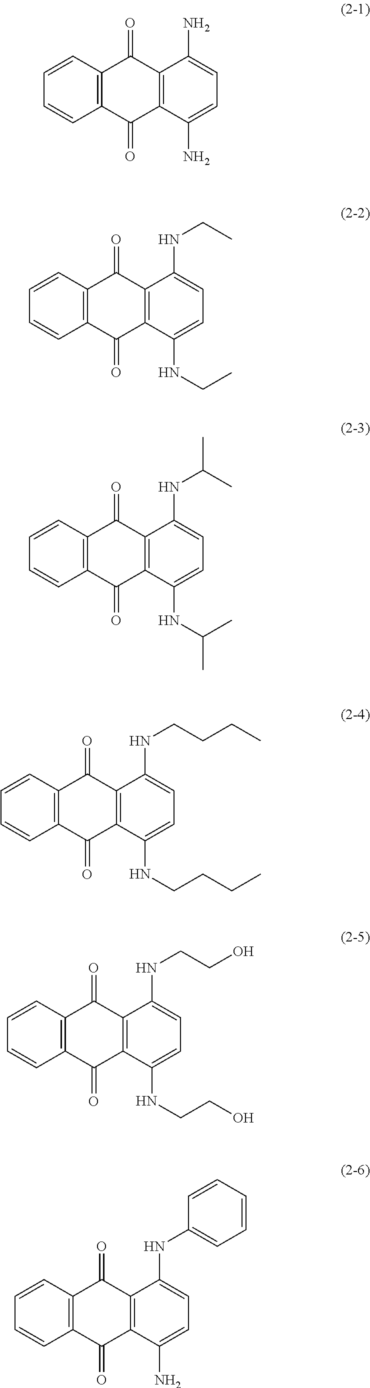

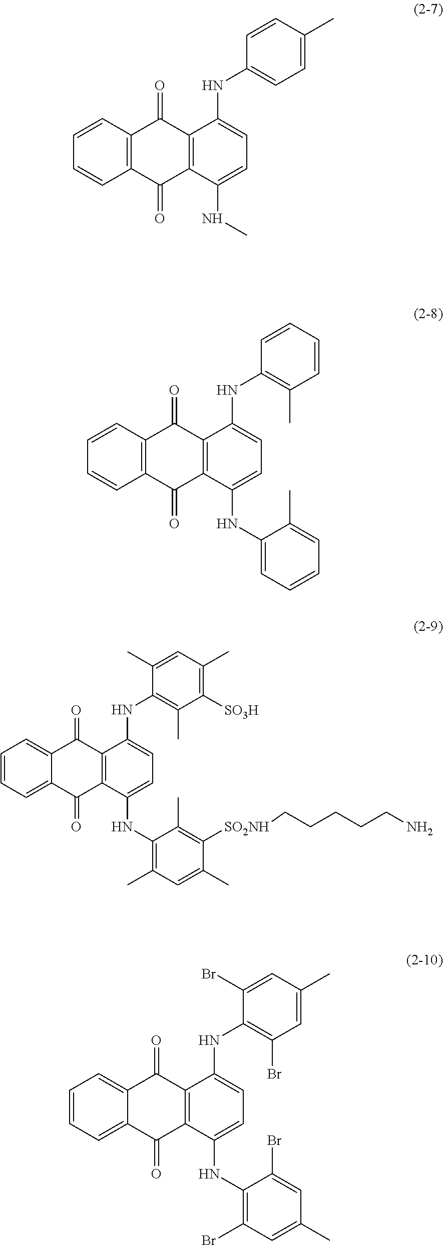

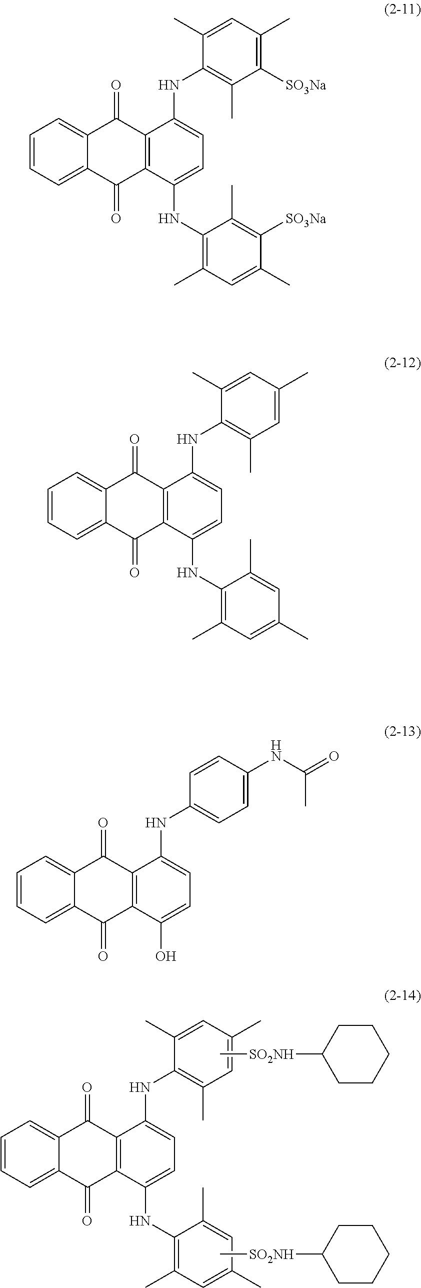

Among these, as the anthraquinone dye represented by General Formula (2), C. I. (Colour Index International) Solvent Blue 35 (the above-described exemplary compound (2-4)), C. I. Solvent Blue 36 (the above-described exemplary compound (2-3)), C. I. Solvent Blue 45 (the above-described exemplary compound (2-14)), C. I. Solvent Blue 63, C. I. Solvent Blue 97, C. I. Acid Blue 80 (the above-described exemplary compound (2-11)), C. I. Solvent Blue 101 (the above-described exemplary compound (2-8)), C. I. Solvent Blue 104 (the above-described exemplary compound (2-12)), and C. I. Solvent Blue 122 (the above-described exemplary compound (2-13)) are preferable.

As the above-described dye, a tetraazaporphyrin dye represented by General Formula (8) can also be preferably used.

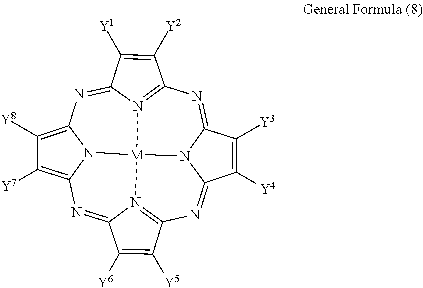

In the formulae, Y¹ to Y⁸ represent a hydrogen atom, a halogen atom, a nitro group, a cyano group, a hydroxy group, an amino group (—NH₂), a carboxy group, a sulfonic acid group, an alkyl group having 1 to 20 carbon atoms, an alkoxy group having 1 to 20 carbon atoms, an aryloxy group having 6 to 20 carbon atoms, a monoalkylamino group having 1 to 20 carbon atoms, a dialkylamino group having 2 to 20 carbon atoms, a monoarylamino group having 6 to 20 carbon atoms, a diarylamino group having 12 to 20 carbon atoms, an aralkyl group having 7 to 20 carbon atoms, an aryl group having 6 to 20 carbon atoms, a heteroaryl group, an alkylthio group having 1 to 20 carbon atoms, or an arylthio group having 6 to 20 carbon atoms.

Y¹ to Y⁸ may form an alicyclic ring through a linking group.

M represents two hydrogen atoms, a divalent metal atom, a divalent monosubstituted metal atom, a trivalent substituted metal atom, a tetravalent substituted metal atom, or an oxidized metal atom.

In the formulae, it is noted that nitrogen atoms located above and below M on the paper surface are coordinated to M by an unshared electron pair.

For a halogen atom, an alkyl group having 1 to 20 carbon atoms, an alkoxy group having 1 to 20 carbon atoms, an aryloxy group having 6 to 20 carbon atoms, a monoalkylamino group having 1 to 20 carbon atoms, a dialkylamino group having 2 to 20 carbon atoms, a monoarylamino group having 6 to 20 carbon atoms, a diarylamino group having 12 to 20 carbon atoms, an aryl group having 6 to 20 carbon atoms, a heteroaryl group, an alkylthio group having 1 to 20 carbon atoms, and an arylthio group having 6 to 20 carbon atoms, which can be adopted as Y¹ to Y⁸, the description of the halogen atom, the alkyl group, the alkoxy group, the aryloxy group, the amino group, the aryl group, the heteroaryl group, the alkylthio group, and the arylthio group in the substituent group T described later can be applied by adjusting the number of carbon atoms.

In addition, for an aralkyl group having 7 to 20 carbon atoms, which can be adopted as Y¹ to Y⁸, the description in the substituent group T described later can be applied by adjusting the number of carbon atoms as a group in which the alkyl group in the substituent group T described later is substituted with an aryl group in the substituent group T described later.

The alicyclic ring which may be formed through a linking group in Y¹ to Y⁸ may be an alicyclic hydrocarbon ring or an alicyclic heterocyclic ring. In addition, the group forming an alicyclic ring through a linking group in Y¹ to Y⁸ is not particularly limited, and examples thereof include substituents bonded to the same ring, such as Y¹ and Y², and substituents bonded to adjacent rings, such as Y² and Y³, as two adjacent groups.

The linking group interposed in a case where Y¹ to Y⁸ form an alicyclic ring is not particularly limited, and examples thereof include a divalent group obtained by removing one hydrogen atom from a monovalent substituent in the substituent group T described later.

As Y¹ to Y⁸, a combination in which one of two substituents bonded to the same 5-membered ring is an alkyl group having 1 to 20 carbon atoms and the other is an aryl group having 6 to 20 carbon atoms (preferably an aryl group substituted with a halogen atom or the like) is preferable.

In a case where M is two hydrogen atoms, one hydrogen atom is bonded to a nitrogen atom constituting a 5-membered ring to which Y³ and Y⁴ are bonded, and another hydrogen atom is bonded to a nitrogen atom constituting a 5-membered ring to which Y⁷ and Y⁸ are bonded.

Examples of the divalent metal atom which can be adopted as M include copper, magnesium, zinc, cobalt, titanium, iron, vanadium, and vanadium oxide, and copper is preferable.

Examples of the divalent monosubstituted metal atom which can be adopted as M include copper, magnesium, zinc, and iron.

Examples of the trivalent substituted metal atom which can be adopted as M include iron, cobalt, and vanadium.

Examples of the tetravalent substituted metal atom which can be adopted as M include titanium.

Examples of the oxidized metal atom which can be adopted as M include vanadium oxide.

In the divalent monosubstituted metal atom, the trivalent substituted metal atom, and the tetravalent substituted metal atom which can be adopted as M, the group that substitutes the metal atom is not particularly limited, and examples thereof include substituents that can be contained in a central metal of a tetraazaporphyrin dye, and examples thereof include a halogen atom, an alkoxy group, an aryloxy group, an acyloxy group, a hydroxy group, an alkyl group, an aryl group, an alkylthio group, and an arylthio group.

For example, as the tetraazaporphyrin dye represented by General Formula (8), commercially available tetraazaporphyrin compounds can be used without any limitation, and for example, tetraazaporphyrin compounds sold by Tokyo Chemical Industry Co., Ltd., YAMADA CHEMICAL CO., LTD., YAMAMOTO CHEMICALS INC., or the like can be used.

In addition, as the dye, a dye represented by General Formula (A) can also be preferably used. As the dye represented by General Formula (A), the description of the compounds represented by General Formulae (1), (3), and (6) and the specific examples described in paragraphs [0016] to [0097] of WO2023/100715A can be applied as they are.

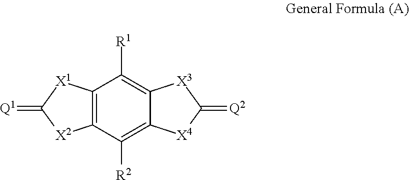

In Formula (A), Q¹ represents a group represented by Formula (Q-1).

Q² represents ═O, ═S, ═NR^{q1}, or ═CR^{q2}R^{q3}, where R^{q1} to R^{q3} represent a hydrogen atom or a substituent, and R^{q2} and R^{q3} may be bonded to each other to form a ring. However, in a case where R^{q2} and R^{q3} are bonded to each other to form a ring, ═CR^{q2}R^{q3} does not have the same structure as Q¹.

R¹ and R² represent a hydrogen atom or a substituent.

X¹ to X⁴ each independently represent —S—, —NR^{X1}—, or —SO₂—, where R^{X1} represents a hydrogen atom or an alkyl group.

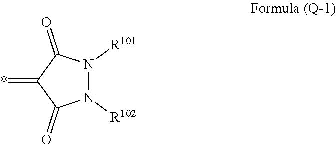

In Formula (Q-1), * represents a bonding site, and R¹⁰¹ and R¹⁰² represent a hydrogen atom, an alkyl group, an aralkyl group, an aryl group, a heterocyclic group, or a group including a polymerizable group having an ethylenically unsaturated bond.

However, in a case where any one of R¹⁰¹ or R¹⁰² is a hydrogen atom, the other is an alkyl group, an aralkyl group, an aryl group, a heterocyclic group, or a group including a polymerizable group having an ethylenically unsaturated bond;
in a case where any one of R¹⁰¹ or R¹⁰² is a methyl group, the other is a hydrogen atom, an alkyl group having 2 or more carbon atoms, an aralkyl group, an aryl group, a heterocyclic group, or a group including a polymerizable group having an ethylenically unsaturated bond; and
in a case where any one of R¹⁰¹ or R¹⁰² is a phenyl group, the other is a hydrogen atom, an alkyl group, an aralkyl group, an aryl group having a substituent, a heterocyclic group, or a group including a polymerizable group having an ethylenically unsaturated bond.

For the definition and the preferred range of each substituent in General Formula (A), the description regarding each substituent of the compound represented by General Formula (1) described in WO2023/100715A can be applied as it is unless otherwise specified. Among these, in the present invention, the dye represented by General Formula (A) is preferably a dye consisting of a combination of the following substituents.

R¹⁰¹ and R¹⁰² are preferably an alkyl group or an aralkyl group, and more preferably an alkyl group having 2 or more carbon atoms.

Q² is ═CR^{q2}R^{q3}, and it is preferable that R^{q2} and R^{q3} are bonded to each other to form a cyclopropane ring, a cyclobutane ring, a cyclopentane ring, or a cyclohexane ring, and it is more preferable that R^{q2} and R^{q3} are bonded to each other to form a cyclobutane ring. It is preferable that the ring formed by bonding R^{q2} and R^{q3} to each other is substituted with one or two ═O's, and it is more preferable that the ring may be further fused with a substituted or unsubstituted benzene ring.

R¹ and R² are preferably —OC(═O)—Y¹¹, —O—Y¹¹, or —OC(═O)NR^{y11}, and more preferably —OC(═O)—Y¹¹. Y¹¹ is preferably an alkyl group, and more preferably a branched alkyl group. R^{y11} is preferably a hydrogen atom or an alkyl group and more preferably an alkyl group.

X¹ to X⁴ are preferably —S—.

In addition, as the above-described dye, a porphyrin dye can also be preferably used, and it is more preferable to use a porphyrin dye represented by General Formula (7) which contains copper, magnesium, zinc, cobalt, titanium, iron, vanadium, or vanadium oxide as a central metal.

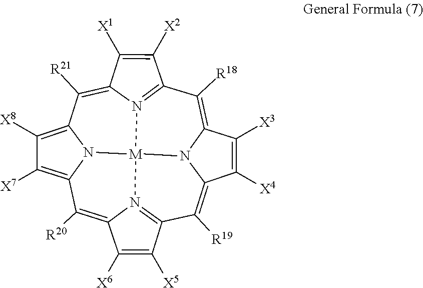

In the formulae, X¹ to X⁸ represent a hydrogen atom, a halogen atom, an alkyl group, an alkoxy group, a substituted or unsubstituted ethenyl group, a substituted or unsubstituted ethynyl group, an aryl group, an aryloxy group, an aryloxycarbonyl group, an alkylthio group, an arylthio group, or an acyl group.

Adjacent groups among X¹ to X⁸ may be bonded to each other to form an aromatic ring together with the substituted carbon atom.

R¹⁸ to R²¹ represent an aryl group.

M represents copper, magnesium, zinc, cobalt, titanium, iron, vanadium, or vanadium oxide.

In the formulae, it is noted that nitrogen atoms located above and below M on the paper surface are coordinated to M by an unshared electron pair.

For the halogen atom, the alkyl group, the alkoxy group, the aryl group, the aryloxy group, the aryloxycarbonyl group, and the alkylthio group, which can be adopted as X¹ to X⁸, the description of the halogen atom, the alkyl group, the alkoxy group, the aryl group, the aryloxy group, the aryloxycarbonyl group, and the alkylthio group in the substituent group T described later can be applied.

The alkyl group which can be adopted as X¹ to X⁸ may have a substituent, and examples of the alkyl group substituted with a substituent include an aralkyl group, a halogenoalkyl group, an alkoxyalkyl group, an aryloxyalkyl group, an aralkyloxyalkyl group, and a halogenoalkoxyalkyl group. For the substituent in the alkyl group substituted with the substituent, the description of the corresponding substituent in the substituent group T described later or the description of the substituent formed by a combination of a plurality of corresponding substituents in the substituent group T described later can be applied.

The alkoxy group which can be adopted as X¹ to X⁸ may have a substituent, and examples of the alkoxy group substituted with a substituent include an aralkyloxy group and a halogenoalkoxy group. For the substituent in the alkoxy group substituted with the substituent, the description of the corresponding substituent in the substituent group T described later can be applied.

As the substituent which can be contained in the substituted ethenyl group and the substituted ethynyl group which can be adopted as X¹ to X⁸, the substituent in the substituent group T described later can be applied.

For the aryl group which can be adopted as R¹⁸ to R²¹, the description of the alkyl group in the substituent group T described later can be applied.

Among these, it is preferable that X¹ to X⁸ represent a hydrogen atom, a halogen atom, a linear alkyl group having 1 to 10 carbon atoms, a branched alkyl group having 3 to 10 carbon atoms, or a cyclic alkyl group having 3 to 10 carbon atoms.

In addition, as the porphyrin dye represented by General Formula (7), commercially available products can also be used without any particular limitation, and for example, a porphyrin compound sold by Tokyo Chemical Industry Co., Ltd., YAMADA CHEMICAL CO., LTD., or the like can be used. For example, FDB-002 (product name, manufactured by YAMADA CHEMICAL CO., LTD.) used in Examples described later corresponds to the porphyrin dye represented by General Formula (7).

A content of the dye in the light absorption layer can be appropriately adjusted according to the purpose, and for example, it is preferably 1.0% to 50% by mass, more preferably 1.5% to 40% by mass, still more preferably 2.0% to 30% by mass, and particularly preferably 2.5% to 20% by mass. In addition, it is also preferable to set the content to 2.5% to 15% by mass.

In a case where two or more kinds of dyes are contained in the light absorption layer, the content of the dye means the total content of all the dyes contained in the light absorption layer.

### <Other Components>

The light absorption layer may contain a leveling agent (surfactant), an antifading agent described in paragraphs [0245] to [0261] of WO2021/014973A, a matting agent described in paragraphs [0262] to [0264] of WO2021/014973A, or the like, in addition to the above-described transparent resin and dye. In a case where the matting agent is contained, it is preferable that the matting agent is applied to a surface of the light absorption layer in the light absorption film according to the embodiment of the present invention (surface on a side opposite to the side in contact with the transparent gas barrier layer I). In a case where the light absorption film according to the embodiment of the present invention contains the transparent gas barrier layer II, it is preferable that the light absorption layer does not contain a matting agent.

### (Leveling Agent)

A leveling agent (surfactant) can be appropriately mixed with the light absorption layer. As the leveling agent, a commonly used compound can be used, and a fluorine-containing surfactant is particularly preferable. Specific examples thereof include compounds described in paragraphs [0028] to [0056] of JP2001-330725A, and a copolymer represented by Formula (IV) described in paragraph [0054] of JP2001-330725A, in which the hydrophilic group Hy in Formula (IV) is a group represented by -(alkyleneoxy)ₙOH (n is an integer of 5 to 30, and the number of carbon atoms in the alkylene group of the alkyleneoxy group is 1 to 6) is preferable. In addition, as the commercially available product, MEGAFACE F (product name) series manufactured by DIC Corporation can also be used.

A content of the leveling agent in the light absorption layer is appropriately adjusted according to the purpose.

The light absorption layer may contain, in addition to the above components, a low-molecular plasticizer, an oligomer-based plasticizer, a retardation modifier, an ultraviolet absorbing agent, a deterioration preventing agent, a peeling accelerating agent, an infrared absorbing agent, an antioxidant, a filler, a compatibilizer.

A film thickness of the light absorption layer is not particularly limited, but is preferably 1 to 18 μm, more preferably 1 to 12 μm, and still more preferably 1 to 8 μm. In a case where the film thickness is equal to or less than the above-described preferred upper limit value, the decrease in the polarization degree due to the fluorescence emitted from the dye (coloring agent) can be suppressed by adding the dye at a high concentration to the thin light absorption layer. In addition, the effect of the antifading agent is also likely to be exhibited. On the other hand, in a case where the film thickness is equal to or larger than the above-described preferred lower limit value, it is easy to maintain the evenness of the in-plane absorbance.

In the present invention, the film thickness of 1 to 18 μm means that the thickness of the light absorption layer is in a range of 1 to 18 μm even in a case where the thickness is measured at any portion. The same applies to the film thicknesses of 1 to 12 μm and 1 to 8 μm. The film thickness can be measured with an electronic micrometer (for example, manufactured by Anritsu Corporation).

In the light absorption layer, an absorbance at a maximal absorption wavelength at which the highest absorbance is exhibited at a wavelength of 400 to 700 nm (hereinafter, also simply referred to as “Ab(λₘₐₓ)”) is preferably 0.3 or more, more preferably 0.5 or more, and still more preferably 0.7 or more.

The absorbance of the light absorption layer can be adjusted by the type of the dye, the addition amount (the content in the light absorption layer), the film thickness, and the like.

From the viewpoint of durability, the moisture content of the light absorption layer is preferably 0.5% by mass or less and more preferably 0.3% by mass or less under the conditions of 25° C. and a relative humidity of 80%, regardless of the film thickness. In the present specification, the moisture content of the light absorption layer can be measured by using a sample having a thick film thickness as necessary. The moisture content can be calculated by humidity-conditioning the sample for 24 hours or longer, then measuring a moisture content (g) by the Karl Fischer method with a water measuring instrument and a sample drying apparatus “CA-03” and “VA-05” (both manufactured by Mitsubishi Chemical Corporation), and dividing the moisture content (g) by the sample mass (g, including the moisture content).

A glass transition temperature (Tg) of the light absorption layer is preferably 50° C. to 140° C., more preferably 60° C. to 130° C., and still more preferably 70° C. to 120° C. In a case where the glass transition temperature is equal to or higher than the above preferable lower limit value, deterioration in a case of being used at a high temperature can be suppressed, and in a case where the glass transition temperature is equal to or lower than the above preferable upper limit value, it is possible to suppress that the organic solvent used in the coating liquid easily remains in the light absorption layer.

The glass transition temperature of the light absorption layer can be measured by the following method.

20 mg of the light absorption layer is put in a measurement pan, and the measurement pan is heated from 30° C. to 120° C. at a rate of 10° C./min in a nitrogen stream and held for 15 minutes, and then cooled to 30° C. at −20° C./min, using a differential scanning calorimeter (for example, X-DSC7000 (manufactured by IT Keisoku Seigyo Co., Ltd.)). Thereafter, the temperature was raised again from 30° C. to 250° C. at a rate of 10° C./min, and the temperature at which the baseline began to deviate from the low temperature side was defined as the glass transition temperature Tg. The glass transition temperature of the light absorption layer can be adjusted by mixing two or more kinds of polymers having different glass transition temperatures, or by changing the adding amount of a low-molecular weight compound such as an antifading agent.

### <Optical Functional Film>

Any optical functional film may be bonded to the light absorption film according to the embodiment of the present invention.

The optional optical functional film is not particularly limited in terms of any of the optical properties and the materials, and a film containing (or containing as a main component) at least any of a cellulose ester resin, an acrylic resin, a cyclic olefin resin, or a polyethylene terephthalate resin can be preferably used. An optically isotropic film or an optically anisotropic retardation film may be used.

For the above optional optical functional films, for example, Fujitac TD80UL (manufactured by FUJIFILM Corporation) or the like can be used as a film containing a cellulose ester resin.

Regarding the optional optical functional film, as those containing an acrylic resin, an optical film containing a (meth)acrylic resin containing a styrene-based resin described in JP4570042B, an optical film containing a (meth)acrylic resin having a glutarimide ring structure in a main chain described in JP5041532B, an optical film containing a (meth)acrylic resin having a lactone ring structure described in JP2009-122664A, and an optical film containing a (meth)acrylic resin having a glutaric anhydride unit described in JP2009-139754A can be used.

In addition, regarding the optional optical functional films, as those containing a cyclic olefin resin, cyclic olefin-based resin film described in paragraphs [0029] and subsequent paragraphs of JP2009-237376A, and cyclic olefin resin film containing an additive reducing Rth described in JP4881827B, and JP2008-063536A can be used.

It is also preferable that the light absorption film according to the embodiment of the present invention has a hard coat layer, an antireflection layer, or the like on a side of the support opposite to a side on which the transparent gas barrier layer I is laminated.

The light absorption film according to the embodiment of the present invention, which includes a hard coat layer on a side of the support opposite to a side on which the transparent gas barrier layer I is laminated, can be used as a light absorption film having a hard coat layer, for example, by disposing the hard coat layer on a front surface (viewer side) of a display device or the like such that the hard coat layer is closest to the viewer side.

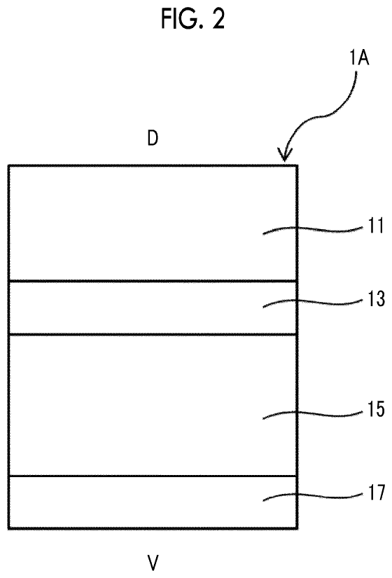

In addition, the light absorption film according to the embodiment of the present invention, which has an antireflection layer 17 on a side of the support 15 opposite to a side on which the transparent gas barrier layer I (13) is laminated, can be used as an antireflection film 1A having an antireflection layer 17, for example, by disposing the light absorption layer 11 on a display device side D and the antireflection layer 17 on a viewer side V on a front surface (viewer side) of a display device or the like as shown in FIG. 2. The light absorption layer 11, the transparent gas barrier layer I (13), and the support 15 in the antireflection film 1A of FIG. 2 can be used as the light absorption layer 11, the transparent gas barrier layer I (13), and the support 15 in the light absorption film 1 of FIG. 1, unless otherwise specified.

As the hard coat layer, a hard coat layer commonly used in a display device can be used without particular limitation, and examples thereof include a hard coat layer described in paragraphs 0190 to 0196 of JP2009-098658A.

As the antireflection layer, an antireflection layer commonly used in a display device can be used without particular limitation, and examples thereof include an inorganic oxide layer (an AR layer, a layer having a function as an antireflection layer) described in paragraphs 0181 to 0185 of JP2021-014014A.

### <<Manufacturing Method of Light Absorption Film>>

The light absorption film according to the embodiment of the present invention can be produced by forming a transparent gas barrier layer I on a support consisting of a transparent film, and then forming a light absorption layer on the transparent gas barrier layer I.

### (Formation of Transparent Gas Barrier Layer I)

The method of forming the transparent gas barrier layer I is not particularly limited, and examples thereof include a producing method according to a conventional method, according to a casting method such as spin coating or slit coating, for example, in a case of an organic material. In addition, examples thereof include a method of bonding a commercially available resin gas barrier film or a resin gas barrier film produced in advance to the support consisting of a transparent film. Moreover, in a case of an inorganic material, examples thereof include a plasma enhanced chemical vapor deposition (CVD) method, a sputtering method, and a vapor deposition method.

In the light absorption film according to the embodiment of the present invention, examples of the method of forming the transparent gas barrier layer I include a method of directly producing the above-described transparent gas barrier layer I on a support consisting of a transparent film. In this case, a surface treatment for increasing the surface energy, such as a glow discharge treatment, a corona treatment, a room temperature plasma treatment, and an alkali saponification treatment, may be performed on a surface of the support consisting of a transparent film, on which the transparent gas barrier layer I is provided, and it is preferable to perform the alkali saponification treatment.

### (Formation of Light Absorption Layer)

The above-described light absorption layer can be produced by a method (coating method) of forming a coating layer on the transparent gas barrier layer I according to any method, according to a conventional method, and stretching can also be appropriately combined.

In the coating method, a solution of a material of the light absorption layer is applied onto the transparent gas barrier layer I to form a coating layer. In addition, the support can be appropriately stretched together with the transparent gas barrier layer I in a state in which the solution of the material of the light absorption layer is applied onto the transparent gas barrier layer I or in a state in which the coating layer is laminated on the transparent gas barrier layer I.

The solvent that is used for the solution of the material of the light absorption layer can be appropriately selected from the viewpoints that the material of the light absorption layer can be dissolved or dispersed, that a uniform surface shape can be easily achieved during the coating step and drying step, liquid storability can be secured, and that a proper saturated vapor pressure is provided.

### —Addition of Dye (Coloring Agent)—

The timing of adding the dye to the material of the light absorption layer is not particularly limited as long as the dye is added at the time of film formation. For example, the dye may be added at the time of synthesizing the matrix resin, or may be mixed with the material of the light absorption layer at the time of preparing the coating liquid for the material of the light absorption layer.

### (Formation of Transparent Gas Barrier Layer II)

In addition, in a case where the light absorption film according to the embodiment of the present invention further has the transparent gas barrier layer II, the light absorption film can be produced by forming a laminate consisting of the transparent gas barrier layer I and the light absorption layer on the support as described above, and then further forming the transparent gas barrier layer II on the light absorption layer.

Regarding the formation of the transparent gas barrier layer II, the above description related to the formation of the transparent gas barrier layer I can be applied by replacing “support consisting of transparent film” with “light absorption layer” and “transparent gas barrier layer I” with “transparent gas barrier layer II”.

### <Treatment of Light Absorption Film>

The light absorption film obtained as described above may be subjected to a hydrophilic treatment by any glow discharge treatment, corona discharge treatment, alkali saponification treatment, or the like, and a corona discharge treatment is preferably used. It is also preferable to apply the method disclosed in JP1994-094915A (JP-H6-094915A) and JP1994-118232A (JP-H6-118232A).

As necessary, the obtained light absorption film can be subjected to a heat treatment step, a superheated steam contact step, an organic solvent contact step, and the like. In addition, a surface treatment may be suitably performed.

In addition, in a case where the above-described optional optical functional film, hardcoat layer, antireflection layer, or the like is provided, the optical functional film, hard coat layer, antireflection layer, or the like may be provided directly on the support, or may be bonded through a pressure-sensitive adhesive layer. For example, it is also preferable to further provide an optical functional film, a hard coat layer, an antireflection layer, or the like directly or through a pressure-sensitive adhesive layer on the support in the light absorption film according to the embodiment of the present invention.

As the pressure-sensitive adhesive layer, a layer consisting of a pressure-sensitive adhesive composition in which a (meth)acrylic resin, a styrene-based resin, a silicone-based resin, or the like is used as a base polymer, and a crosslinking agent such as an isocyanate compound, an epoxy compound, or an aziridine compound is added thereto can be applied.

Preferably, the description regarding the pressure-sensitive adhesive layer in the display device described later can be applied.

### <<Display Device>>

The display device according to the embodiment of the present invention includes the light absorption film or the antireflection film according to the embodiment of the present invention.

As the display device according to the embodiment of the present invention, as long as the light absorption film or the antireflection film according to the embodiment of the present invention is included in a configuration in which the light absorption layer is positioned on the display device side and the support is positioned on the viewer side, and a positional relationship in which excellent light resistance of the light absorption layer by the transparent gas barrier layer I can be realized is adopted, the configuration of a display device that is generally used can be used without particular limitation as another configuration.

The display device is not particularly limited, and examples thereof include an organic light emitting diode (OLED) display device, an inorganic electroluminescence (EL) display device, a micro light emitting diode (micro LED) display device, a mini light emitting diode (mini LED) display device, and a liquid crystal display device.

### [OLED Display Device]

As the OLED display device according to the embodiment of the present invention, as long as the light absorption film or the antireflection film according to the embodiment of the present invention is included, the configuration of an OLED display device that is generally used can be used without particular limitation as another configuration. The configuration example of the OLED display device according to the embodiment of the present invention is not particularly limited; and examples thereof include a display device including glass, a layer containing a thin film transistor (TFT), an OLED display element, a barrier film, a color filter, glass, a pressure-sensitive adhesive layer, and the light absorption film or the antireflection film according to the embodiment of the present invention, in order from the opposite side to external light.

The above-described OLED display element has a configuration in which an anode electrode, a light emitting layer, and a cathode electrode are laminated in this order. In addition to the light emitting layer, a hole injection layer, a hole transport layer, an electron transport layer, an electron injection layer, or the like is included between the anode electrode and the cathode electrode. In addition, for example, the description in JP2014-132522A can also be referenced.

Further, as the color filter, in addition to a typical color filter, a color filter in which quantum dots are laminated can also be used.

A resin film can be used instead of the above-described glass.

In the present invention, the mini LED means an LED having a chip size of about 100 to 200 μm square, and the micro LED means an LED having a chip size of less than 100 μm square. Preferred examples of the micro LED include the micro LED described in WO2014/204694A.

### [Inorganic EL Display Device]

As the inorganic EL display device according to the embodiment of the present invention, a configuration of a general inorganic EL display device which is usually used can be used without particular limitation as another configuration as long as the inorganic EL display device includes the light absorption film or the antireflection film according to the embodiment of the present invention, and for example, the description of the inorganic EL element and the inorganic electroluminescent display device described in JP2005-338640A can be preferably applied.

### [Liquid Crystal Display Device]

As the liquid crystal display device according to the embodiment of the present invention, a configuration of a general liquid crystal display device which is usually used can be used without particular limitation as another configuration as long as the liquid crystal display device includes the light absorption film or the antireflection film according to the embodiment of the present invention, and for example, a liquid crystal display device in an in-plane switching (IPS) mode described in paragraphs [0128] to [0136] of JP2010-102296A is preferable as the liquid crystal display device according to the embodiment of the present invention, except that the light absorption film or the antireflection film according to the embodiment of the present invention is used.

In the display device according to the embodiment of the present invention, it is preferable that the light absorption film or the antireflection film according to the embodiment of the present invention is bonded to a layer constituting the display device, such as glass, on the light absorption layer side (the side opposite to the support) through a pressure-sensitive adhesive layer.

For the pressure-sensitive adhesive layer, the descriptions related to the pressure-sensitive adhesive layer and the forming method in the OLED display device, which are described in paragraphs [0296] to [0347] of WO2021/014973A, can be applied as they are.

A method of forming the pressure-sensitive adhesive layer is not particularly limited, and for example, a method of applying a pressure-sensitive adhesive composition onto the light absorption layer (or the transparent gas barrier layer II) in the light absorption film or the antireflection film according to the embodiment of the present invention by a general means such as a bar coater, and drying and curing the pressure-sensitive adhesive composition; a method of applying a pressure-sensitive adhesive composition onto a surface of a peelable substrate, drying the pressure-sensitive adhesive composition, and then transferring the pressure-sensitive adhesive layer onto the light absorption layer (or the transparent gas barrier layer II) in the light absorption film or the antireflection film according to the embodiment of the present invention using the peelable substrate, and aging and curing the pressure-sensitive adhesive layer; and the like are used.

The peelable substrate is not particularly limited, and any peelable substrate can be used, and for example, the surface energy of the above-described support can be adjusted and used as a peeling film.

In addition, the conditions of application, drying, aging, and curing can be appropriately adjusted based on a conventional method.

The display device according to the embodiment of the present invention can be directly incorporated into the display device without undergoing a peeling step of peeling off the support used in the production of the film from the light absorption film or the antireflection film according to the embodiment of the present invention and a transfer step. Therefore, the peeling step of the support and the transfer step can be reduced, and the production efficiency can be improved.

### EXAMPLES

Hereinafter, the present invention will be more specifically described based on examples. Materials, using amounts, proportions, treatment details, treatment content, and the like shown in the following examples can be appropriately changed without departing from the gist of the present invention. Therefore, it is to be understood that the scope of the present invention is not limited to Examples described below.

In the following examples, “parts” and “%” representing the composition are based on mass unless otherwise specified. Further, λₘₐₓ means the maximal absorption wavelength showing the maximum light absorbance.

In addition, T_{Ave} means an average transmittance calculated from a light transmittance at a wavelength of 400 to 800 nm, which is measured with an ultraviolet-visible-near infrared spectrophotometer UV-3600i (product name, manufactured by Shimadzu Corporation). The T_{Ave} of the individual layers (the gas barrier layer and the light absorption layer) other than the base material is calculated from the ratio of the average transmittance in a case where the layer is provided to the average transmittance in a case where the layer is not provided. In addition, the T_{Ave} of the light absorption layer is calculated from the ratio of the average transmittance in a case where a layer for T_{Ave} measurement having the same film thickness as the light absorption layer is formed using a forming liquid obtained by removing the dye from the light absorption layer forming liquid, to the average transmittance in a case where the layer for T_{Ave} measurement is not provided.

### [Production of Light Absorption Film]

The materials used for producing the light absorption film are shown below.

### <Matrix Resin>

Poly(benzyl methacrylate) (manufactured by Sigma-Aldrich Co., LLC) was used as a resin 10.

ARTON R5000 (product name, manufactured by JSR Corporation, norbornene-based polymer, Tg: 135° C.), which is a cyclic polyolefin resin, was used as a resin 11.

### <Dye>

Each dye described below was used as the dye. The λₘₐₓ described in the section of the following dyes means λₘₐₓ exhibited by each dye in the light absorption film measured by the following method.

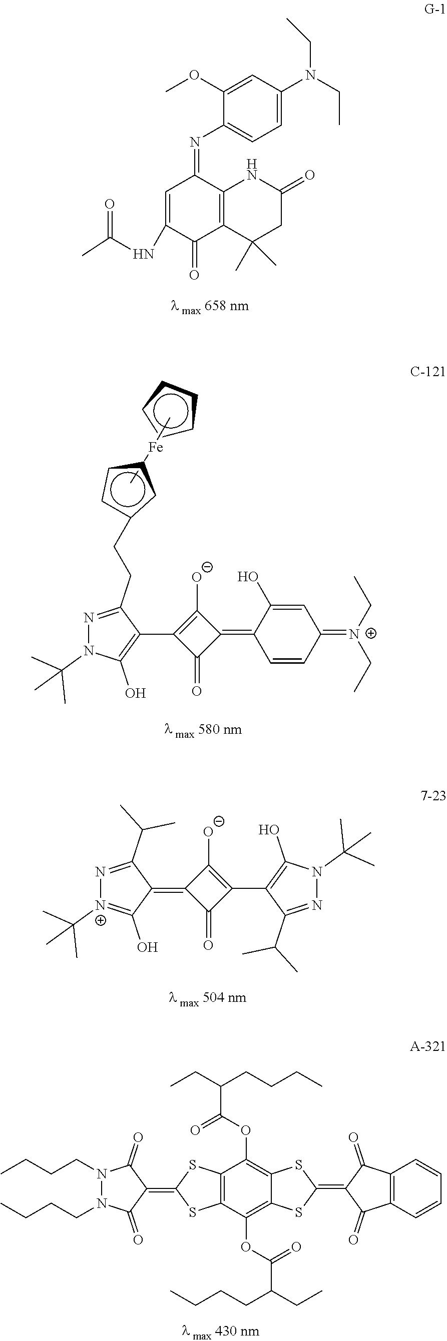

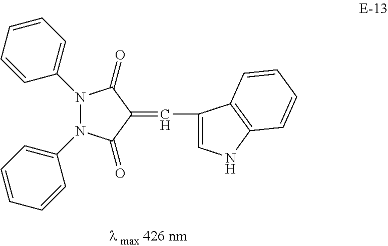 [SMILES: O=C1C(=Cc2c[nH]c3ccccc23)C(=O)N(c2ccccc2)N1c1ccccc1]

Solvent Blue 35 (manufactured by FUJIFILM Wako Pure Chemical Corporation, anthraquinone dye, λₘₐₓ 652 nm) was used as a dye H-1.

PD-311F (product name, manufactured by YAMAMOTO CHEMICALS, Inc., tetraazaporphyrin copper complex dye, λₘₐₓ 585 nm) was used as a dye I-2.

FDB-002 (product name, manufactured by YAMADA CHEMICAL CO., LTD., porphyrin vanadium complex dye, λₘₐₓ 432 nm) was used as a dye J-1.

### (Maximal Absorption Value of Light Absorption Film)

Using a UV3150 spectrophotometer (product name) manufactured by Shimadzu Corporation, the absorbance of the light absorption film in a wavelength range of 380 nm to 800 nm was measured every 1 nm. An absorbance difference Abₓ(λ)−Ab₀(λ) between an absorbance Abₓ(λ) of the light absorption film at each wavelength λ nm and an absorbance Ab₀(λ) of the light absorption film not containing a dye was calculated, and the maximum value of the absorbance difference was defined as the maximal absorption value.

### <Leveling Agent 1>

A polymer surfactant composed of the following constitutional units was used as a leveling agent 1. In the following structural formulae, the proportion of each constitutional unit is a molar ratio.

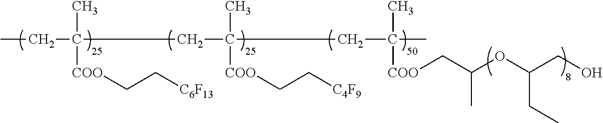

### <Base Material 1>

A cellulose acylate film (manufactured by FUJIFILM Corporation, trade name: FUJITAC TG60UL) was used.

### (Alkali Saponification Treatment)

The above-described cellulose acylate film was passed through a dielectric heating roll at a temperature of 60° C. to raise a film surface temperature to 40° C. Thereafter, an alkaline solution having the following formulation was applied onto a band surface of the film at an application amount of 14 mL/m² using a bar coater, and then transported for 10 seconds under a steam type far-infrared heater manufactured by Noritake Company Limited, which was heated to 110° C. Subsequently, pure water at an amount of 3 mL/m² was applied thereto using the same bar coater. Next, washing with water using a fountain coater and dewatering using an air knife were repeated three times, and then the film was transported to a drying zone at 70° C. for 10 seconds and dried to produce a base material 1 (T_{Ave} 92%) subjected to an alkali saponification treatment.

Alkaline solution

| | | |
|---|---|---|
| Potassium hydroxide | 4.7 | parts by mass |
| Water | 15.8 | parts by mass |
| Isopropanol | 63.7 | parts by mass |
| Surfactant SF-1: C₁₄H₂₉O(CH₂CH₂O)₂₀H | 1.0 | part by mass |
| Propylene glycol | 14.8 | parts by mass |

### Example 1: Example in which Light Absorption Layer Contains Boronic Acid-Containing Polymer

### (1) Preparation of Transparent Gas Barrier Layer Forming Liquid

Each component was mixed with the composition shown below, and the resultant mixture was stirred in a constant-temperature tank at 90° C. for 1 hour to dissolve Kuraray Exceval AQ-4105 (product name, manufactured by KURARAY Co., Ltd., modified polyvinyl alcohol, saponification degree: 98 to 99 mol %), whereby a transparent gas barrier layer forming liquid was prepared.

Composition of transparent gas barrier layer forming liquid

| | | |
|---|---|---|
| Kuraray Exceval AQ-4105 (trade name, | 4.0 | parts by mass |
| manufactured by KURARAY CO., LTD.) | | |
| Pure water | 88.5 | parts by mass |
| Isopropyl alcohol | 7.5 | parts by mass |

Subsequently, the obtained transparent gas barrier layer forming liquid was filtered using a filter having an absolute filtration precision of 5 μm (product name: Hydrophobic Fluorepore Membrane, manufactured by Millex).

### (2) Lamination of Transparent Gas Barrier Layer

The transparent gas barrier layer forming liquid after the filtration treatment was applied onto the surface of the base material 1, which had been subjected to the alkali saponification treatment, using a bar coater so that the film thickness after drying was 1.6 μm, and dried at 120° C. for 60 seconds to produce a base material 1B having a transparent gas barrier layer (T_{Ave} 99%).

### (3) Preparation of Light Absorption Layer Forming Liquid A

Each component was mixed in the following formulation to prepare a light absorption layer forming liquid A.

Formulation of light absorption layer forming liquid A

| | | |
|---|---|---|
| Resin 10 | 66.04 | parts by mass |
| Boronic acid-containing polymer 1 | 20.0 | parts by mass |
| Leveling agent 1 | 0.16 | parts by mass |
| Dye G-1 | 2.4 | parts by mass |
| Dye C-121 | 1.8 | parts by mass |
| Dye 7-23 | 2.1 | parts by mass |
| Dye A-321 | 7.5 | parts by mass |
| Methyl ethyl ketone (solvent) | 733.3 | parts by mass |

Bronic acid-containing polymer 1: A boronic acid-containing polymer composed of the following constitutional units was used as the boronic acid-containing polymer 1. In the following structural formulae, the proportion of each constitutional unit is a mass ratio.

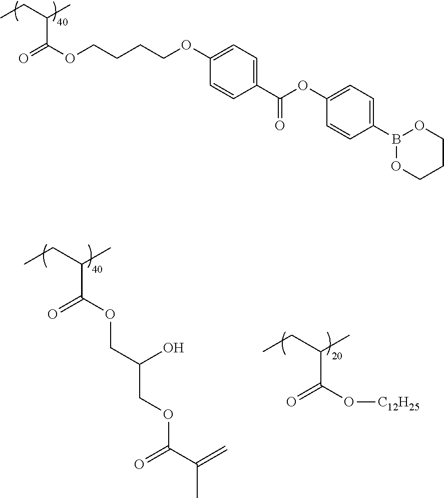

Subsequently, the obtained light absorption layer forming liquid A was filtered using a filter paper (#63, manufactured by Toyo Filter Paper Co., Ltd.) having an absolute filtration precision of 10 μm, and further filtered using a metal sintered filter (FH025, manufactured by Pall) with an absolute filtration precision of 2.5 μm.

### (4) Production of Light Absorption Films Nos. 101 and 102

The light absorption layer forming liquid A after the filtration treatment was applied onto a transparent gas barrier layer of a base material 1B using a bar coater so that the film thickness after drying was 2.4 μm, and dried at 120° C. to form a light absorption layer, thereby producing a light absorption film No. 101.

A light absorption film No. 102 was produced in the same manner as in the production of the light absorption film No. 101, except that the dye E-13 was used instead of the dye A-321 in the light absorption layer forming liquid A.

In the light absorption layers in the light absorption films Nos. 101 and 102, T_{Ave} of the above-described layer for measuring T_{Ave} was 80% or more.

### Example 2: Example in which Polymer Constituting Transparent Resin in Light Absorption Layer Includes Polymer Having Polar Group

A light absorption film No. 201 was produced in the same manner as in the production of the light absorption film No. 101 in Example 1, except that 86.04 parts by mass of a cyclohexyl methacrylate-methacrylic acid random copolymer (methacrylic acid content: 29% by mole, weight-average molecular weight: 26,300) was used instead of the resin 10 and the boronic acid-containing polymer 1 in the light absorption layer forming liquid A.

In the light absorption layer in the light absorption film No. 201, T_{Ave} of the above-described layer for measuring T_{Ave} was 80% or more.

### Example 3: Example in which Polymer Constituting Transparent Resin in Light Absorption Layer Includes Polymer Having Polar Group, and Transparent Gas Barrier Layer I Includes Amine Compound or Polymer Having Amino Group

A light absorption film No. 301 was produced in the same manner as in the production of the light absorption film No. 201 in Example 2, except that 0.7 parts by mass (0.2 parts by mass of polyethyleneimine itself) of polyethyleneimine (30% polyethyleneimine P-70 solution (product name), manufactured by FUJIFILM Wako Pure Chemical Corporation, weight-average molecular weight of about 70,000) was further blended and used in the transparent gas barrier layer forming liquid.

T_{Ave} of the transparent gas barrier layer in the light absorption film No. 301 was 99%.

### [Example 4: Example in which Polymer Constituting Transparent Resin in Light Absorption Layer Includes Polymer Having Polar Group, and Transparent Gas Barrier Layers I and II Disposed in Contact with Both Sides of Light Absorption Layer Include Amine Compound or Polymer Having Amino Group]

### (1) Preparation of Transparent Gas Barrier Layer Forming Liquid C

Each component was mixed with the composition shown below, and the resultant mixture was stirred in a constant-temperature tank at 90° C. for 1 hour to dissolve Kuraray Exceval AQ-4105 (product name, manufactured by KURARAY Co., Ltd., modified polyvinyl alcohol, saponification degree: 98 to 99 mol %), whereby a transparent gas barrier layer forming liquid C was prepared.

Composition of transparent gas barrier layer forming liquid C

| | |
|---|---|
| Kuraray Exceval AQ-4105 (product name, | 3.8 parts by mass |
| manufactured by KURARAY Co., Ltd.) | |
| 30% polyethyleneimine P-70 solution (product | 0.7 parts by mass |
| name, manufactured by FUJIFILM Wako Pure | (0.2 parts by mass |
| Chemical Corporation, weight-average | of polyethyleneimine |
| molecular weight of about 70,000) | itself) |
| Pure water | 88.5 parts by mass |
| Isopropyl alcohol | 7.5 parts by mass |

Subsequently, the obtained transparent gas barrier layer forming liquid C was filtered using a filter (product name: Hydrophobic Fluorepore Membrane, manufactured by Millex) having an absolute filtration precision of 5 μm.

### (2) Lamination of Transparent Gas Barrier Layer

The transparent gas barrier layer forming liquid C after the filtration treatment was applied onto the surface of the base material 1, which had been subjected to the alkali saponification treatment, using a bar coater so that the film thickness after drying was 1.6 μm, and dried at 120° C. for 60 seconds to produce a base material 1C having a transparent gas barrier layer C (T_{Ave} 99%).

### (3) Preparation of Light Absorption Layer Forming Liquid D

Each component was mixed with the following composition to prepare a light absorption layer forming liquid D.

Composition of light absorption layer forming liquid D

| | | |
|---|---|---|
| Resin 11 | 73.34 | parts by mass |
| Tuftec M1913 (maleic acid anhydride-modified | 9.25 | parts by mass |
| styrene-ethylene-ethylene-styrene block | | |
| copolymer resin, manufactured by Asahi Kasei | | |
| Corporation) | | |
| Leveling agent 1 | 0.16 | parts by mass |
| Dye H-1 | 5.5 | parts by mass |
| Dye I-2 | 2.8 | parts by mass |
| Dye 7-23 | 2.9 | parts by mass |
| Dye J-1 | 6.1 | parts by mass |
| Toluene (solvent) | 1,229.7 | parts by mass |
| Cyclohexanone (solvent) | 136.6 | parts by mass |
| Isopropyl alcohol (solvent) | 151.8 | parts by mass |

Subsequently, the obtained light absorption layer forming liquid D was filtered using filter paper (#63, manufactured by Toyo Roshi Kaisha, Ltd.) having an absolute filtration precision of 10 μm, and further filtered using a metal sintered filter (FH025, manufactured by Pall Corporation) having an absolute filtration precision of 2.5 μm.

### (4) Lamination of Light Absorption Layer

The light absorption layer forming liquid D after the filtration treatment was applied onto the transparent gas barrier layer C of the base material 1C using a bar coater such that the film thickness after drying was 1.8 μm, and dried at 130° C. to form a light absorption layer, thereby producing a laminate No. 401.

Furthermore, the light absorption layer side (the side opposite to the base material 1) of the laminate No. 401 was subjected to a corona treatment using a corona treatment device (product name: Corona-Plus, manufactured by VETAPHONE) under the conditions of a discharge amount of 1,000 W min/m² and a treatment speed of 3.2 m/min.

### (5) Preparation of Transparent Gas Barrier Layer Forming Liquid E

Each component was mixed with the composition shown below, and stirred in a constant-temperature tank at 90° C. for 1 hour to dissolve Kuraray Exceval AQ-4105 (product name, manufactured by Kuraray Co., Ltd.), thereby preparing a transparent gas barrier layer forming liquid E.

Composition of transparent gas barrier layer forming liquid E

| | |
|---|---|
| Kuraray Exceval AQ-4105 (trade name, | 4.0 parts by mass |
| manufactured by KURARAY CO., LTD.) | |
| 30% polyethyleneimine P-70 solution (product | 0.1 parts by mass |
| name, manufactured by FUJIFILM Wako Pure | (0.03 parts by mass |
| Chemical Corporation, weight-average | of polyethyleneimine |
| molecular weight of about 70,000) | itself) |
| Pure water | 88.5 parts by mass |
| Isopropyl alcohol | 7.5 parts by mass |

Subsequently, the obtained gas barrier layer forming liquid E was filtered using a filter having an absolute filtration precision of 5 m (product name: Hydrophobic Fluorepore Membrane, manufactured by Millex).

### (6) Production of Light Absorption Film No. 401

The transparent gas barrier layer forming liquid E after the filtration treatment was applied to the surface (light absorption layer) of the laminate No. 401, which had been subjected to the corona treatment, using a bar coater so that the film thickness after drying was 1.6 μm, and dried at 130° C. for 60 seconds to form a transparent gas barrier layer E (T_{Ave} 99%), thereby producing a light absorption film No. 401.

The light absorption film No. 401 had a configuration in which the base material 1, the transparent gas barrier layer C, the light absorption layer, and the transparent gas barrier layer E were laminated in this order.

The T_{Ave} of the layer for measuring T_{Ave} described above for the light absorption layer in the light absorption film No. 401 was 80% or more.

### REFERENCE EXAMPLE

A light absorption film No. r11 was produced in the same manner as in the production of the light absorption film No. 101 in Example 1, except that the light absorption layer forming liquid A was changed to a composition not containing the boronic acid-containing polymer 1.

The T_{Ave} of the layer for measuring T_{Ave} described above for the light absorption layer in the light absorption film No. r11 was 80% or more.

The light absorption films No. 101, 102, 201, 301, and 401 were the light absorption films according to the embodiment of the present invention, and the light absorption film No. r11 was the light absorption film of the reference example.

All of the light absorption films No. 101, 102, 201, 301, 401, and r11 were laminates in which the transparent gas barrier layer I and the light absorption layer were arranged in contact with each other in this order on the base material corresponding to the support. Therefore, in a case where the light absorption film is incorporated into a display device so that a decrease in absorbance of a dye contained in the light absorption layer can be suppressed by the transparent gas barrier layer I, the light absorption film according to the embodiment of the present invention can be incorporated into the display device such that the light absorption layer (in No. 401, the transparent gas barrier layer II) is on the display device side, without peeling off the support from the light absorption layer and without transferring the light absorption layer, so that the manufacturing efficiency of the display device can be improved.

### <Evaluations>

The adhesiveness and the light resistance of each light absorption film were evaluated as follows. The results are shown in Table 1 below.

### [Adhesiveness]

The light absorption film was cut out into a size of 25 mm in width and 150 mm in length, and a surface of the light absorption film on a side opposite to the base material 1 (the surface on the light absorption layer side or the surface on the transparent gas barrier layer E side) was bonded to glass through a pressure-sensitive adhesive (trade name: STT-125CK, manufactured by Soken Chemical & Engineering Co., Ltd.) having a size of 35 mm in width and 80 mm in length to produce an adhesiveness evaluation film. The size of the bonding surface between the pressure-sensitive adhesive and the light absorption film was 25 mm in width and 80 mm in length, and the pressure-sensitive adhesive and the light absorption film were bonded to each other such that the pressure-sensitive adhesive and the light absorption film protruded by 25 mm in width and 70 mm in length with respect to the laminate of the pressure-sensitive adhesive and the glass (not bonded to the pressure-sensitive adhesive).

Subsequently, a 90-degree peel test was performed according to JIS standard: JIS Z-0237 (2009) under the conditions of a peeling rate of 300 mm/min and 25° C. Specifically, in the adhesiveness evaluation film obtained as described above, a portion of the light absorption film protruding from the glass was peeled off in the length direction by 25 mm while being held by hand, the glass substrate was fixed to one chuck of a tensile tester, the light absorption film on the side protruding from the glass was gripped by the other chuck, and the light absorption film was peeled off in the vertical direction by 50 mm, and the peeling force at that time was measured with the tensile tester.

In the above test, an average value (average peeling force) of the peeling forces from a position where 20 mm peeling was performed to a position where 50 mm peeling was performed was calculated, and the adhesiveness was evaluated according to the following standard based on the average peeling force.

The adhesiveness between the glass and the light absorption layer or the transparent gas barrier layer E in the light absorption film due to the pressure-sensitive adhesive is sufficiently high as compared with the adhesiveness between the respective layers constituting the light absorption film, and the average peeling force obtained by the above-described test is the peeling force between the two layers which are most likely to be peeled off among the respective layers constituting the light absorption film.

### —Evaluation Standard—

A: average peeling force was 5 N/25 mm or more.

B: average peeling force was 2 N/25 mm or more and less than 5 N/25 mm.

C: average peeling force was 0.5 N/25 mm or more and less than 2 N/25 mm.

D: average peeling force was less than 0.5 N/25 mm.

### <Light Resistance>

The light absorption film was punched out in a square shape having a side of 40 mm, and the surface on the side opposite to the base material 1 was bonded to a glass plate using a pressure-sensitive adhesive (trade name: STT-125CK, manufactured by Soken Chemical & Engineering Co., Ltd.). The glass-bonded light absorption film produced above was irradiated with light for 140 hours from the surface of the glass-bonded light absorption film opposite to the surface bonded to the glass (surface on the base material 1 side) using a Super Xenon Weather Meter SX75 (trade name, manufactured by Suga Test Instruments Co., Ltd.), the color loss of the end part (outer peripheral portion of the square) of the glass-bonded light absorption film was visually observed, and the light resistance was evaluated by applying the evaluation standard below.

### —Evaluation Standard—

A: No color loss was observed at the end part.

B: The width of the color loss portion was at most less than 1 mm from the end.

C: The width of the color loss portion was at most 1 mm or more and less than 3 mm from the end.

D: The width of the color loss portion was at most 3 mm or more.

TABLE 1

| Light absorption film No. | Adhesiveness | Light resistance |
|---|---|---|
| 101 | A | C |
| 102 | A | C |
| 201 | C | C |
| 301 | B | C |
| 401 | A | A |
| r11 | D | D |

From the results in Table 1 above, the following facts can be seen.

The light absorption films Nos. 101 and 102 in which the light absorption layer further contains a boronic acid-containing polymer, the light absorption film No. 201 in which the polymer constituting the transparent resin in the light absorption layer contains a polymer having a polar group, the light absorption film No. 301 in which the polymer constituting the transparent resin in the light absorption layer contains a polymer having a polar group and the transparent gas barrier layer I contains an amine compound or a polymer having an amino group, and the light absorption film No. 401 in which the polymer constituting the transparent resin in the light absorption layer contains a polymer having a polar group and the transparent gas barrier layers I and II disposed in contact with both sides of the light absorption layer contain an amine compound or a polymer having an amino group satisfy any of the regulations (I) to (III). All of the light absorption films Nos. 101, 102, 201, 301, and 401 exhibited excellent adhesiveness to the light absorption film No. r11 of the reference example, which did not satisfy any of the regulations (I) to (III).

In addition, the light absorption film No. 401 of the embodiment of the present invention, which had the gas barrier layers I and II in contact with both sides of the light absorption layer, was particularly preferable since no color loss occurred at the end part after the xenon light irradiation.

### EXPLANATION OF REFERENCES

1: light absorption film
1A: antireflection film
1B: light absorption film
11: light absorption layer
13: transparent gas barrier layer I
15: support
17: antireflection layer
19: transparent gas barrier layer II
D: display device side
V: viewer side

What is claimed is:

1. Alight absorption film comprising:
a support made of a transparent film;
a transparent layer I having gas barrier properties, the transparent layer I being disposed in contact with the support; and
a light absorption layer containing a transparent resin and a dye, the light absorption layer being disposed in contact with the transparent layer I having gas barrier properties.

2. The light absorption film according to claim 1, further comprising:
a transparent layer II having gas barrier properties, the transparent layer II being disposed in contact with the light absorption layer on a side opposite to a side of the transparent layer I having gas barrier properties.

3. The light absorption film according to claim 1,
wherein the light absorption layer further contains a polymer having a boronic acid-containing group.

4. The light absorption film according to claim 1,
wherein a polymer constituting the transparent resin in the light absorption layer has a polar group.

5. The light absorption film according to claim 1,
wherein the transparent layer I having gas barrier properties contains an amine compound or a polymer having an amino group.

6. The light absorption film according to claim 1, further comprising:
a hard coat layer on a side of the support opposite to a side on which the transparent layer I having gas barrier properties is laminated.

7. An antireflection film comprising:
an antireflection layer on a side of the support in the light absorption film according to claim 1 opposite to a side on which the transparent layer I having gas barrier properties is laminated.

8. A display device comprising:
the light absorption film according to claim 6.

9. A display device comprising:
the antireflection film according to claim 7.
